(19) United States
(12) Patent Application Publication
(10) Pub. No.: US 2026/0282577 A1
(43) Pub. Date: Sep. 17, 2026

(54) SOLID-STATE IMAGING DEVICE

(71) Applicant: SONY SEMICONDUCTOR SOLUTIONS CORPORATION, Kanagawa (JP)

(72) Inventors: Mariko MIURA, Kanagawa (JP); Kosuke OZAKI, Nagasaki (JP); Sachio NISHI, Nagasaki (JP); Kazuhiro YONEDA, Osaka (JP); Tetsushi OKAZAKI, Tokyo (JP); Yusuke OTAKE, Kanagawa (JP)

(73) Assignee: SONY SEMICONDUCTOR SOLUTIONS CORPORATION, Kanagawa (JP)

(21) Appl. No.: 18/871,790

(22) PCT Filed: Apr. 27, 2023
(86) PCT No.: PCT/JP2023/016658

§ 371 Date: Dec. 4, 2024

(30) Foreign Application Priority Data
Jun. 15, 2022 (JP) 2022-096657

(51) Int. Cl. H10F 39/00

(52) U.S. Cl. CPC H10F 39/8057; H10F 39/8053

(57) ABSTRACT

A solid-state imaging device includes pixels arranged in a plurality of arrays in a first direction and in a second direction, a first color filter disposed over a plurality of light receiving pixels arranged in the first direction and having a first color, a second color filter disposed over a plurality of light receiving pixels arranged in the first direction and having a second color different from the first color, a first inter-waveguide light shielding wall between the first color filter and the second color filter at an image height center of the pixel region, and and a second inter-waveguide light shielding wall between the first color filter and the second color filter at an image height periphery located away from the image height center of the pixel region and has a width greater than a width of the first inter-waveguide light shielding wall in the same direction.

### TECHNICAL FIELD

The present disclosure relates to a solid-state imaging device.

### BACKGROUND ART

Patent Literature 1 discloses a solid-state imaging element, an imaging device, and an electronic device. The solid-state imaging element includes a white pixel, and a red pixel, a green pixel, and a blue pixel other than the white pixel. At a position where the white pixel is adjacent to each of the red, green, and blue pixels, a light-shielding film having a thickness greater than that of the white pixel is provided.

In the solid-state imaging element thus configured, light transmitted through a color filter of the white pixel is shielded by the light-shielding film, thereby making it possible to suppress an entry of the light into an area other than the white pixel. This makes it possible to reduce color mixing while suppressing a reduction in a sensitivity of the white pixel.

### CITATION LIST

### Patent Literature

Patent Literature 1: Japanese Unexamined Patent Application Publication No. 2016-54227

### SUMMARY OF THE INVENTION

In a solid-state imaging device, color mixing between each adjacent light receiving pixel provided with a color filter of a different color is expected to be effectively suppressed or prevented.

A solid-state imaging device according to a first mode of the present disclosure includes: a pixel region including light receiving pixels arranged in a plurality of arrays, the light receiving pixels being arranged in a first direction and a second direction that intersects with the first direction, a first color filter disposed over a plurality of the light receiving pixels arranged in the first direction, the first color filter having a first color, a second color filter disposed over the plurality of the light receiving pixels arranged in the first direction, the second color filter having a second color different from the first color, a first inter-waveguide light shielding wall provided between the first color filter and the second color filter at an image height center of the pixel region, the first inter-waveguide light shielding wall having a light-shielding property, and a second inter-waveguide light shielding wall provided between the first color filter and the second color filter at an image periphery located away from the image height center of the pixel region, the second inter-waveguide light shielding wall having a light-shielding property and having a width greater than a width of the first inter-waveguide light shielding wall in the same direction.

In a solid-state imaging device according a second mode of the present disclosure, in the solid-state imaging device according to the first mode, the second inter-waveguide light shielding wall has a width that increases as an offset distance from the image height center increases.

In a solid-state imaging device according to a third mode of the present disclosure, in a solid-state imaging device according to the first mode or the second mode, an image height periphery includes: a first image height periphery located away from an image height center of a pixel region, and a second image height periphery located away from the image height center toward an opposite side of the first image height periphery, and the second inter-waveguide light shielding wall is provided at the first image height periphery and the second image height periphery.

In a solid-state imaging device according to a fourth mode of the present disclosure, in a solid-state imaging device according to the third mode, the width of the second inter-waveguide light shielding wall provided at the first image height periphery has a dimension that is the same as or different from the width of the second inter-waveguide light shielding wall provided at the second image height periphery.

### BRIEF DESCRIPTION OF THE DRAWINGS

FIG. 1 is a schematic plan view of a pixel region (effective pixel region) of a solid-state imaging device according to a first embodiment of the present disclosure.

FIG. 2 is an enlarged plan view of a main portion of a light receiving pixel arranged in the pixel region illustrated in FIG. 1.

FIG. 3 is a cross-sectional view of the main portion of the light receiving pixel illustrated in FIG. 2 (a cross-sectional view taken along a section line A-A illustrated in FIG. 2).

FIG. 4 is an enlarged cross-sectional view of the main portion of the light receiving pixel illustrated in FIG. 3.

FIG. 5 illustrates an enlarged cross-sectional view of an inter-waveguide light shielding wall provided between each color filter in the solid-state imaging device illustrated in FIGS. 2 to 4.

FIG. 6 is an enlarged plan view of a lens in the solid-state imaging device illustrated in FIGS. 2 to 4.

FIG. 7 is a schematic enlarged plan view of a main portion, illustrating a relationship between photosensitivity and each of an image height center and an image height periphery in the pixel region illustrated in FIG. 1.

FIG. 8A is an enlarged plan view of the image height center of the pixel region of the solid-state imaging device according to the first embodiment.

FIG. 8B is an enlarged plan view of an image height periphery (a positive image height side) of the pixel region.

FIG. 8C is an enlarged plan view of an image height periphery (a negative image height side) of the pixel region.

FIG. 8D is an enlarged cross-sectional view of the image height periphery of the pixel region illustrated in FIG. 8B (a cross-sectional view taken along a section line B-B illustrated in FIG. 8B).

FIG. 9A is an enlarged plan view of an image height center of a pixel region of a solid-state imaging device according to a second embodiment of the present disclosure.

FIG. 9B is an enlarged plan view of an image height periphery (a positive image height side) of the pixel region.

FIG. 9C is an enlarged plan view of an image height periphery (a negative image height side) of the pixel region.

FIG. 9D is an enlarged cross-sectional view of the image height periphery of the pixel region illustrated in FIG. 9B (a cross-sectional view taken along a section line C-C illustrated in FIG. 9B).

FIG. 10A is an enlarged plan view of an image height center of a pixel region of a solid-state imaging device according to a third embodiment of the present disclosure.

FIG. 10B is an enlarged plan view of an image height periphery (a positive image height side) of the pixel region.

FIG. 10C is an enlarged plan view of an image height periphery (a negative image height side) of the pixel region.

FIG. 10D is an enlarged cross-sectional view of the image height periphery of the pixel region illustrated in FIG. 10B (a cross-sectional view taken along a section line D-D illustrated in FIG. 10B).

FIG. 11A is an enlarged plan view of an image height center of a pixel region of a solid-state imaging device according to a fourth embodiment of the present disclosure.

FIG. 11B is an enlarged plan view of an image height periphery (a positive image height side) of the pixel region.

FIG. 11C is an enlarged plan view of an image height periphery (a negative image height side) of the pixel region.

FIG. 11D is an enlarged cross-sectional view of the image height periphery of the pixel region illustrated in FIG. 11B (a cross-sectional view taken along a section line E-E illustrated in FIG. 11B).

FIG. 12A is an enlarged plan view of an image height center of a pixel region of a solid-state imaging device according to a fifth embodiment of the present disclosure.

FIG. 12B is an enlarged plan view of an image height periphery (a positive image height side) of the pixel region.

FIG. 12C is an enlarged plan view of an image height periphery (a negative image height side) of the pixel region.

FIG. 12D is an enlarged cross-sectional view of the image height periphery of the pixel region illustrated in FIG. 12B (a cross-sectional view taken along a section line F-F illustrated in FIG. 12B).

FIG. 13A is an enlarged plan view of an image height center of a pixel region of a solid-state imaging device according to a sixth embodiment of the present disclosure.

FIG. 13B is an enlarged plan view of an image height periphery (a positive image height side) of the pixel region.

FIG. 13C is an enlarged plan view of an image height periphery (a negative image height side) of the pixel region.

FIG. 13D is an enlarged cross-sectional view of the image height periphery of the pixel region illustrated in FIG. 13B (a cross-sectional view taken along a section line G-G illustrated in FIG. 13B).

FIG. 14A is an enlarged plan view of an image height center of a pixel region of a solid-state imaging device according to a seventh embodiment of the present disclosure.

FIG. 14B is an enlarged plan view of an image height periphery (a positive image height side) of the pixel region.

FIG. 14C is an enlarged plan view of an image height periphery (a negative image height side) of the pixel region.

FIG. 14D is an enlarged cross-sectional view of the image height periphery of the pixel region illustrated in FIG. 14B (a cross-sectional view taken along a section line H-H illustrated in FIG. 14B).

FIG. 15A is an enlarged plan view of an image height center of a pixel region of a solid-state imaging device according to an eighth embodiment of the present disclosure.

FIG. 15B is an enlarged plan view of an image height periphery (a positive image height side) of the pixel region.

FIG. 15C is an enlarged plan view of an image height periphery (a negative image height side) of the pixel region.

FIG. 15D is an enlarged cross-sectional view of the image height periphery of the pixel region illustrated in FIG. 15B (a cross-sectional view taken along a section line I-I illustrated in FIG. 15B).

FIG. 16A is an enlarged plan view of an image height center of a pixel region of a solid-state imaging device according to a ninth embodiment of the present disclosure.

FIG. 16B is an enlarged plan view of an image height periphery (a positive image height side) of the pixel region.

FIG. 16C is an enlarged plan view of an image height periphery (a negative image height side) of the pixel region.

FIG. 16D is an enlarged cross-sectional view of the image height periphery of the pixel region illustrated in FIG. 16B (a cross-sectional view taken along a section line J-J illustrated in FIG. 16B).

FIG. 17A is an enlarged plan view of an image height center of a pixel region of a solid-state imaging device according to a tenth embodiment of the present disclosure.

FIG. 17B is an enlarged plan view of an image height periphery (a positive image height side) of the pixel region.

FIG. 17C is an enlarged plan view of an image height periphery (a negative image height side) of the pixel region.

FIG. 17D is an enlarged cross-sectional view of the image height periphery of the pixel region illustrated in FIG. 17B (a cross-sectional view taken along a section line K-K illustrated in FIG. 17B).

FIG. 18A is an enlarged plan view of an image height center of a pixel region of a solid-state imaging device according to an eleventh embodiment of the present disclosure.

FIG. 18B is an enlarged plan view of an image height periphery (a positive image height side) of the pixel region.

FIG. 18C is an enlarged plan view of an image height periphery (a negative image height side) of the pixel region.

FIG. 18D is an enlarged cross-sectional view of the image height periphery of the pixel region illustrated in FIG. 18B (a cross-sectional view taken along a section line L-L illustrated in FIG. 18B).

FIG. 19A is an enlarged plan view of an image height center of a pixel region of a solid-state imaging device according to a thirteenth embodiment of the present disclosure.

FIG. 19B is an enlarged plan view of an image height periphery (a positive image height side) of the pixel region.

FIG. 19C is an enlarged plan view of an image height periphery (a negative image height side) of the pixel region.

FIG. 19D is an enlarged cross-sectional view of the image height periphery of the pixel region illustrated in FIG. 19B (a cross-sectional view taken along a section line M-M illustrated in FIG. 19B).

FIG. 20A is an enlarged plan view of an image height center of a pixel region of a solid-state imaging device according to a fourteenth embodiment of the present disclosure.

FIG. 20B is an enlarged plan view of an image height periphery (a positive image height side) of the pixel region.

FIG. 20C is an enlarged plan view of an image height periphery (a negative image height side) of the pixel region.

FIG. 20D is an enlarged cross-sectional view of the image height periphery of the pixel region illustrated in FIG. 20B (a cross-sectional view taken along a section line N-N illustrated in FIG. 20B).

FIG. 21A is an enlarged plan view of an image height center of a pixel region of a solid-state imaging device according to a fifteenth embodiment of the present disclosure.

FIG. 21B is an enlarged plan view of an image height periphery (a positive image height side) of the pixel region.

FIG. 21C is an enlarged plan view of an image height periphery (a negative image height side) of the pixel region.

FIG. 21D is an enlarged cross-sectional view of the image height periphery of the pixel region illustrated in FIG. 21B (a cross-sectional view taken along a section line O-O illustrated in FIG. 21B).

FIG. 22A is an enlarged plan view of an image height center of a pixel region of a solid-state imaging device according to a sixteenth embodiment of the present disclosure.

FIG. 22B is an enlarged plan view of an image height periphery (a positive image height side) of the pixel region.

FIG. 22C is an enlarged plan view of an image height periphery (a negative image height side) of the pixel region.

FIG. 22D is an enlarged cross-sectional view of the image height periphery of the pixel region illustrated in FIG. 22B (a cross-sectional view taken along a section line P-P illustrated in FIG. 22B).

FIG. 23A is an enlarged plan view of an image height center of a pixel region of a solid-state imaging device according to a seventeenth embodiment of the present disclosure.

FIG. 23B is an enlarged plan view of an image height periphery (a positive image height side) of the pixel region.

FIG. 23C is an enlarged plan view of an image height periphery (a negative image height side) of the pixel region.

FIG. 23D is an enlarged cross-sectional view of the image height periphery of the pixel region illustrated in FIG. 23B (a cross-sectional view taken along a section line Q-Q illustrated in FIG. 23B).

FIG. 24A is an enlarged plan view of an image height center of a pixel region of a solid-state imaging device according to an eighteenth embodiment of the present disclosure.

FIG. 24B is an enlarged plan view of an image height periphery (a positive image height side) of the pixel region.

FIG. 24C is an enlarged plan view of an image height periphery (a negative image height side) of the pixel region.

FIG. 24D is an enlarged cross-sectional view of the image height periphery of the pixel region illustrated in FIG. 24B (a cross-sectional view taken along a section line R-R illustrated in FIG. 24B).

FIG. 25A is an enlarged plan view of an image height center of a pixel region of a solid-state imaging device according to a nineteenth embodiment of the present disclosure.

FIG. 25B is an enlarged plan view of an image height periphery (a positive image height side) of the pixel region.

FIG. 25C is an enlarged plan view of an image height periphery (a negative image height side) of the pixel region.

FIG. 25D is an enlarged cross-sectional view of the image height periphery of the pixel region illustrated in FIG. 25B (a cross-sectional view taken along a section line S-S illustrated in FIG. 25B).

FIG. 26A is an enlarged plan view of an image height center of a pixel region of a solid-state imaging device according to a twentieth embodiment of the present disclosure.

FIG. 26B is an enlarged plan view of an image height periphery (a positive image height side) of the pixel region.

FIG. 26C is an enlarged plan view of an image height periphery (a negative image height side) of the pixel region.

FIG. 26D is an enlarged cross-sectional view of the image height periphery of the pixel region illustrated in FIG. 26B (a cross-sectional view taken along a section line T-T illustrated in FIG. 26B).

FIG. 27A is an enlarged plan view of an image height center of a pixel region of a solid-state imaging device according to a twenty-first embodiment of the present disclosure.

FIG. 27B is an enlarged plan view of an image height periphery (a positive image height side) of the pixel region.

FIG. 27C is an enlarged plan view of an image height periphery (a negative image height side) of the pixel region.

FIG. 27D is an enlarged cross-sectional view of the image height periphery of the pixel region illustrated in FIG. 27B (a cross-sectional view taken along a section line U-U illustrated in FIG. 27B).

FIG. 28A is an enlarged plan view of an image height center of a pixel region of a solid-state imaging device according to a twenty-second embodiment of the present disclosure.

FIG. 28B is an enlarged plan view of an image height periphery (a positive image height side) of the pixel region.

FIG. 28C is an enlarged plan view of an image height periphery (a negative image height side) of the pixel region.

FIG. 28D is an enlarged cross-sectional view of the image height periphery of the pixel region illustrated in FIG. 28B (a cross-sectional view taken along a section line V-V illustrated in FIG. 28B).

FIG. 29 is a schematic plan view corresponding to FIG. 1, illustrating a pixel region (effective pixel region) of a solid-state imaging device according to a twenty-third embodiment of the present disclosure.

FIG. 30 is an enlarged cross-sectional view corresponding to FIG. 5, illustrating an inter-waveguide light shielding wall in a solid-state imaging device according to a twenty-fourth embodiment of the present disclosure.

FIG. 31 is an enlarged cross-sectional view corresponding to FIG. 5, illustrating an inter-waveguide light shielding wall of a solid-state imaging device according to a twenty-fifth embodiment of the present disclosure.

FIG. 32 is a block diagram depicting an example of schematic configuration of a vehicle control system.

FIG. 33 is a diagram of assistance in explaining an example of installation positions of an outside-vehicle information detecting section and an imaging section.

### MODES FOR CARRYING OUT THE INVENTION

In the following, embodiments of the present disclosure are described in detail with reference to the drawings. It is to be noted that description is given in the following order.

### 1. First Embodiment

A first embodiment describes an example in which the present technology is applied to a solid-state imaging device. Here, a planar structure of a pixel region of a solid-state imaging device, a planar structure including an array configuration of a light receiving pixel, and a cross-sectional structure of a main portion of the light receiving pixel are described. In particular, a configuration of an inter-waveguide light shielding wall between each color filter disposed in the light receiving pixel is described in detail.

### 2. Second Embodiment

A second embodiment describes a first example in which a configuration of the inter-waveguide light shielding wall in the solid-state imaging device according to the first embodiment is changed.

### 3. Third Embodiment

A third embodiment describes a second example in which the configuration of the inter-waveguide light shielding wall in the solid-state imaging device according to the first embodiment is changed.

### 4. Fourth Embodiment

A fourth embodiment describes a third example in which the configuration of the inter-waveguide light shielding wall in the solid-state imaging device according to the first embodiment is changed.

### 5. Fifth Embodiment

A fifth embodiment describes a fourth example in which the configuration of the inter-waveguide light shielding wall in the solid-state imaging device according to the first embodiment is changed.

### 6. Sixth Embodiment

A sixth embodiment describes a fifth example in which the configuration of the inter-waveguide light shielding wall in the solid-state imaging device according to the first embodiment is changed.

### 7. Seventh Embodiment

A seventh embodiment describes a sixth example in which the configuration of the inter-waveguide light shielding wall in the solid-state imaging device according to the first embodiment is changed.

### 8. Eighth Embodiment

An eighth embodiment describes a seventh example in which the configuration of the inter-waveguide light shielding wall in the solid-state imaging device according to the first embodiment is changed.

### 9. Ninth Embodiment

A ninth embodiment describes an eighth example in which the configuration of the inter-waveguide light shielding wall in the solid-state imaging device according to the first embodiment is changed.

### 10. Tenth Embodiment

A tenth embodiment describes a ninth example in which the configuration of the inter-waveguide light shielding wall in the solid-state imaging device according to the first embodiment is changed.

### 11. Eleventh Embodiment

An eleventh embodiment describes a tenth example in which the configuration of the inter-waveguide light shielding wall in the solid-state imaging device according to the first embodiment is changed.

### 12. Twelfth Embodiment

A twelfth embodiment describes an eleventh example in which the configuration of the inter-waveguide light shielding wall in the solid-state imaging device according to the first embodiment is changed.

### 13. Thirteenth Embodiment

A thirteenth embodiment describes a twelfth example in which the configuration of the inter-waveguide light shielding wall in the solid-state imaging device according to the first embodiment is changed.

### 14. Fourteenth Embodiment

A fourteenth embodiment describes a thirteenth example in which the configuration of the inter-waveguide light shielding wall in the solid-state imaging device according to the first embodiment is changed.

### 15. Fifteenth Embodiment

A fifteenth embodiment describes a fourteenth example in which the configuration of the inter-waveguide light shielding wall in the solid-state imaging device according to the first embodiment is changed.

### 16. Sixteenth Embodiment

A sixteenth embodiment describes a fifteenth example in which the configuration of the inter-waveguide light shielding wall in the solid-state imaging device according to the first embodiment is changed.

### 17. Seventeenth Embodiment

A seventeenth embodiment describes a sixteenth example in which the configuration of the inter-waveguide light shielding wall in the solid-state imaging device according to the first embodiment is changed.

### 18. Eighteenth Embodiment

An eighteenth embodiment describes a seventeenth example in which the configuration of the inter-waveguide light shielding wall in the solid-state imaging device according to the first embodiment is changed.

### 19. Nineteenth Embodiment

A nineteenth embodiment describes an eighteenth example in which the configuration of the inter-waveguide light shielding wall in the solid-state imaging device according to the first embodiment is changed.

### 20. Twentieth Embodiment

A twentieth embodiment describes a nineteenth example in which the configuration of the inter-waveguide light shielding wall in the solid-state imaging device according to the first embodiment is changed.

### 21. Twenty-First Embodiment

A twenty-first embodiment describes a twentieth example in which the configuration of the inter-waveguide light shielding wall in the solid-state imaging device according to the first embodiment is changed.

### 22. Twenty-Second Embodiment

A twenty-second embodiment describes a twenty-first example in which the configuration of the inter-waveguide light shielding wall in the solid-state imaging device according to the first embodiment is changed.

### 23. Twenty-Third Embodiment

A twenty-third embodiment describes a twenty-second example in which the configuration of the inter-waveguide light shielding wall in the solid-state imaging device according to the first embodiment is changed.

### 24. Twenty-Fourth Embodiment

A twenty-fourth embodiment describes a twenty-third example in which the configuration of the inter-waveguide light shielding wall in the solid-state imaging device according to the first embodiment is changed.

### 25. Twenty-Fifth Embodiment

A twenty-fifth embodiment describes a twenty-fourth example in which the configuration of the inter-waveguide light shielding wall in the solid-state imaging device according to the first embodiment is changed.

### 26. Application Example for Mobile Object

An example of applying the present technology to a vehicle control system that is an example of a mobile object control system.

### 27. Other Embodiment

### 1. First Embodiment

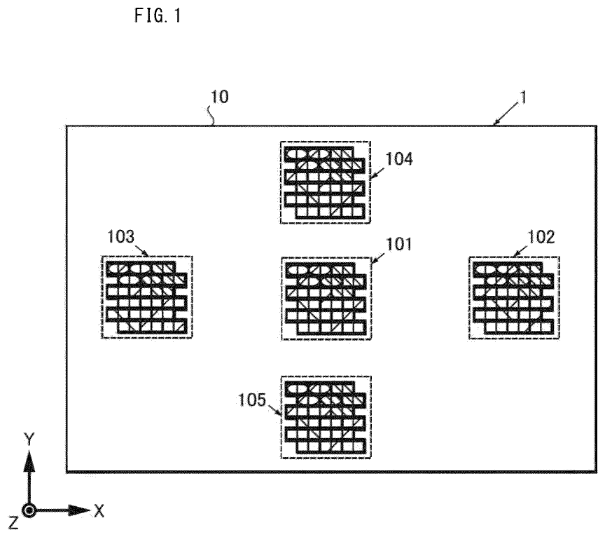

A solid-state imaging device 1 according to a first embodiment of the present disclosure is described with reference to FIGS. 1 to 7 and FIGS. 8A to 8D.

Here, an arrow X direction illustrated accordingly in the figures indicates one planar direction of the solid-state imaging device 1 mounted on a plane for convenience. An arrow Y direction indicates another planar direction orthogonal to the arrow X direction. In addition, an arrow Z direction indicates an upper direction orthogonal to the arrow X direction and the arrow Y direction. In other words, the arrow X direction, the arrow Y direction, and the arrow Z direction correspond exactly to an X-axis direction, a Y-axis direction, and a Z-axis direction of a three-dimensional coordinate system, respectively.

It is to be noted that each of these directions is illustrated to help understanding of the description, and does not limit any direction in the present technology.

### Configuration of the Solid-State Imaging Device 1

### (1) Overall Schematic Configuration of the Pixel Region 10 of the Solid-State Imaging Device 1

FIG. 1 illustrates an example of an overall planer configuration of a pixel region 10 of the solid-state imaging device 1.

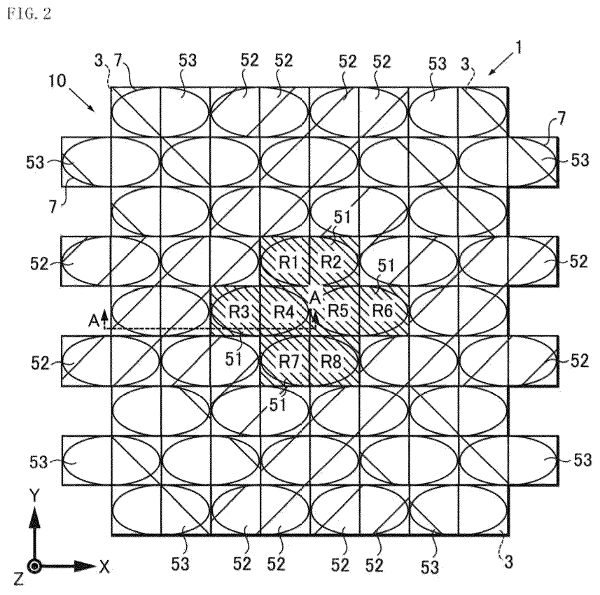

As illustrated in FIG. 1, the solid-state imaging device 1 includes the pixel region 10 in a central region. The pixel region 10 is an effective pixel region in which light receiving pixels 3 (see FIGS. 2 and 3), each of which receives entering light and generates an electrical charge from the entering light, are arranged in a plurality of arrays. The pixel region 10 includes the light receiving pixels 3 arranged in a plurality of arrays in the arrow X direction as a first direction, and the light receiving pixels 3 arranged in a plurality of arrays in the arrow Y direction that intersects with the first direction as a second direction. In other words, the pixel region 10 includes the light receiving pixels 3 arranged in in a matrix, and is formed in a rectangular shape as viewed from the arrow Z direction (hereinafter, simply referred to as “in plan view”).

In the first embodiment, the first direction is a horizontal direction of the solid-state imaging device 1. In addition, the second direction is a vertical direction of the solid-state imaging device 1.

The pixel region 10 includes an image height center 101 in the central region in the first direction, and includes an image height periphery 102 on the first direction side and an image height periphery 103 on an opposite side of the first direction centered on the image height center 101. Here, the image height periphery 102 is assumed to be a “positive image height side”. In addition, the image height periphery 103 is assumed to be a “negative image height side”.

### (2) Configuration of the Light Receiving Pixel 3

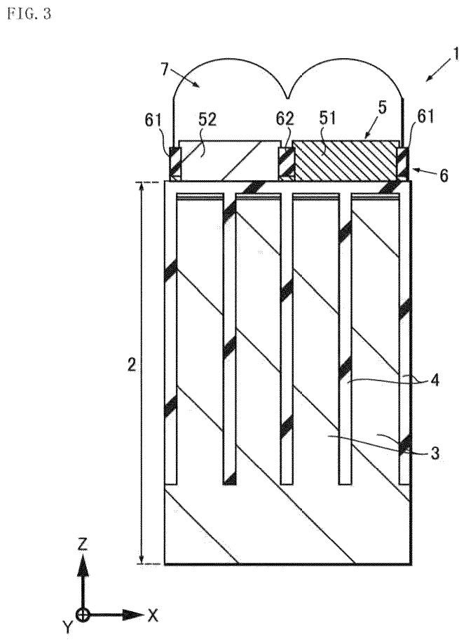

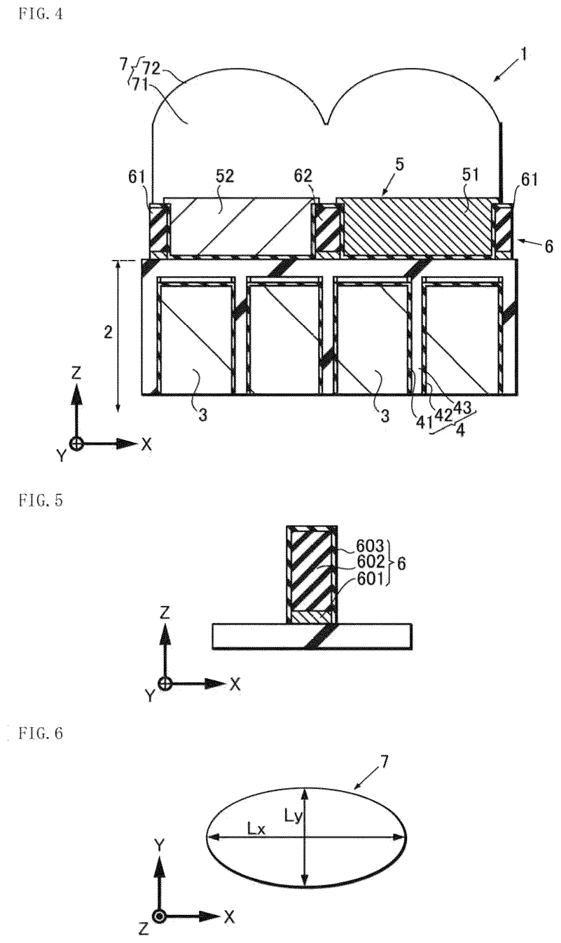

FIG. 2 illustrates an example of a planer configuration of a main portion of the pixel region 10 in the solid-state imaging device 1. For a more detailed description, FIG. 2 illustrates an example of an array configuration of the light receiving pixel 3 and an array configuration of a color filter 5. FIG. 3 illustrates an example of a cross-sectional configuration of a main portion of the pixel region 10 in the solid-state imaging device 1. FIG. 3 is a cross-sectional configuration taken along a section line A-A illustrated in FIG. 2. FIG. 4 illustrates an example of a cross-sectional configuration in which a further important portion in FIG. 3 is enlarged. FIG. 5 illustrates an example of a cross-sectional configuration of an inter-waveguide light shielding wall 6 disposed between each color filter 5. FIG. 6 illustrates an example of a planar configuration of a lens 7 disposed on the color filter 5.

As illustrated in FIGS. 2 to 6, the solid state imaging device 1 includes the light receiving pixel 3, an inter-pixel light shielding wall 4, the color filter 5, the inter-waveguide light shielding wall 6, and the lens 7.

As illustrated in FIGS. 3 and 4, the light receiving pixel 3 is provided on a substrate 2. Here, the substrate 2 includes a semiconductor layer including silicon (Si). For example, when viewed from the arrow Y direction (hereinafter, simply referred to as “in side view”), the substrate 2 has a thickness of 2 μm or more and 6 μm or less in the arrow Z direction.

The light receiving pixel 3 includes, although not illustrated, a photodiode (Photo Diode) formed at a p-n junction between a p-type semiconductor region and an n-type semiconductor region. As illustrated in FIG. 2, the light receiving pixel 3 is formed in a rectangular shape in plan view, to have one side coinciding with the arrow X direction and another adjacent side coinciding with the arrow Y direction. Here, the planar shape of the light receiving pixel 3 is formed into a square shape. For example, one side of the light receiving pixel 3 has a length of 0.4 μm or more and 1.3 μm or less.

### (3) Configuration of Inter-Pixel Light Shielding Wall 4

As illustrated in FIGS. 2 and 3, the inter-pixel light shielding wall 4 is provided between a plurality of light receiving pixels 3 arranged in the first direction and a plurality of light receiving pixels 3 arranged in the second direction. The inter-pixel light shielding wall 4 includes a groove 41, an inner wall insulator 42, and a separating member 43.

The groove 41 is formed in the substrate 2 in the arrow Z direction along a side surface of the light receiving pixel 3. Here, in the inter-pixel light shielding wall 4 provided between each light receiving pixel 3 arranged in the first direction, the groove 41 has, for example, a width (length) of 50 nm or more and 170 nm or less in the same direction. In addition, the groove 41 has, for example, a depth of 2 μm or more and 6 μm or less. In the inter-pixel light shielding wall 4 provided between each light receiving pixel 3 arranged in the second direction, the width in the same direction of the groove 41 is the same as the width of the groove 41 in the inter-pixel light shielding wall 4 provided between each light receiving pixel 3 arranged in the first direction. In addition, each groove has the same depth.

The inner wall insulator 42 includes, for example, aluminum oxide (AlO₂). In addition, for example, the separator 43 includes silicon oxide (SiO₂).

Although not illustrated, wiring, a circuit, or the like is provided below the light receiving pixel 3 in the substrate 2. For a more detailed description, the circuit includes, for example, a drive circuit that drives the light receiving pixel 3, a readout circuit that reads a signal from the light receiving pixel 3, a signal processing circuit that processes a signal, a control circuit that controls various circuits, or the like. These circuits are coupled by wiring.

### (4) Configuration of the Color Filter 5

The color filter 5 is disposed above the substrate 2, that is, over the light receiving pixel 3. In the first embodiment, the color filter 5 includes a first color filter 51, a second color filter 52, and a third color filter 53.

Here, the first color filter 51 is a color filter having, for example, a red color as a first color. The second color filter 52 is a color filter having, for example, a green color as a second color different from the first color. Then, the third color filter 53 is a color filter having, for example, a blue color as a third color different from the first color and the second color (see FIG. 2). In other words, the color filter 5 is an RGB color filter.

For example, the color filter 5 has a thickness of 400 nm or more and 600 nm or less.

As illustrated in FIG. 2, the first color filter 51 is disposed over a plurality of light receiving pixels 3 arranged in the first direction. In the first embodiment, one first color filter 51 is disposed over two light receiving pixels 3. That is, the first color filter 51 has a length corresponding to two light receiving pixels 3 in the first direction and a length corresponding to one light receiving pixel 3 in the second direction, and is formed in a rectangular shape long in the first direction in plan view.

Similar to the first color filter 51, one second color filter 52 is disposed over a plurality of light receiving pixels 3 arranged in the first direction. In other words, the second color filter 52 is formed in the same rectangular shape as the first color filter 51 in plan view.

Similar to the first color filter 51 and the second color filter 52, one third color filter 53 is disposed over a plurality of light receiving pixels 3 arranged in the first direction. The third color filter 53 is formed in the same rectangular shape as each of the first color filter 51 and the second color filter 52 in plan view.

Another first color filter 51 having the same color and being adjacent to the first color filter 51 in the second direction is disposed with a shift in the first direction by an interval of an array of the light receiving pixel 3. In addition, the second color filter 52 having a different color and being adjacent to the first color filter 51 in the second direction is disposed with a shift in the first direction by an interval of an array of the light receiving pixel 3.

Similarly, another second color filter 52 having the same color and being adjacent to the second color filter 52 in the second direction is disposed in the first direction by an interval of an array of the light receiving pixels 3. In addition, a third color filter 53 having a different color and being adjacent to the second color filter 52 in the second direction is disposed with a shift in the first direction by an interval of an array of the light receiving pixel 3.

Then, another third color filter 53 having the same color and being adjacent to the third color filter 53 in the second direction is disposed with a shift in the first direction by an interval of an array of the light receiving pixel 3. In addition, a first color filter 51 having a different color and being adjacent to the third color filter 53 in the second direction is disposed with a shift in the first direction by an interval of an array of the light receiving pixels 3.

As illustrated in FIG. 2, in the solid-state imaging device 1 according to the first embodiment, two types of pixel blocks are arranged alternately in each of the first and second directions, although no particular reference sign is attached. Here, a red pixel block or a blue pixel block is one of the two types of pixel blocks. A green pixel block is another type of pixel block.

In one pixel block, one first color filter 51, two first color filters 51 adjacent to each other in the first direction, and one first color filter 51 are each sequentially arranged in the second direction. In other words, the one pixel block includes a total of four first color filters 51 and is formed in a cross shape in plan view.

In addition, similarly, in one pixel block, one third color filter 53, two third color filters 53 adjacent to each other in the first direction, and one third color filter 53 are each sequentially arranged in the second direction. In other words, the one pixel block includes a total of four third color filters 53 and is formed in a cross shape in plan view.

In another pixel block, two second color filters 52 adjacent to each other in the first direction, one second color filter 52, and two second color filters 52 adjacent to each other in the first direction are each sequentially arranged in the second direction. In other words, the other pixel block includes a total of five second color filters 52 and is formed in an H-shape in plan view.

### (5) Configuration of the Lens 7

As illustrated in FIGS. 2 to 4 and FIG. 6, the lens 7 is provided on a side of the color filter 5 opposite from the light receiving pixel 3. The lens 7 includes a lens body 71 and an anti-reflective film 72 formed on a surface of the lens body 71. The lens 7 is integrally formed above a plurality of light receiving pixels 3 in the pixel region 10, to be configured as an on-chip lens disposed on the color filter 5.

The lens 7 is disposed for each first color filter 51, each second color filter 52, and each third color filter 53. As illustrated in FIG. 6, for example, the lens 7 disposed on the first color filter 51 has the first direction as a long axis Lx and has the second direction as a short axis Ly with respect to the long axis Lx. The long axis Lx has a length corresponding to two light receiving pixels 3, and the short axis Ly has a length corresponding to one light receiving pixel 3. In other words, the lens 7 has a small aspect ratio in the second direction with respect to the first direction. Here, the aspect ratio is set to 2 to 1.

Furthermore, as illustrated in FIGS. 3 and 4, the lens 7 is formed in a shape that protrudes and curves toward the opposite side of the light receiving pixel 3 in side view. This causes the lens 7 to collect entering light that enters from the arrow Z direction at the light receiving pixel 3.

The lens 7 disposed on each of the second color filter 52 and the third color filter 53 has the same configuration as the lens 7 disposed on the first color filter 51.

### (6) Configuration of the Inter-Waveguide Light Shielding Wall 6

As illustrated in FIGS. 2 to 5, the inter-waveguide light shielding wall 6 is provided between each color filter 5. The inter-waveguide light shielding wall 6 has a lower light transmittance than the color filter 5 and the lens 7, and has a light-shielding property.

As illustrated in detail in FIG. 5, in the first embodiment, the inter-waveguide light shielding wall 6 includes a barrier metal 601, a light-shielding wall body 602, and a protective film 603 in side view. The barrier metal 601 includes a material that increases adhesion between a base and the light-shielding wall body 602, and has a light-shielding property.

The barrier metal 601 is formed using, for example, one or more materials selected from titanium (Ti), titanium nitride (TiN), tantalum (Ta), and tantalum nitride (TaN). Here, for example, Ti is used as the barrier metal 601. In addition, the barrier metal 601 may also include a composite film in which Ti is laminated on TiN or a composite film in which TiN is laminated on Ti. For example, the barrier metal 601 has a thickness of 10 nm or more and 100 nm or less.

The light-shielding wall body 602 is laminated on the barrier metal 601. The light-shielding wall body 602 is formed using, for example, SiO₂ having a higher light-shielding property than the color filter 5. In addition, the light-shielding wall body 602 may also include a material having a lower refractive index than SiO₂, for example, a porous material including silica. For example, the light-shielding wall body 602 has a thickness of 100 nm or more and 400 nm or less.

The protective film 603 is laminated on the light-shielding wall body 602. The protective film 603 improves an environmental tolerance of each of the barrier metal 601 and the light-shielding wall body 602, and is formed using, for example, SiO₂. For example, the protective film 603 has a thickness of 5 nm or more and 50 nm or less.

As illustrated in FIGS. 3 and 4, the inter-waveguide light shielding wall 6 is formed to have a height in the arrow Z direction smaller than the thickness of the color filter 5 in the same direction. Here, the inter-waveguide light shielding wall 6 has a height of, for example, 300 nm or more and 600 nm or less.

### Relationship Between the Image Height and Photosensitivity of the Solid-State Imaging Device 1

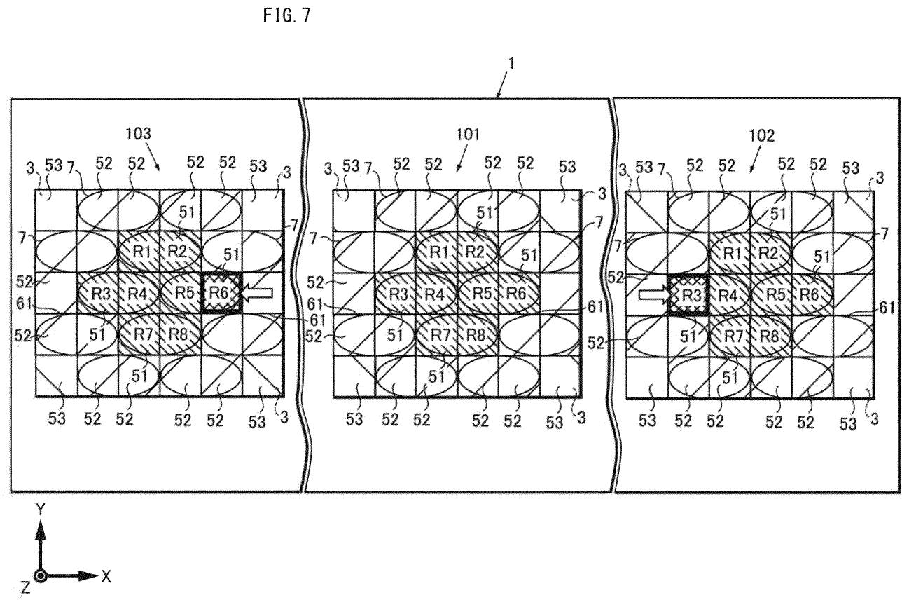

FIG. 7 illustrates an example of a relationship between image height and photosensitivity in the pixel region 10 illustrated in FIG. 1.

Here, as illustrated in FIG. 7, for convenience, a symbol is given to a pixel block in which the first color filter 51 having a red color is provided. That is, in FIG. 7 where the first color filter 51 is provided, “R1” is given to the light receiving pixel 3 on a left side in an upper row, and “R2” is given to the light receiving pixel 3 on a right side in the upper row. From a right side in a middle row to a left side in the middle row, “R3”, “R4”, “R5”, and “R6” are sequentially given to the respective light receiving pixels 3. Then, “R7” is given to the light receiving pixel 3 on a left side in a lower row, and “R8” is given to the light receiving pixel 3 on a right side in the lower row.

At the image height center 101 of the pixel region 10 (see FIG. 1), almost no amount of shift in photosensitivity occurs in the light receiving pixels 3 denoted by the symbols “R1” to “R8”.

In contrast, at the image height periphery 102, which is to be the positive image height side of the pixel region 10, the amount of shift in photosensitivity is increased on the negative side, particularly in the light receiving pixel 3 denoted by the symbol “R3”, as compared with the other light receiving pixels 3 denoted by the symbols “1”, “2”, and “4” to “8”. In other words, the light receiving pixel 3 including the first color filter 51 and denoted by “R3” is more affected by color mixing from a side of the light receiving pixel 3 on which the second color filter 52 is provided adjacent in the first direction. In addition, an output of the light receiving pixel 3 is increased. At the image height periphery 102, color mixing is generated significantly as an offset distance from the image height center 101 increases.

Similarly, at the image height periphery 103, which is to be the negative image height side of the pixel region 10, the amount of shift in photosensitivity is increased on the positive side, particularly in the light receiving pixel 3 denoted by a symbol “R5”, as compared with other light receiving pixels 3 denoted by the symbols “1” to “5”, “7”, and “8”. In other words, the light receiving pixel 3 provided with the first color filter 51 and denoted by “R6” is more affected by color mixing from a side of the light receiving pixel 3 on which the second color filter 52 is provided adjacent in the first direction. In addition, an output of light receiving pixel 3 is increased. Similarly, at the image height periphery 103, color mixing is generated significantly as the offset distance from the image height center 101 increases.

### Configuration of the Inter-Waveguide Light Shielding Wall 6 With Amount of Shift in Photosensitivity Corrected

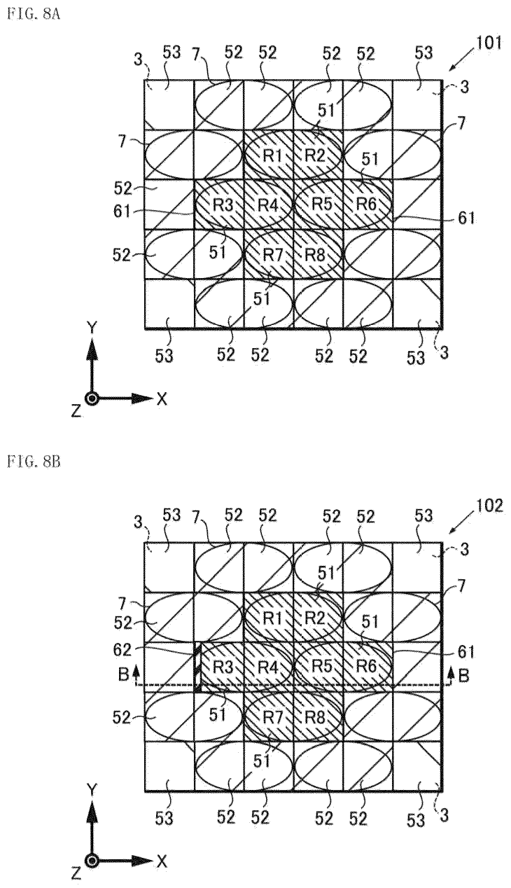

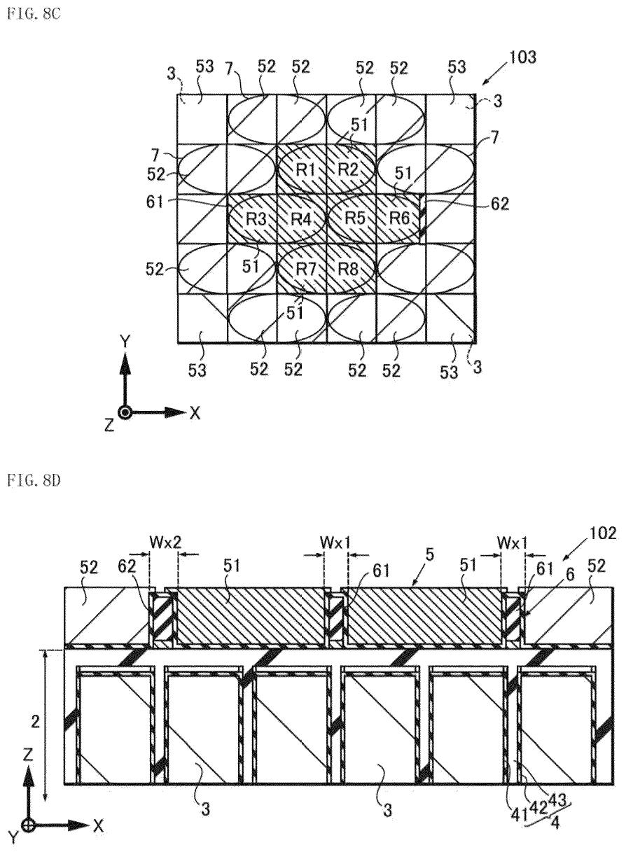

FIG. 8A illustrates an example of an enlarged planar configuration of the image height center 101 of the pixel region 10. FIG. 8B illustrates an example of an enlarged planar configuration of the image height periphery 102 on the positive image height side of the pixel region 10. FIG. 8C illustrates an example of an enlarged planar configuration of the image height periphery 103 on the negative image height side of the pixel region 10. Then, FIG. 8D illustrates an example of an enlarged cross-sectional configuration of the image height periphery 102 of the pixel region 10 illustrated in FIG. 8B.

In the pixel region 10 illustrated in FIG. 1, as illustrated in FIGS. 8A to 8D, a first inter-waveguide light shielding wall 61 and a second inter-waveguide light shielding wall 62 are provided as the inter-waveguide light shielding wall 6.

As illustrated in FIG. 8A, at the image height center 101, the first inter-waveguide light shielding wall 61 is provided between the first color filter 51 provided at the light receiving pixel 3 denoted by “R3” and the second color filter 52 adjacent to this first color filter 51 in the first direction. In addition, at the image height center 101, the first inter-waveguide light shielding wall 61 is provided between the first color filter 51 provided at the light receiving pixel 3 denoted by “R6” and the second color filter 52 adjacent to this first color filter 51 in the first direction.

In addition, at the image height center 101, the first inter-waveguide light shielding wall 61 is provided between each of the first color filter 51, the second color filter 52, and the third color filter 53 in the first direction and the second direction.

Furthermore, at the image height periphery 102 as illustrated in FIGS. 8B and 8D, the first inter-waveguide light shielding wall 61 is also provided between the first color filter 51 provided at the light receiving pixel 3 denoted by “R6” and the second color filter 52 adjacent to this first color filter 51 in the first direction. Similarly, at the image height periphery 103 as illustrated in FIG. 8C, the first inter-waveguide light shielding wall 61 is also provided between the first color filter 51 provided at the light receiving pixel 3 denoted by “R3” and the second color filter 52 adjacent to this first color filter 51 in the first direction.

A width Wx1 (thickness) in the first direction of the first inter-waveguide light shielding wall 61 is set to a smallest dimension in the pixel region 10. For example, the width Wx1 of the first inter-waveguide light shielding wall 61 is 150 nm or more and 170 nm or less. Here, a width (Wy1) in the second direction of the first inter-waveguide light shielding wall 61 is the same as the width Wx1, although this is to be described in detail in the thirteenth and subsequent embodiments.

As illustrated in FIGS. 8B and 8D, at the image height periphery, 102 the second inter-waveguide light shielding wall 62 is provided between the first color filter 51 provided at the light receiving pixel 3 denoted by “R3” and the second color filter 52 adjacent to this first color filter 51 in the first direction. In other words, at the image height periphery 102 on the positive image height side, the second inter-waveguide light shielding wall 62 is provided between the first color filter 51 provided at the light receiving pixel 3 at a left end in a middle row of the pixel block and the second color filter 52.

In addition, at the image height periphery 103 as illustrated in FIG. 8C, the second inter-waveguide light shielding wall 62 is provided between the first color filter 51 provided at the light receiving pixel 3 denoted by “R6” and the second color filter 52 adjacent to this first color filter 51 in the first direction. In other words, at the image height periphery 103 on the negative image height side, the second inter-waveguide light shielding wall 62 is provided between the first color filter 51 provided at the light receiving pixel 3 at a right end in the middle row of the pixel block and the second color filter 52.

At the image height periphery 102, in a region other than where the second inter-waveguide light shielding wall 62 is provided, the first inter-waveguide light shielding wall 61 is provided between each of the first color filter 51, the second color filter 52, and the third color filter 53 in the first direction and the second direction. Similarly, at the image height periphery 103, in a region other than where the second inter-waveguide light shielding wall 62 is provided, the first inter-waveguide light shielding wall 61 is provided between each of the first color filter 51, the second color filter 52, and the third color filter 53 in the first direction and the second direction.

A width Wx2 in the first direction of the second inter-waveguide light shielding wall 62 is set greater than the width Wx1 of the first inter-waveguide light shielding wall 61 in the same direction. For example, the width Wx2 of the second inter-waveguide light shielding wall 62 is 160 nm or more and 250 nm or less.

The width Wx2 of the second inter-waveguide light shielding wall 62 is a dimension at a predetermined position at each of the image height periphery 102 and the image height periphery 103. In other words, for example, the width Wx2 is a dimension at one of an entire region of the image height periphery 102, an intermediate region of the image height periphery 102 in the first direction, a left side region of the image height periphery 102 in the first direction, and a right side region of the image height periphery 102 in the first direction.

Basically, the width Wx2 extends from the image height center 101 to the image height periphery 102 as the offset distance from the image height center 101 increases. Similarly, the width Wx2 extends from the image height center 101 to the image height periphery 103 as the offset distance from the image height center 101 increases. An amount of increase in the width Wx2 may be linear per pixel block or may be stepwise for each plurality of pixel blocks.

Alternatively expressed, the width Wx2 of the second inter-waveguide light shielding wall 62 is configured to vary appropriately within a dimensional range from the width Wx1 to the width Wx2.

### Workings and Effects

As illustrated in FIGS. 1 to 5, the solid-state imaging device 1 according to the first embodiment includes the pixel region 10, the first color filter 51, and the second color filter 52. The pixel region 10 includes light receiving pixels 3 arranged in a plurality of arrays in the first direction and in the second direction that intersects with the first direction. The first color filter 51 is disposed over a plurality of light receiving pixels 3 arranged in the first direction and has a first color. The second color filter 52 is disposed over a plurality of light receiving pixels 3 arranged in the first direction and has a second color different from the first color.

Here, as illustrated in FIGS. 1 to 5 and FIGS. 8A to 8D, the solid-state imaging device 1 includes the first inter-waveguide light shielding wall 61 and the second inter-waveguide light shielding wall 62.

The first inter-waveguide light shielding wall 61 is provided between the first color filter 51 and the second color filter 52 at the image height center 101 of the pixel region 10 and has a light-shielding property. The second inter-waveguide light shielding wall 62 is provided between the first color filter 51 and the second color filter 52 at each of the image height periphery 102 and the image height periphery 103 located away from the image height center 101 of the pixel region 10, and has a light-shielding property. Furthermore, the width Wx2 of the second inter-waveguide light shielding wall 62 is greater than the width Wx1 of the first inter-waveguide light shielding wall 61 in the same direction.

Thus, as a result of providing the second inter-waveguide light shielding wall 62 having a greater width at each of the image height periphery 102 and the image height periphery 103 where the amount of shift in photosensitivity is greater than at the image height center 101 (see FIG. 7), it is possible to effectively suppress or prevent color mixing. This makes it possible to improve autofocus performance of the solid-state imaging device 1.

In addition, in the solid-state imaging device 1, as illustrated in FIGS. 8A to 8D, the second inter-waveguide light shielding wall 62 is provided between the first color filter 51 and the second color filter 52 disposed closer to the image height center 101 side than this first color filter 51. Between the first color filter 51 and the second color filter 52 disposed on the opposite side of the image height center 101, the first inter-waveguide light shielding wall 61 having the width Wx1 smaller than the width Wx2 of the second inter-waveguide light shielding wall 62 is provided. Thus, it is possible to increase a light receiving area (opening area) of the light receiving pixel 3 at each of the image height periphery 102 and the image height periphery 103, as compared with a case in a case where all of the inter-waveguide light shielding walls 6 provided are the second inter-waveguide light shielding walls 62. This makes it possible to improve a quantum efficiency of the solid-state imaging device 1.

In addition, in the solid-state imaging device 1, as illustrated in FIGS. 8A to 8D, the second inter-waveguide light shielding wall 62 is provided between the first color filter 51 and the second color filter 52 that are provided in the first direction. At each of the image height periphery 102 and the image height periphery 103, the first inter-waveguide light shielding wall 61 is provided between the first color filter 51 and the second color filter 52 in the second direction. Thus, it is possible to increase the light receiving area of the light receiving pixel 3 at each of the image height periphery 102 and the image height periphery 103, as compared with a case where all of the inter-waveguide light shielding walls 6 provided are the second inter-waveguide light shielding walls 62. This makes it possible to improve the quantum efficiency of the solid-state imaging device 1.

In addition, in the solid-state imaging device 1, as illustrated in FIGS. 8A to 8D, in the second inter-waveguide light shielding wall 62, the width Wx2 is increased as the offset distance from the image height center 101 increases (see FIG. 7).

Thus, color mixing is limited in response to the increase in the amount of shift in photosensitivity, to prevent excessive reduction in the light receiving area of the light receiving pixel 3. This makes it possible for the solid-state imaging device 1 to effectively suppress or prevent color mixing and also improve the quantum efficiency.

In addition, in the solid-state imaging device 1, as illustrated in FIG. 1 and FIGS. 8A to 8D, the pixel region 10 includes the image height periphery (first image height periphery) 102 and the image height periphery (second image height periphery) 103. The image height periphery 102 is located away from the image height center 101. The image height periphery 103 is located away from the image height center 101 on the opposite side of the image height periphery 102.

This makes it possible to effectively suppress or prevent color mixing in the solid-state imaging device 1 at each of the image height periphery 102 on the positive image height side and the image height periphery 103 on the negative image height side.

In addition, in the solid-state imaging device 1, as illustrated in FIG. 1 and FIGS. 8A to 8D, the width Wx2 of the second inter-waveguide light shielding wall 62 provided at the image height periphery 102 has the same dimension as the width Wx2 of the second inter-waveguide light shielding wall 62 provided at the image height periphery 103.

This makes it possible to suppress or prevent color mixing equally and effectively in the solid-state imaging device 1 at each of the image height periphery 102 on the positive image height side and the image height periphery 103 on the negative image height side.

### 2. Second Embodiment

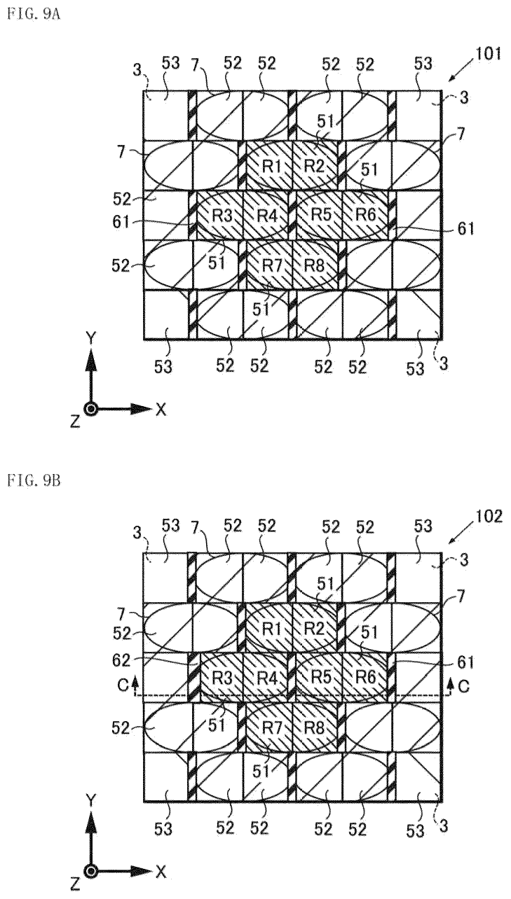

A solid-state imaging device 1 according to a second embodiment of the present disclosure is described with reference to FIGS. 9A to 9D. The solid-state imaging device 1 according to the second embodiment describes an example in which the configuration of the first inter-waveguide light shielding wall 61 and the second inter-waveguide light shielding wall 62 of the solid-state imaging device 1 according to the first embodiment is changed. It is to be noted that in the second and subsequent embodiments, the same or substantially the same components as those of the solid-state imaging device 1 according to the first embodiment will be denoted by the same reference numerals, and duplicate description will be omitted.

### Configuration of the Solid-State Imaging Device 1

FIG. 9A illustrates an example of an enlarged planar configuration of the image height center 101 of the pixel region 10 (see FIG. 1). FIG. 9B illustrates an example of an enlarged planar configuration of the image height periphery 102 on the positive image height side of the pixel region 10. FIG. 9C illustrates an example of an enlarged planar configuration of the image height periphery 103 on the negative image height side of the pixel region 10. Then, FIG. 9D illustrates an example of an enlarged cross-sectional configuration of the image height periphery 102 of the pixel region 10 illustrated in FIG. 9B.

In the solid-state imaging device 1 according to the second embodiment, as illustrated in FIGS. 9A to 9D, the first inter-waveguide light shielding wall 61 and the second inter-waveguide light shielding wall 62 are provided as the inter-waveguide light shielding wall 6 in the pixel region 10 illustrated in FIG. 1.

Similar to the solid-state imaging device 1 according to the first embodiment, as illustrated in FIG. 9A, the first inter-waveguide light shielding wall 61 is provided between the first color filter 51 and the second color filter 52 arranged adjacent to each other in the first direction at the image height center 101.

In addition, the first inter-waveguide light shielding wall 61 is also provided between each of the first color filter 51 and the second color filters 52 arranged adjacent to each other in the second direction at the image height center 101.

The first inter-waveguide light shielding wall 61 provided in the first direction is set to a width Wx3 that is greater than the width Wx1 and the width Wx2 of the second inter-waveguide light shielding wall 62. For example, the width Wx3 of the first inter-waveguide light shielding wall 61 is 280 nm or more and below 300 nm. In addition, the first inter-waveguide light shielding wall 61 provided in the second direction is set to the width Wy1 that is the same as the width Wx1.

As illustrated in FIGS. 9B and 8D, at the image height periphery 102, the second inter-waveguide light shielding wall 62 is provided between the first color filter 51 provided at the light receiving pixel 3 denoted by “R3” and the second color filter 52 adjacent to this first color filter 51 in the first direction.

In addition, at the image height periphery 103 as illustrated in FIG. 9C, the second inter-waveguide light shielding wall 62 is provided between the first color filter 51 provided at the light receiving pixel 3 denoted by “R6” and the second color filter 52 adjacent to this first color filter 51 in the first direction.

At the image height periphery 102, in a region other than where the second inter-waveguide light shielding wall 62 is provided, the first inter-waveguide light shielding wall 61 is provided between each of the first color filter 51, the second color filter 52, and the third color filter 53 in the first direction and the second direction. Similarly, at the image height periphery 103, in a region other than where the second inter-waveguide light shielding wall 62 is provided, the first inter-waveguide light shielding wall 61 is provided between each of the first color filter 51, the second color filter 52, and the third color filter 53 in the first direction and the second direction.

The second inter-waveguide light shielding wall 62 is set to a width Wx4 that is greater than the width Wx3 of the first inter-waveguide light shielding wall 61. For example, the width Wx4 of the second inter-waveguide light shielding wall 62 is 300 nm or more and 390 nm or less. In addition, at each of the image height periphery 102 and the image height periphery 103, the first inter-waveguide light shielding wall 61 is provided in a region other than where the second inter-waveguide light shielding wall 62 is provided. In the first direction, the first inter-waveguide light shielding wall 61 is set to the width Wx3. In addition, in the second direction, the first inter-waveguide light shielding wall 61 is set to the width Wx1.

Components other than those mentioned above are the same or substantially the same as those of the solid-state imaging device 1 according to the first embodiment described above.

### Workings and Effects

For the solid-state imaging device 1 according to the second embodiment, it is possible to obtain workings and effects similar to those obtained by the solid-state imaging device 1 according to the first embodiment.

In addition, in the solid-state imaging device 1, as illustrated in FIGS. 9A to 9D, the first inter-waveguide light shielding wall 61 is set to the width Wx3 that is greater than the width Wx1 and the width Wx2 in the first direction at each of the image height center 101, the image height periphery 102, and the image height periphery 103.

Thus, in a region other than where the second inter-waveguide light shielding wall 62 is provided, it is also possible to effectively suppress or prevent color mixing that occurs periodically or suddenly in the light receiving pixel 3 provided at each of the image height center 101, the image height periphery 102, and the image height periphery 103.

### 3. Third Embodiment

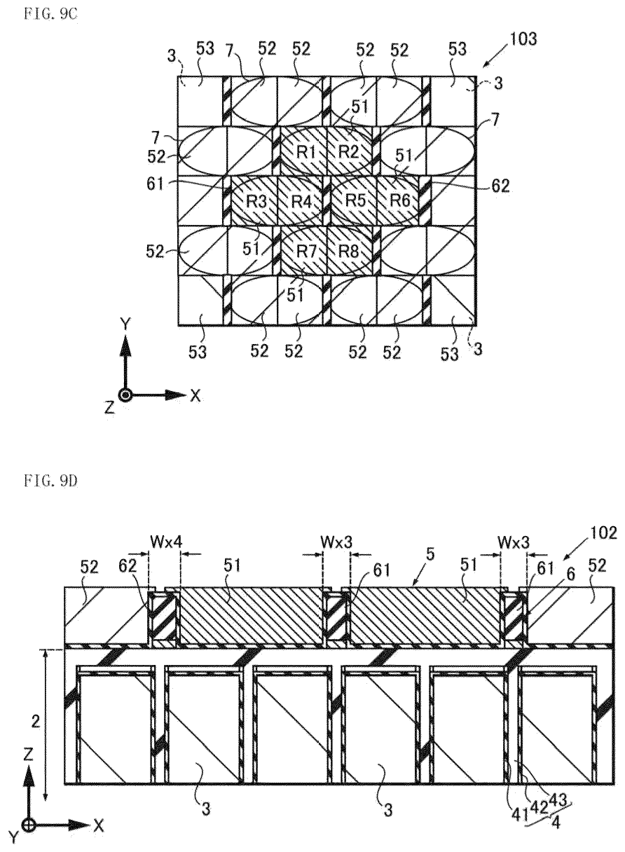

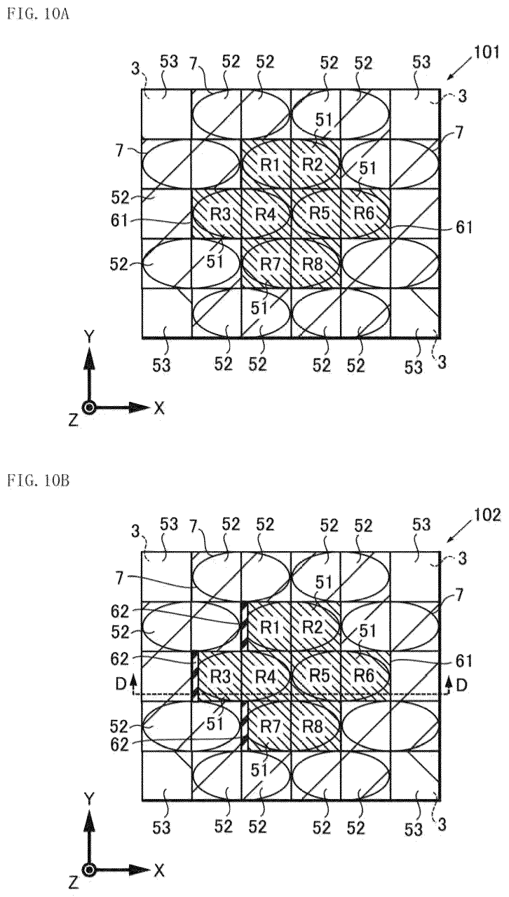

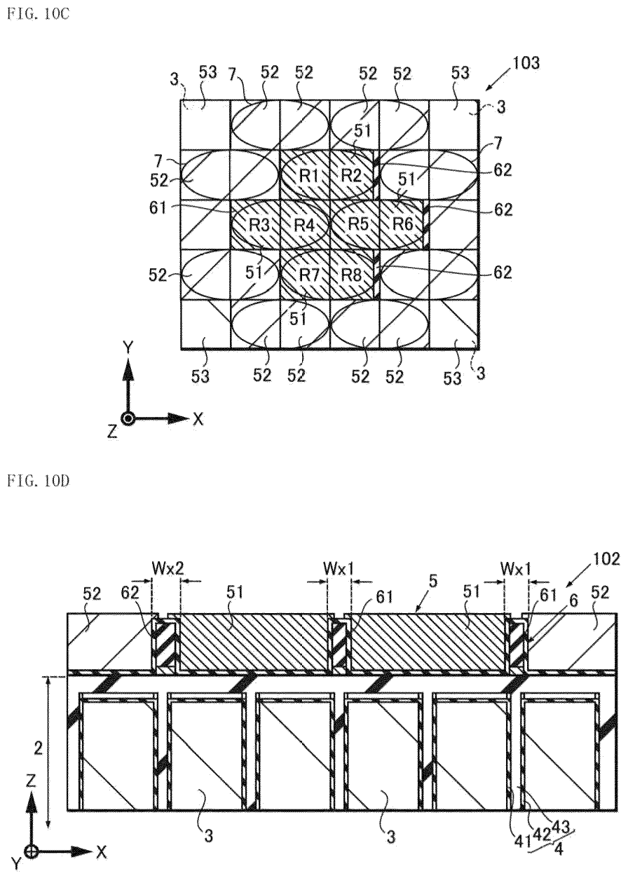

A solid-state imaging device 1 according to a third embodiment of the present disclosure is described with reference to FIGS. 10A to 10D. The solid-state imaging device 1 according to the third embodiment describes an example in which a configuration of the second inter-waveguide light shielding wall 62 of the solid-state imaging device 1 according to the first embodiment is changed.

### Configuration of the Solid-State Imaging Device 1

FIG. 10A illustrates an example of an enlarged planar configuration of the image height center 101 of the pixel region 10 (see FIG. 1). FIG. 10B illustrates an example of an enlarged planar configuration of the image height periphery 102 on the positive image height side of the pixel region 10. FIG. 10C illustrates an example of an enlarged planar configuration of the image height periphery 103 on the negative image height side of the pixel region 10. Then, FIG. 10D illustrates an example of an enlarged cross-sectional configuration of the image height periphery 102 of the pixel region 10 illustrated in FIG. 10B.

In the solid-state imaging device 1 according to the third embodiment, at the image height periphery 102 as illustrated in FIGS. 10B and 10D, the second inter-waveguide light shielding wall 62 is provided between the first color filter 51 provided at each light receiving pixel 3 denoted by “R1”, “R3”, and “R7” and the second color filter 52 adjacent in the first direction. In other words, at the image height periphery 102 on the positive image height side, the second inter-waveguide light shielding wall 62 is provided between the first color filter 51 provided at each light receiving pixel 3 at a left end in an upper row, a left end in a middle row, and a left end in a lower row of the pixel block and the second color filter 52.

In addition, at the image height periphery 103 as illustrated in FIG. 10C, the second inter-waveguide light shielding wall 62 is provided between the first color filter 51 provided at each light receiving pixel 3 denoted by “R2”, “R6”, and “R8” and the second color filter 52 adjacent in the first direction. In other words, at the image height periphery 103 on the negative image height side, the second inter-waveguide light shielding wall 62 is provided between the first color filter 51 provided at each light receiving pixel 3 at a right end in the upper row, a right end in the middle row, and a right end in the lower row of the pixel block and the second color filter 52.

The second inter-waveguide light shielding wall 62 is set to the width Wx2 in the first direction. The first inter-waveguide light shielding wall 61 is provided in a region other than where the second inter-waveguide light shielding wall 62 is provided. The first inter-waveguide light shielding wall 61 is set to the width Wx1 in the first direction.

Components other than those mentioned above are the same or substantially the same as those of the solid-state imaging device 1 according to the first embodiment described above.

### Workings and Effects

For the solid-state imaging device 1 according to the third embodiment, it is possible to obtain workings and effects similar to those obtained by the solid-state imaging device 1 according to the first embodiment.

In addition, in the solid-state imaging device 1, as illustrated in FIGS. 10A to 10D, the second inter-waveguide light shielding wall 6 is provided between all the first color filters 51 and second color filters 52 on the image center 101 side of the pixel block, at each of the image height periphery 102 and the image-height periphery 103.

This makes it possible to effectively suppress or prevent color mixing in the pixel blocks at the image height periphery 102 and the image-height periphery 103.

### 4. Fourth Embodiment

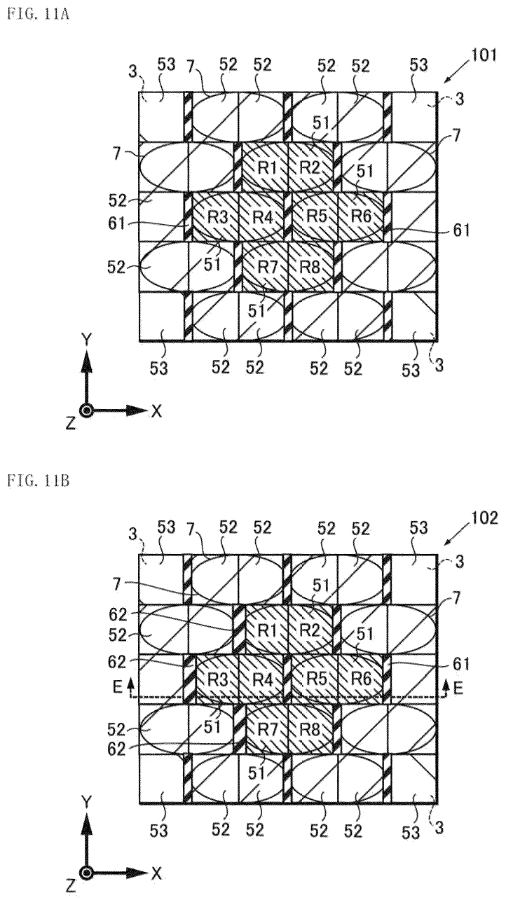

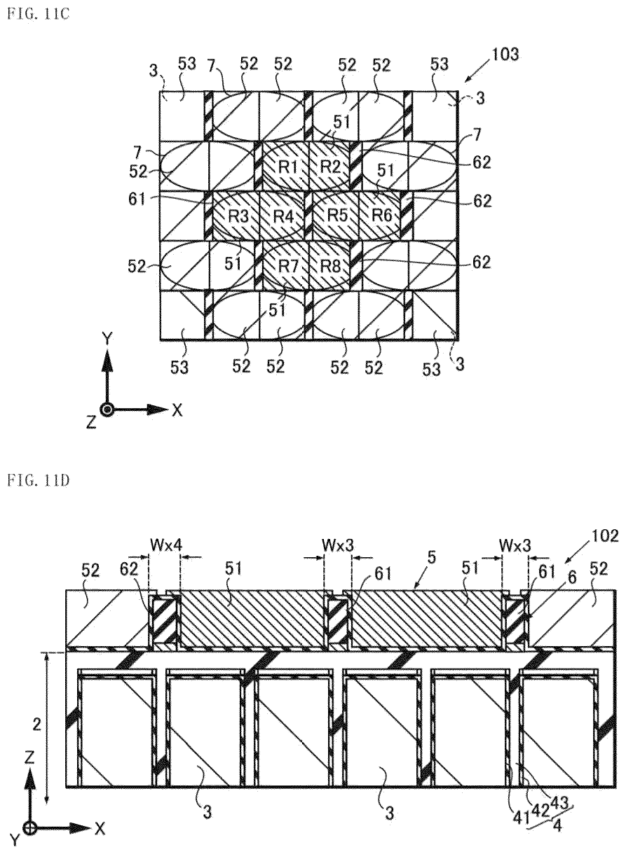

A solid-state imaging device 1 according to a fourth embodiment of the present disclosure is described with reference to FIGS. 11A to 11D. The solid-state imaging device 1 according to the fourth embodiment is an example of a combination of the solid-state imaging device 1 according to the second embodiment and the solid-state imaging device 1 according to the third embodiment.

### Configuration of the Solid-State Imaging Device 1

FIG. 11A illustrates an example of an enlarged planar configuration of the image height center 101 of the pixel region 10 (see FIG. 1). FIG. 11B illustrates an example of an enlarged planar configuration of the image height periphery 102 on the positive image height side of the pixel region 10. FIG. 11C illustrates an example of an enlarged planar configuration of the image height periphery 103 on the negative image height side of the pixel region 10. Then, FIG. 11D illustrates an example of an enlarged cross-sectional configuration of the image height periphery 102 of the pixel region 10 illustrated in FIG. 11B.

In the solid-state imaging device 1 according to the fourth embodiment, at the image height periphery 102 as illustrated in FIGS. 11B and 11D, the second inter-waveguide light shielding wall 62 is provided between the first color filter 51 provided at each light receiving pixel 3 denoted by “R1”, “R3”, and “R7” and the second color filter 52 adjacent in the first direction. In other words, at the image height periphery 102 on the positive image height side, the second inter-waveguide light shielding wall 62 is provided between the first color filter 51 provided at each light receiving pixel 3 at a left end in an upper row, a left end in a middle row, and a left end in a lower row of the pixel block and the second color filter 52.

In addition, at the image height periphery 103 as illustrated in FIG. 11C, the second inter-waveguide light shielding wall 62 is provided between the first color filter 51 provided at each light receiving pixel 3 denoted by “R2”, “R6”, and “R8” and the second color filter 52 adjacent in the first direction. In other words, at the image height periphery 103 on the negative image height side, the second inter-waveguide light shielding wall 62 is provided between the first color filter 51 provided at each light receiving pixel 3 at a right end in the upper row, a right end in the middle row, and a right end in the lower row of the pixel block and the second color filter 52.

The second inter-waveguide light shielding wall 62 is set to the width Wx4 in the first direction. The first inter-waveguide light shielding wall 61 is provided in a region other than where the second inter-waveguide light shielding wall 62 is provided. The first inter-waveguide light shielding wall 61 is set to the width Wx3 in the first direction.

Components other than those mentioned above are the same or substantially the same as those of each of the solid-state imaging device 1 according to the second embodiment and the solid-state imaging device 1 according to the third embodiment described above.

### Workings and Effects

For the solid-state imaging device 1 according to the fourth embodiment, it is possible to obtain workings and effects obtained by a combination of those obtained by the solid-state imaging device 1 according to the second embodiment and those obtained by the solid-state imaging device 1 according to the third embodiment.

### 5. Fifth Embodiment

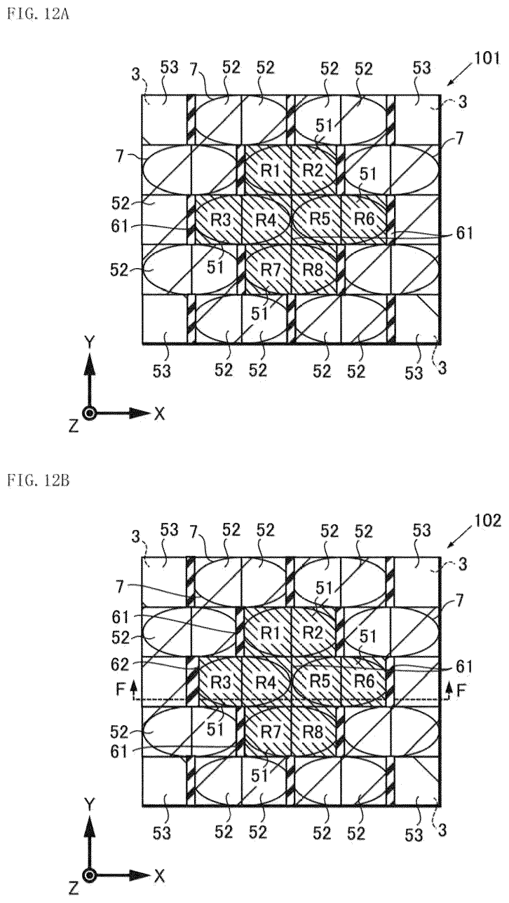

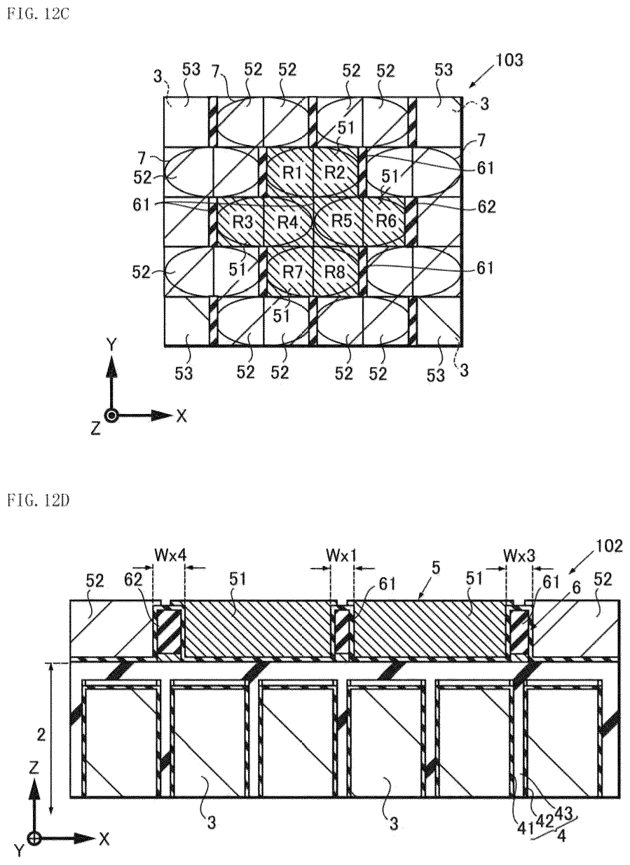

A solid-state imaging device 1 according to a fifth embodiment of the present disclosure is described with reference to FIGS. 12A to 12D. The solid-state imaging device 1 according to the fifth embodiment is an example of a combination of the solid-state imaging device 1 according to the first embodiment and the solid-state imaging device 1 according to the second embodiment.

### Configuration of the Solid-State Imaging Device 1

FIG. 12A illustrates an example of an enlarged planar configuration of the image height center 101 of the pixel region 10 (see FIG. 1). FIG. 12B illustrates an example of an enlarged planar configuration of the image height periphery 102 on the positive image height side of the pixel region 10. FIG. 12C illustrates an example of an enlarged planar configuration of the image height periphery 103 on the negative image height side of the pixel region 10. Then, FIG. 12D illustrates an example of an enlarged cross-sectional configuration of the image height periphery 102 of the pixel region 10 illustrated in FIG. 12B.

In the solid-state imaging device 1 according to the fifth embodiment, as illustrated in FIGS. 12A to 12D, the first inter-waveguide light shielding wall 61 and the second inter-waveguide light shielding wall 62 are provided as the inter-waveguide light shielding wall 6 in the pixel region 10 illustrated in FIG. 1.

Similar to the solid-state imaging device 1 according to the second embodiment, as illustrated in FIG. 12A, the first inter-waveguide light shielding wall 61 is provided between the first color filter 51 and the second color filter 52 arranged adjacent to each other in the first direction at the image height center 101.

In addition, the first inter-waveguide light shielding wall 61 is also provided between each of the first color filter 51 and the second color filter 52 arranged adjacent to each other in the second direction at the image height center 101.

The first inter-waveguide light shielding wall 61 provided in the first direction is set to the width Wx3 that is greater than the width Wx1 and the width Wx2. In addition, the first inter-waveguide light shielding wall 61 provided in the second direction is set to the width Wy1 that is the same as the width Wx1.

As illustrated in FIGS. 12B and 12D, at the image height periphery 102, the second inter-waveguide light shielding wall 62 is provided between the first color filter 51 provided at the light receiving pixel 3 denoted by “R3” and the second color filter 52 adjacent to this first color filter 51 in the first direction.

In addition, at the image height periphery 103 as illustrated in FIG. 12C, the second inter-waveguide light shielding wall 62 is provided between the first color filter 51 provided at the light receiving pixel 3 denoted by “R6” and the second color filter 52 adjacent to this first color filter 51 in the first direction.

At the image height periphery 102, in a region other than where the second inter-waveguide light shielding wall 62 is provided, the first inter-waveguide light shielding wall 61 is provided between each of the first color filter 51, the second color filter 52, and the third color filter 53 in the first direction and the second direction. Similarly, at the image height periphery 103, in a region other than where the second inter-waveguide light shielding wall 62 is provided, the first inter-waveguide light shielding wall 61 is provided between each of the first color filter 51, the second color filter 52, and the third color filter 53 in the first direction and the second direction.

The second inter-waveguide light shielding wall 62 is set to the width Wx4 that is greater than the width Wx3 of the first inter-waveguide light shielding wall 61. In addition, at each of the image height periphery 102 and the image height periphery 103, the first inter-waveguide light shielding wall 61 is provided in a region other than where the second inter-waveguide light shielding wall 62 is provided. In the first direction, the first inter-waveguide light shielding wall 61 is set to the width Wx3. In addition, in the second direction, the first inter-waveguide light shielding wall 61 is set to the width Wx1.

Then, at each of the image height center 101, the image height periphery 102, and the image height periphery 103, the first inter-waveguide light shielding wall 61 is provided between the first color filters 51 having the same color in the pixel block. This first inter-waveguide light shielding wall 61 is set to the width Wx1 that is smaller than the width Wx2, the width Wx3, and the width Wx4.

Components other than those mentioned above are the same or substantially the same as those of the solid-state imaging device 1 according to the first embodiment and the solid-state imaging device 1 according to the second embodiment described above.

It is to be noted that here, an example in which the first inter-waveguide light shielding wall 61 having the width Wx1 is provided between the first color filters 51 having the same color is described. In the present technology, the first inter-waveguide light shielding wall 61 having the width Wx1 may be provided between each second color filter 52 having the same color and between each third color filter 53 having the same color.

### Workings and Effects

For the solid-state imaging device 1 according to the fifth embodiment, it is possible to obtain workings and effects obtained by a combination of those obtained by the solid-state imaging device 1 according to the first embodiment and those obtained by the solid-state imaging device 1 according to the second embodiment.

In addition, in the solid-state imaging device 1, as illustrated in FIGS. 12A to 12D, the first inter-waveguide light shielding wall 61 is provided between the first color filters 51 having the same color in the pixel block at each of the image height center 101, the image height periphery 102, and the image height periphery 103. This first inter-waveguide light shielding wall 61 is set to the width Wx1.

Thus, it is possible to increase the light receiving area of the light receiving pixel 3 in the pixel block at each of the image height center 101, the image height periphery 102, and the image height periphery 103. This makes it possible to improve the quantum efficiency of the solid-state imaging device 1.

### 6. Sixth Embodiment

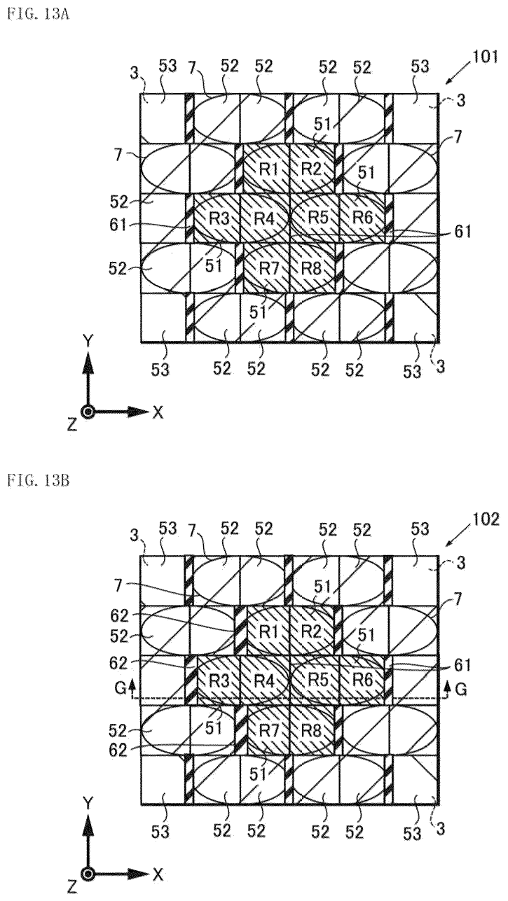

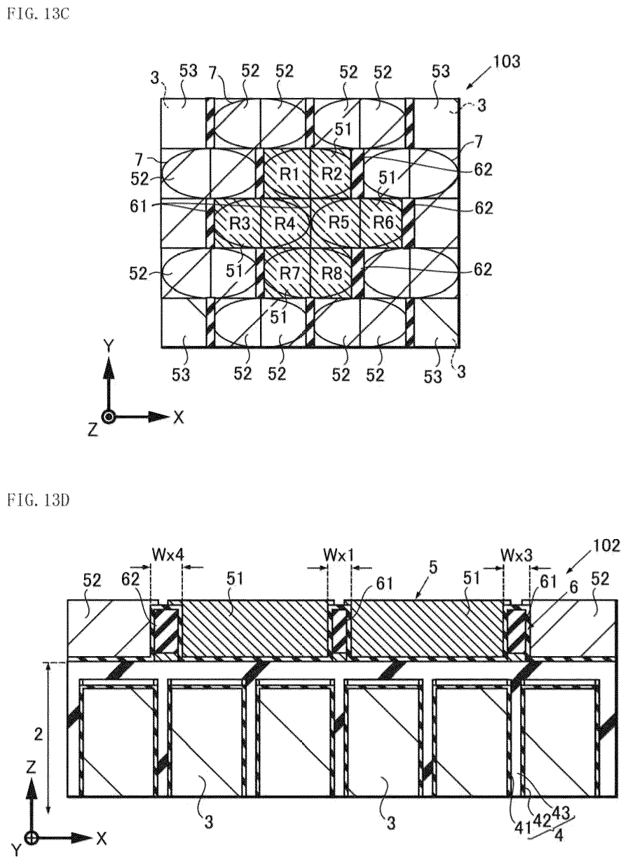

A solid-state imaging device 1 according to a sixth embodiment of the present disclosure is described with reference to FIGS. 13A to 13D. The solid-state imaging device 1 according to the sixth embodiment is an example of a combination of the solid-state imaging device 1 according to the fourth embodiment and the solid-state imaging device 1 according to the fifth embodiment.

### Configuration of the Solid-State Imaging Device 1

FIG. 13A illustrates an example of an enlarged planar configuration of the image height center 101 of the pixel region 10 (see FIG. 1). FIG. 13B illustrates an example of an enlarged planar configuration of the image height periphery 102 on the positive image height side of the pixel region 10. FIG. 13C illustrates an example of an enlarged planar configuration of the image height periphery 103 on the negative image height side of the pixel region 10. Then, FIG. 13D illustrates an example of an enlarged cross-sectional configuration of the image height periphery 102 of the pixel region 10 illustrated in FIG. 13B.

In the solid-state imaging device 1 according to the sixth embodiment, at the image height periphery 102 as illustrated in FIGS. 13B and 13D, the second inter-waveguide light shielding wall 62 is provided between the first color filter 51 provided at each light receiving pixel 3 denoted by “R1”, “R3”, and “R7”, and the second color filter 52 adjacent in the first direction. In other words, at the image height periphery 102 on the positive image height side, the second inter-waveguide light shielding wall 62 is provided between the first color filter 51 provided at each light receiving pixel 3 at a left end in an upper row, a left end in a middle row, and a left end in a lower row of the pixel block and the second color filter 52.

In addition, at the image height periphery 103 as illustrated in FIG. 13C, the second inter-waveguide light shielding wall 62 is provided between the first color filter 51 provided at each light receiving pixel 3 denoted by “R2”, “R6”, and “R8” and the second color filter 52 adjacent in the first direction. In other words, at the image height periphery 103 on the negative image height side, the second inter-waveguide light shielding wall 62 is provided between the first color filter 51 provided at each light receiving pixel 3 at a right end in the upper row, a right end in the middle row, and a right end in the lower row of the pixel block and the second color filter 52.

The second inter-waveguide light shielding wall 62 is set to the width Wx4 in the first direction. The first inter-waveguide light shielding wall 61 is provided in a region other than where the second inter-waveguide light shielding wall 62 is provided. The first inter-waveguide light shielding wall 61 is set to the width Wx3 in the first direction.

Then, at each of the image height center 101, image height periphery 102, and image height periphery 103, the first inter-waveguide light shielding wall 61 is provided between the first color filters 51 having the same color in the pixel block. This first inter-waveguide light shielding wall 61 is set to the width Wx1 that is smaller than the width Wx2, the width Wx3, and the width Wx4.

Components other than those mentioned above are the same or substantially the same as those of each of the solid-state imaging device 1 according to the fourth embodiment and the solid-state imaging device 1 according to the fifth embodiment described above.

### Workings and Effects

For the solid-state imaging device 1 according to the sixth embodiment, it is possible to obtain workings and effects obtained by a combination of those obtained by the solid-state imaging device 1 according to the fourth embodiment and those obtained by the solid-state imaging device 1 according to the fifth embodiment.

### 7. Seventh Embodiment

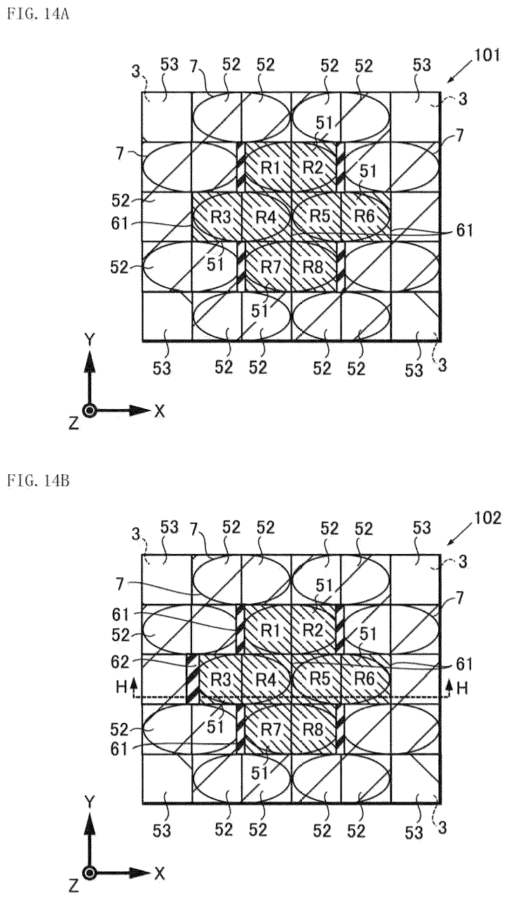

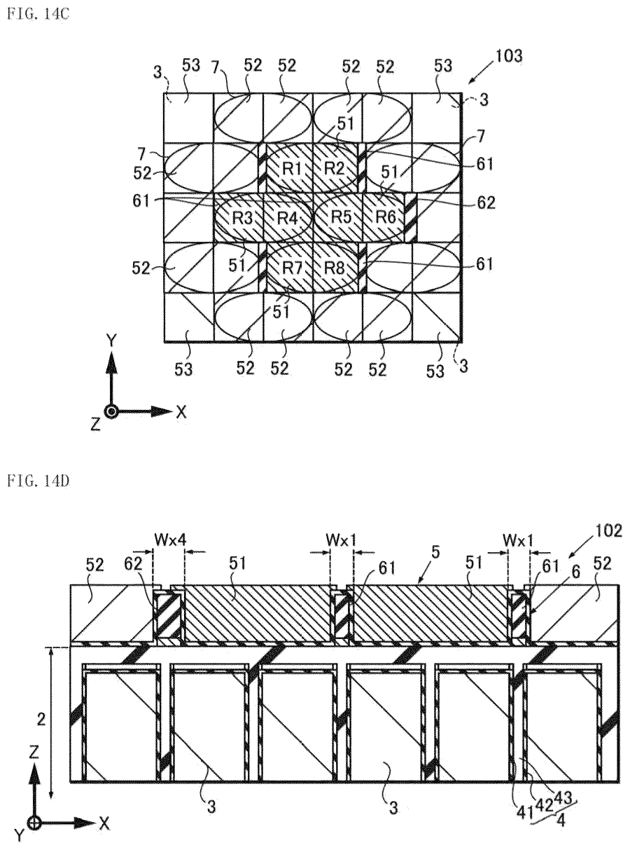

A solid-state imaging device 1 according to a seventh embodiment of the present disclosure is described with reference to FIGS. 14A to 14D. The solid-state imaging device 1 according to the seventh embodiment is an application example of the solid-state imaging device 1 according to the fifth embodiment.

### Configuration of the Solid-State Imaging Device 1

FIG. 14A illustrates an example of an enlarged planar configuration of the image height center 101 of the pixel region 10 (see FIG. 1). FIG. 14B illustrates an example of an enlarged planar configuration of the image height periphery 102 on the positive image height side of the pixel region 10. FIG. 14C illustrates an example of an enlarged planar configuration of the image height periphery 103 on the negative image height side of the pixel region 10. Then, FIG. 14D illustrates an example of an enlarged cross-sectional configuration of the image height periphery 102 of the pixel region 10 illustrated in FIG. 14B.

In the solid-state imaging device 1 according to the seventh embodiment, as illustrated in FIGS. 14A to 14D, the first inter-waveguide light shielding wall 61 and the second inter-waveguide light shielding wall 62 are provided as the inter-waveguide light shielding wall 6 in the pixel region 10 illustrated in FIG. 1.

As illustrated in FIG. 14A, at the image height center 101 of the pixel region 10, the first inter-waveguide light shielding wall 61 is provided between the first color filter 51 provided at each light receiving pixel 3 denoted by “R3” and “R4” in a middle row of the pixel block and the second color filter 52 adjacent in the first direction. Similarly, the first inter-waveguide light shielding wall 61 is provided between the first color filter 51 provided at each light receiving pixel 3 denoted by “R5” and “R6” in the middle row of the pixel block and the second color filter 52 adjacent in the first direction. Furthermore, the first inter-waveguide light shielding wall 61 is provided between each first color filter 51 in the middle row of the pixel block. These first inter-waveguide light shielding walls 61 are set to the width Wx1.

As illustrated in FIGS. 14B and 14D, at the image height periphery 102 of the pixel region 10, the second inter-waveguide light shielding wall 62 is provided between the first color filter 51 provided at each light receiving pixel 3 denoted by “R3” and “R4” in the middle row of the pixel block and the second color filter 52 adjacent in the first direction. The second inter-waveguide light shielding wall 62 is set to the width Wx4.

On the other hand, the first inter-waveguide light shielding wall 61 is provided between the first color filter 51 provided at each light receiving pixel 3 denoted by “R5” and “R6” in the middle row of the pixel block and the second color filter 52 adjacent in the first direction. Furthermore, the first inter-waveguide light shielding wall 61 is provided between each first color filter 51 in the middle row of the pixel block. These first inter-waveguide light shielding walls 61 are set to the width Wx1.

As illustrated in FIG. 14C, at the image height periphery 102 of the pixel region 10, the second inter-waveguide light shielding wall 62 is provided between the first color filter 51 provided at each light receiving pixel 3 denoted by “R5” and “R6” in the middle row of the pixel block and the second color filter 52 adjacent in the first direction. The second inter-waveguide light shielding wall 62 is set to the width Wx4.

On the other hand, the first inter-waveguide light shielding wall 61 is provided between the first color filter 51 provided at each light receiving pixel 3 denoted by “R3” and “R4” in the middle row of the pixel block and the second color filter 52 adjacent in the first direction. Furthermore, the first inter-waveguide light shielding wall 61 is provided between each first color filter 51 in the middle row of the pixel block. These first inter-waveguide light shielding walls 61 are set to the width Wx1.

Components other than those mentioned above are the same or substantially the same as those of the solid-state imaging device 1 according to the fifth embodiment described above.

### Workings and Effects

For the solid-state imaging device 1 according to the seventh embodiment, it is possible to obtain workings and effects similar to those obtained by the solid-state imaging device 1 according to the fifth embodiment.

In addition, in the solid-state imaging device 1, as illustrated in FIGS. 14A to 14D, the first inter-waveguide light shielding wall 61 is provided between the first color filter 51 and the second color filter 52 in the middle row of the pixel block at each of the image height center 101, the image height periphery 102, and the image height periphery 103. Furthermore, the first inter-waveguide light shielding wall 61 is also provided between each first color filter 51 in the middle row of the pixel block. These first inter-waveguide light shielding walls 61 are set to the width Wx1.

Thus, it is possible to increase the light receiving area (opening area) of the light receiving pixel 3 at each of the image height center 101, the image height periphery 102, and the image height periphery 103, as compared with a case where all of the inter-waveguide light shielding walls 6 provided are the second inter-waveguide light shielding walls 62. This makes it possible to improve the quantum efficiency of the solid-state imaging device 1.

### 8. Eighth Embodiment

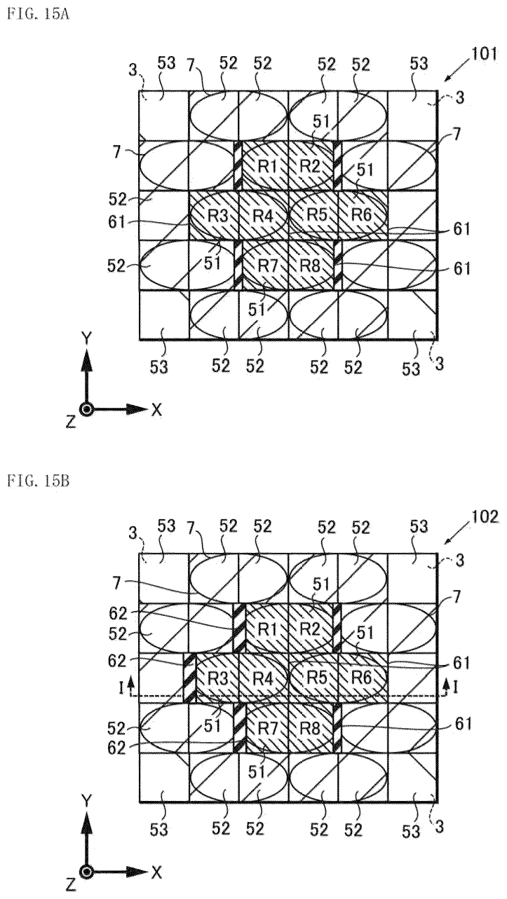

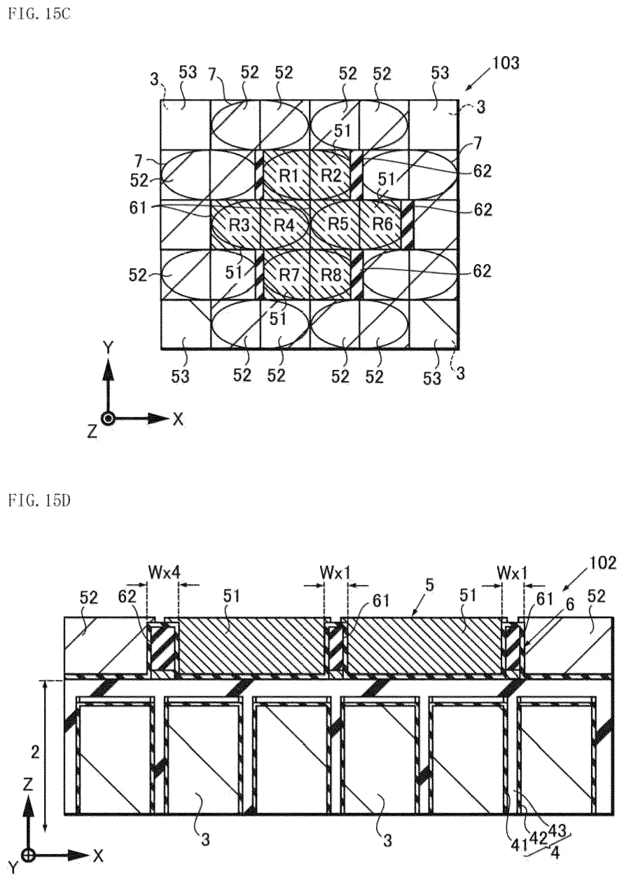

A solid-state imaging device 1 according to an eighth embodiment of the present disclosure is described with reference to FIGS. 15A to 15D. The solid-state imaging device 1 according to the eighth embodiment is an example of a combination of the solid-state imaging device 1 according to the sixth embodiment and the solid-state imaging device 1 according to the seventh embodiment.

### Configuration of the Solid-State Imaging Device 1

FIG. 15A illustrates an example of an enlarged planar configuration of the image height center 101 of the pixel region 10 (see FIG. 1). FIG. 15B illustrates an example of an enlarged planar configuration of the image height periphery 102 on the positive image height side of the pixel region 10. FIG. 15C illustrates an example of an enlarged planar configuration of the image height periphery 103 on the negative image height side of the pixel region 10. Then, FIG. 15D illustrates an example of an enlarged cross-sectional configuration of the image height periphery 102 of the pixel region 10 illustrated in FIG. 15B.

In the solid-state imaging device 1 according to the eighth embodiment, at the image height periphery 102 as illustrated in FIGS. 15B and 15D, the second inter-waveguide light shielding wall 62 is provided between the first color filter 51 provided at each light receiving pixel 3 denoted by “R1”, “R3”, and “R7” and the second color filter 52 adjacent in the first direction. In other words, at the image height periphery 102 on the positive image height side, the second inter-waveguide light shielding wall 62 is provided between the first color filter 51 provided at each light receiving pixel 3 at a left end in an upper row, a left end in a middle row, and a left end in a lower row of the pixel block and the second color filter 52.

The second inter-waveguide light shielding wall 62 is set to the width Wx4 in the first direction.

On the other hand, the first inter-waveguide light shielding wall 61 is provided between each first color filter 51 provided at the light receiving pixel 3 in the middle row of the pixel block, and between the first color filter 51 provided at a right end in the middle row and the second color filter 52.

The first inter-waveguide light shielding wall 61 is set to the width Wx1 in the first direction.

In addition, in the solid-state imaging device 1, at the image height periphery 103 as illustrated in FIG. 15C, the second inter-waveguide light shielding wall 62 is provided between the first color filter 51 provided at each light receiving pixel 3 denoted by “R2”, “R6”, and “R8” and the second color filter 52 adjacent in the first direction. In other words, at the image height periphery 103 on the negative image height side, the second inter-waveguide light shielding wall 62 is provided between the first color filter 51 provided at each light receiving pixel 3 at a right end in the upper row, a right end in the middle row, and a right end in the lower row of the pixel block and the second color filter 52.

The second inter-waveguide light shielding wall 62 is set to the width Wx4 in the first direction.

On the other hand, the first inter-waveguide light shielding wall 61 is provided between each first color filter 51 provided at the light receiving pixels 3 in the middle row of the pixel block, and between the first color filter 51 provided at the light receiving pixel 3 at a left end in the middle row of the pixel block and the second color filter 52.

The first inter-waveguide light shielding wall 61 is set to the width Wx1 in the first direction.

Components other than those mentioned above are the same or substantially the same as those of each of the solid-state imaging device 1 according to the sixth embodiment and the solid-state imaging device 1 according to the seventh embodiment described above.

### Workings and Effects

For the solid-state imaging device 1 according to the eighth embodiment, it is possible to obtain workings and effects obtained by a combination of those obtained by the solid-state imaging device 1 according to the sixth embodiment and those obtained by the solid-state imaging device 1 according to the seventh embodiment.

### 9. Ninth Embodiment

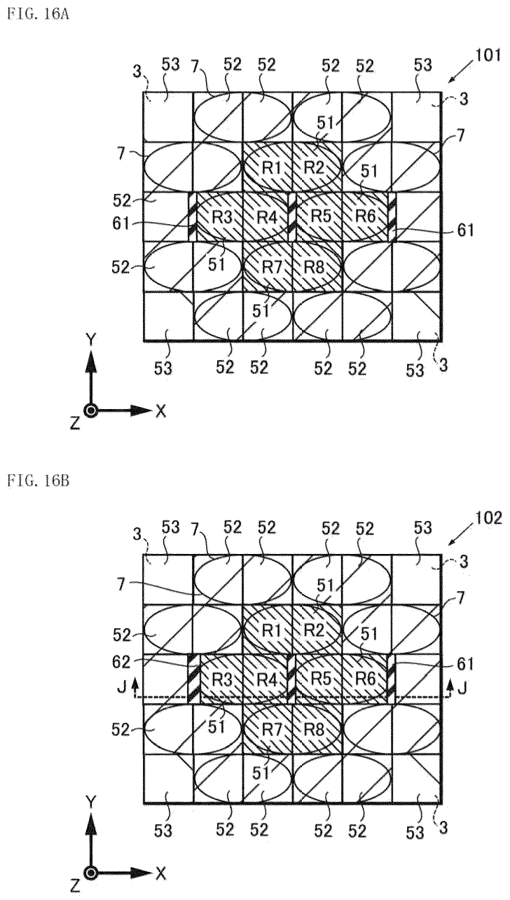

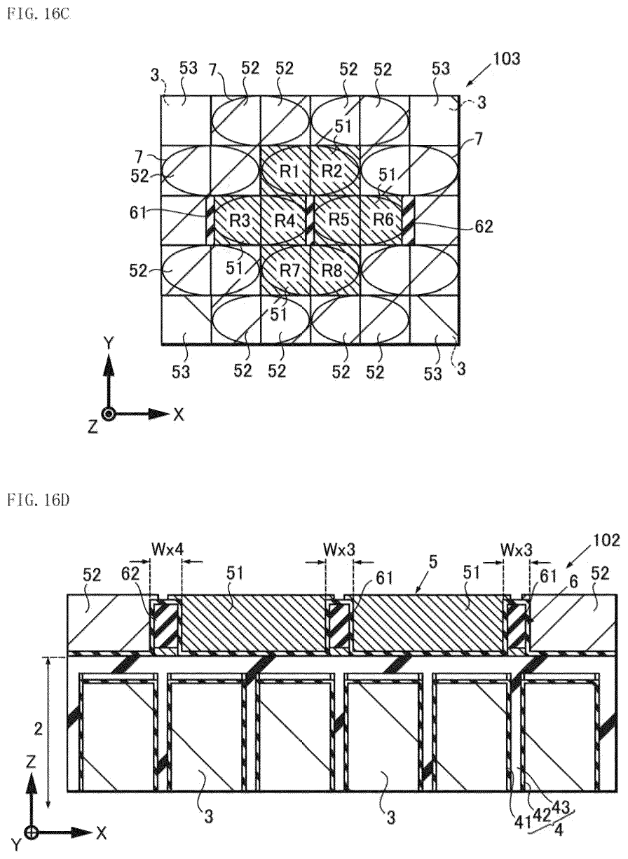

A solid-state imaging device 1 according to a ninth embodiment of the present disclosure is described with reference to FIGS. 16A to 16D. The solid-state imaging device 1 according to the ninth embodiment is an application example of the solid-state imaging device 1 according to the second embodiment.

### Configuration of the Solid-State Imaging Device 1

FIG. 16A illustrates an example of an enlarged planar configuration of the image height center 101 of the pixel region 10 (see FIG. 1). FIG. 16B illustrates an example of an enlarged planar configuration of the image height periphery 102 on the positive image height side of the pixel region 10. FIG. 16C illustrates an example of an enlarged planar configuration of the image height periphery 103 on the negative image height side of the pixel region 10. Then, FIG. 16D illustrates an example of an enlarged cross-sectional configuration of the image height periphery 102 of the pixel region 10 illustrated in FIG. 16B.

In the solid-state imaging device 1 according to the ninth embodiment, as illustrated in FIGS. 16A to 16D, the first inter-waveguide light shielding wall 61 and the second inter-waveguide light shielding wall 62 are provided as the inter-waveguide light shielding wall 6 in the pixel region 10 illustrated in FIG. 1.

In the solid-state imaging device 1, at the image height center 101 as illustrated in FIG. 16A, the first inter-waveguide light shielding wall 61 is provided between each first color filter 51 in a middle row of the pixel block and between the first color filter 51 and the second color filter 52. The first inter-waveguide light shielding wall 61 is set to the width Wx3.

At the image height center 101, the first inter-waveguide light shielding wall 61 having the width Wx1 or width Wy1 is provided in a region other than the first inter-waveguide light shielding wall 61 having the width Wx3.

On the other hand, in the solid-state imaging device 1, at the image height periphery 102 as illustrated in FIGS. 16B and 16D, the second inter-waveguide light shielding wall 62 is provided between the first color filter 51 on a left side of the middle row of the pixel block and the second color filter 52. The second inter-waveguide light shielding wall 62 is set to the width Wx4.

At the image height periphery 102, the first inter-waveguide light shielding wall 61 is provided between the first color filter 51 on a right side of the middle row of the pixel block and the second color filter 52 and between each first color filter 51 in the middle row of the pixel block. The first inter-waveguide light shielding wall 61 is set to the width Wx3.

In addition, at the image height periphery 102, the first inter-waveguide light shielding wall 61 having the width Wx1 or width Wy1 is provided in a region other than the second inter-waveguide light shielding wall 62 having the width Wx4 and the first inter-waveguide light shielding wall 61 having the width Wx3.

Similarly, in the solid-state imaging device 1, at the image height periphery 103 as illustrated in FIG. 16C, the second inter-waveguide light shielding wall 62 is provided between the first color filter 51 on the right side of the middle row of the pixel block and the second color filter 52. The second inter-waveguide light shielding wall 62 is set to the width Wx4.

At the image height periphery 103, the first inter-waveguide light shielding wall 61 is provided between the first color filter 51 on the left side of the middle row of the pixel block and the second color filter 52 and between each first color filter 51 in the middle row of the pixel block. The first inter-waveguide light shielding wall 61 is set to the width Wx3.

In addition, at the image height periphery 103, the first inter-waveguide light shielding wall 61 having the width Wx1 or width Wy1 is provided in a region other than the second inter-waveguide light shielding wall 62 having the width Wx4 and the first inter-waveguide light shielding wall 61 having the width Wx3.

Components other than those mentioned above are the same or substantially the same as those of the solid-state imaging device 1 according to the second embodiment described above.

### Workings and Effects

For the solid-state imaging device 1 according to the ninth embodiment, it is possible to obtain workings and effects similar to those obtained by the solid-state imaging device 1 according to the second embodiment.

In addition, in the solid-state imaging device 1, as illustrated in FIGS. 16A to 16D, the first inter-waveguide light shielding wall 61 is set to the width Wx1 or width Wy1 except in the middle row of the pixel block.

Thus, it is possible to increase the light receiving area (opening area) of the light receiving pixel 3 at each of the image height center 101, the image height periphery 102, and the image height periphery 103 of the pixel region 10, as compared with the solid-state imaging device 1 according to the second embodiment. This makes it possible to improve the quantum efficiency of the solid-state imaging device 1.

### 10. Tenth Embodiment

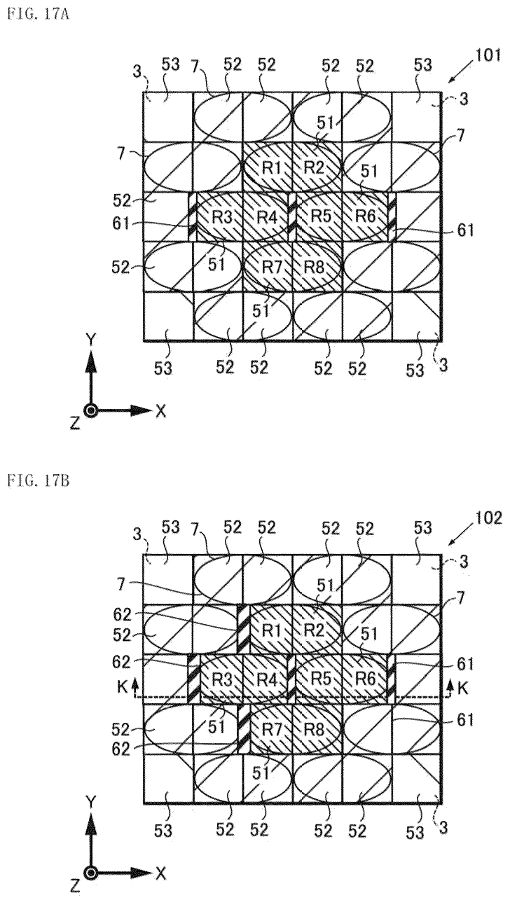

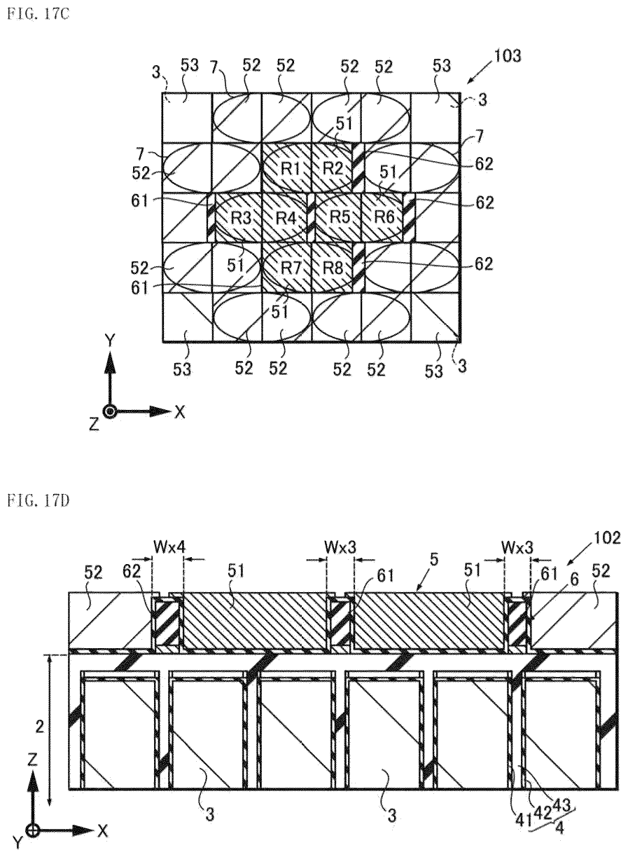

A solid-state imaging device 1 according to a tenth embodiment of the present disclosure is described with reference to FIGS. 17A to 17D. The solid-state imaging device 1 according to the tenth embodiment is an example of a combination of the solid-state imaging device 1 according to the third embodiment and the solid-state imaging device 1 according to the ninth embodiment.

### Configuration of the Solid-State Imaging Device 1

FIG. 17A illustrates an example of an enlarged planar configuration of the image height center 101 of the pixel region 10 (see FIG. 1). FIG. 17B illustrates an example of an enlarged planar configuration of the image height periphery 102 on the positive image height side of the pixel region 10. FIG. 17C illustrates an example of an enlarged planar configuration of the image height periphery 103 on the negative image height side of the pixel region 10. Then, FIG. 17D illustrates an example of an enlarged cross-sectional configuration of the image height periphery 102 of the pixel region 10 illustrated in FIG. 17B.

In the solid-state imaging device 1 according to the tenth embodiment, as illustrated in FIGS. 17A to 17D, the first inter-waveguide light shielding wall 61 and the second inter-waveguide light shielding wall 62 are provided as the inter-waveguide light shielding wall 6 in the pixel region 10 illustrated in FIG. 1.

In the solid-state imaging device 1 according to the tenth embodiment, at the image height periphery 102 as illustrated in FIGS. 17B and 17D, the second inter-waveguide light shielding wall 62 is provided between the first color filter 51 provided at each light receiving pixel 3 denoted by “R1”, “R3”, and “R7” and the second color filter 52 adjacent in the first direction. In other words, at the image height periphery 102 on the positive image height side, the second inter-waveguide light shielding wall 62 is provided between the first color filter 51 provided at each light receiving pixel 3 at a left end in an upper row, a left end in a middle row, and a left end in a lower row of the pixel block and the second color filter 52. The second inter-waveguide light shielding wall 62 is set to the width Wx4.

In addition, at the image height periphery 102, the first inter-waveguide light shielding wall 61 is provided between each first color filter 51 in the middle row of the pixel block and between the first color filter 51 at a left end in the middle row and the second color filter 52. The first inter-waveguide light shielding wall 61 is set to the width Wx3.

In addition, at the image height periphery 102, the first inter-waveguide light shielding wall 61 having the width Wx1 or width Wy1 is provided in a region other than the second inter-waveguide light shielding wall 62 having the width Wx4 and the first inter-waveguide light shielding wall 61 having the width Wx3.

On the other hand, at the image height periphery 103 as illustrated in FIG. 17C, the second inter-waveguide light shielding wall 62 is provided between the first color filter 51 provided at each light receiving pixel 3 denoted by “R2”, “R6”, and “R8” and the second color filter 52 adjacent in the first direction. In other words, at the image height periphery 103 on the negative image height side, the second inter-waveguide light shielding wall 62 is provided between the first color filter 51 provided at each light receiving pixel 3 at a right end in the upper row, a right end in the middle row, and a right end in the lower row of the pixel block and the second color filter 52. The second inter-waveguide light shielding wall 62 is set to the width Wx4.

In addition, at the image height periphery 103, the first inter-waveguide light shielding wall 61 is provided between each first color filter 51 in the middle row of the pixel block and between the first color filter 51 at the right end in the middle row and the second color filter 52. The first inter-waveguide light shielding wall 61 is set to the width Wx3.

In addition, at the image height periphery 103, the first inter-waveguide light shielding wall 61 having the width Wx1 or width Wy1 is provided in a region other than the second inter-waveguide light shielding wall 62 having the width Wx4 and the first inter-waveguide light shielding wall 61 having the width Wx3.

Components other than those mentioned above are the same or substantially the same as those of each of the solid-state imaging device 1 according to the third embodiment and the solid-state imaging device 1 according to the ninth embodiment described above.

### Workings and Effects

For the solid-state imaging device 1 according to the tenth embodiment, it is possible to obtain workings and effects obtained by a combination of those obtained by the solid-state imaging device 1 according to the third embodiment and those obtained by the solid-state imaging device 1 according to the ninth embodiment.

### 11. Eleventh Embodiment

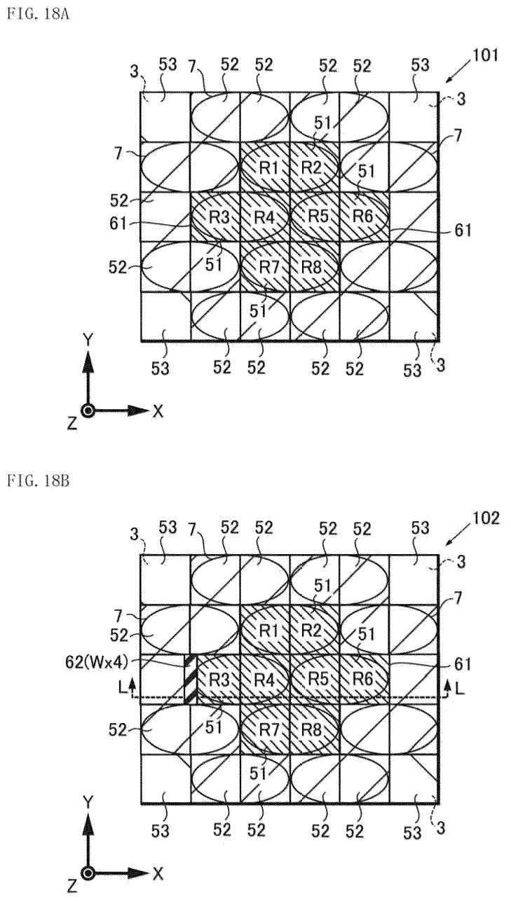

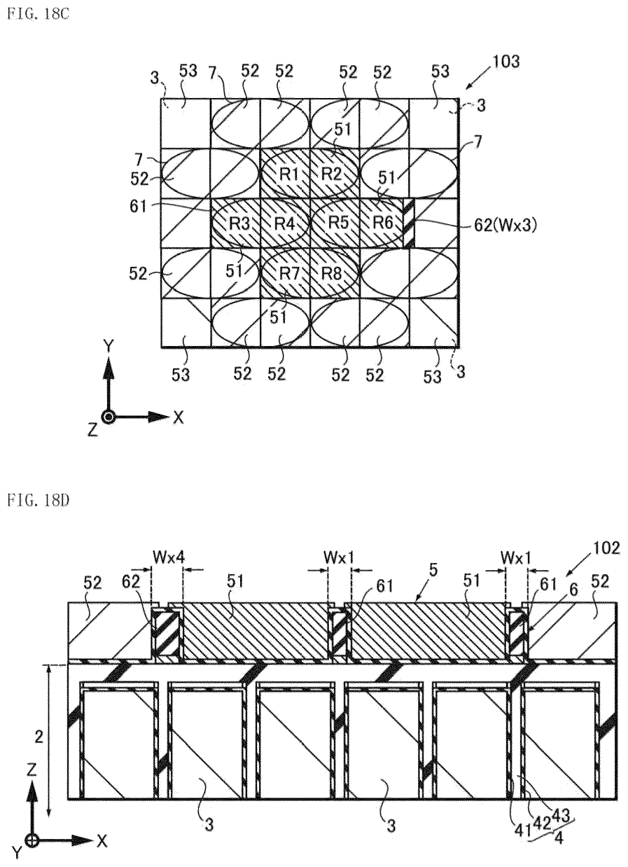

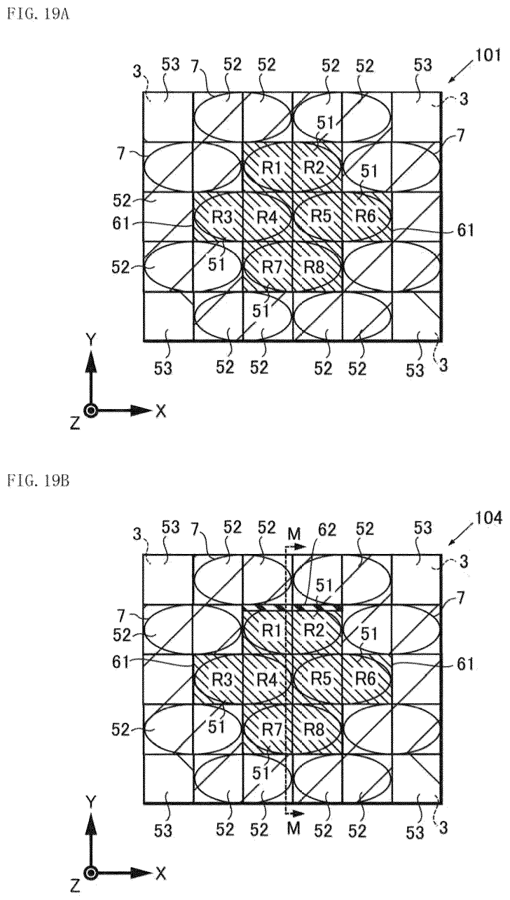

A solid-state imaging device 1 according to an eleventh embodiment of the present disclosure is described with reference to FIGS. 18A to 18D. The solid-state imaging device 1 according to the eleventh embodiment is an application example of the solid-state imaging device 1 according to the first embodiment.

### Configuration of the Solid-State Imaging Device 1

FIG. 18A illustrates an example of an enlarged planar configuration of the image height center 101 of the pixel region 10 (see FIG. 1). FIG. 18B illustrates an example of an enlarged planar configuration of the image height periphery 102 on the positive image height side of the pixel region 10. FIG. 18C illustrates an example of an enlarged planar configuration of the image height periphery 103 on the negative image height side of the pixel region 10. Then, FIG. 18D illustrates an example of an enlarged cross-sectional configuration of the image height periphery 102 of the pixel region 10 illustrated in FIG. 18B.

In the solid-state imaging device 1 according to the eleventh embodiment, as illustrated in FIGS. 18A to 18D, the first inter-waveguide light shielding wall 61 and the second inter-waveguide light shielding wall 62 are provided as the inter-waveguide light shielding wall 6 in the pixel region 10 illustrated in FIG. 1.

In the solid-state imaging device 1, at the image height periphery 102 of the pixel region 10 as illustrated in FIGS. 18B and 18D, the second inter-waveguide light shielding wall 62 is provided between the first color filter 51 provided at the light receiving pixel 3 denoted by “R3” and the second color filter 52 adjacent in the first direction. In other words, at the image height periphery 102 on the positive image height side, the second inter-waveguide light shielding wall 62 is provided between the first color filter 51 provided at the light receiving pixel 3 at the left end in a middle row of the pixel block and the second color filter 52. For example, the second inter-waveguide light shielding wall 62 is set to the width Wx4.

On the other hand, at the image height periphery 103 of the pixel region 10, the second inter-waveguide light shielding wall 62 is provided between the first color filter 51 provided at the light receiving pixel 3 denoted by “R6” and the second color filter 52 adjacent in the first direction. In other words, at the image height periphery 103 on the negative image height side, the second inter-waveguide light shielding wall 62 is provided between the first color filter 51 provided at the light receiving pixel 3 at a right end in the middle row of the pixel block and the second color filter 52. For example, the second inter-waveguide light shielding wall 62 is set to the width Wx3 that is smaller than the width Wx4.

Alternatively expressed, the second inter-waveguide light shielding wall 62 provided at each of the image height periphery 102 and the image height periphery 103 has a different width.

Components other than those mentioned above are the same or substantially the same as those of the solid-state imaging device 1 according to the first embodiment described above.

### Workings and Effects

For the solid-state imaging device 1 according to the eleventh embodiment, it is possible to obtain workings and effects similar to those obtained by the solid-state imaging device 1 according to the first embodiment.

In addition, in the solid-state imaging device 1, it is possible to effectively suppress or prevent color mixing at the image height periphery 102 on one side of the pixel regions 10.

### 12. Twelfth Embodiment

A solid-state imaging device 1 according to a twelfth embodiment of the present disclosure is described with reference to FIG. 2 and FIGS. 8A to 8D described above. The solid-state imaging device 1 according to the twelfth embodiment is an application example of the solid-state imaging device 1 according to the first embodiment.

Although not illustrated, in the solid-state imaging device 1 according to the twelfth embodiment, the second inter-waveguide light shielding wall 62 is provided between each second color filter 52 at each of the image height periphery 102 and the image height periphery 103 of the solid-state imaging device 1 according to the first embodiment.

In addition, in the solid-state imaging device 1 according to the twelfth embodiment, the second inter-waveguide light shielding wall 62 is provided between each third color filter 53 at each of the image height periphery 102 and the image height periphery 103 of the solid-state imaging device 1 according to the first embodiment.

In addition, in the solid-state imaging device 1 according to the twelfth embodiment, the second inter-waveguide light shielding wall 62 is provided between the second color filter and the third color filter 53 at each of the image height periphery 102 and the image height periphery 103 of the solid-state imaging device 1 according to the first embodiment. In addition, at each of the image height periphery 102 and the image height periphery 103, the second inter-waveguide light shielding wall 62 is provided between the second color filter and the third color filter 53.

Components other than those mentioned above are the same or substantially the same as those of the solid-state imaging device 1 according to the first embodiment described above.

### Workings and Effects

For the solid-state imaging device 1 according to the twelfth embodiment, it is possible to obtain workings and effects similar to those obtained by the solid-state imaging device 1 according to the first embodiment.

Furthermore, in the solid-state imaging device 1, the second inter-waveguide light shielding wall 62 is provided except between the first color filter 51 and the second color filter 52 at each of the image height periphery 102 and the image-periphery 103. This makes it possible for the solid-state imaging device 1 to effectively suppress or prevent color mixing.

### Thirteenth Embodiment

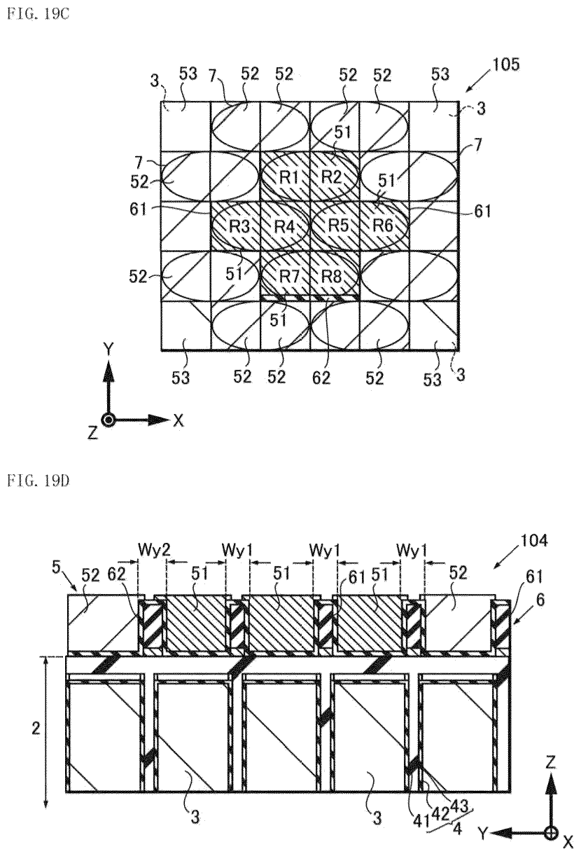

A solid-state imaging device 1 according to a thirteenth embodiment of the present disclosure is described with reference to FIGS. 19a to 19d.

The solid-state imaging device 1 according to the thirteenth embodiment is an application example of the solid-state imaging device 1 according to the first embodiment. In the solid-state imaging device 1 according to the first to twelfth embodiments described above, a configuration of the image height periphery 102 and the image height periphery 103 in the first direction centered on the image height center 101 in the pixel region 10 is described. In the thirteenth and subsequent embodiments, a configuration of each of an image height periphery 104 on the positive image height side and an image height periphery 105 on the negative image height side in the second direction centered on the image height center 101 in the pixel region 10, is described.

### Configuration of the Solid-State Imaging Device 1

FIG. 19A illustrates an example of an enlarged planar configuration of the image height center 101 of the pixel region 10. FIG. 19B illustrates an example of an enlarged planar configuration of the image height periphery 104 on the positive image height side of the pixel region 10. FIG. 19C illustrates an example of an enlarged planar configuration of the image height periphery 105 on the negative image height side of the pixel region 10. Then, FIG. 19D illustrates an example of an enlarged cross-sectional configuration of the image height periphery 104 of the pixel region 10 Illustrated in FIG. 19b.

In the pixel region 10 illustrated in FIG. 1, as illustrated in FIGS. 19A to 19D, the first inter-waveguide light shielding wall 61 and the second inter-waveguide light shielding wall 62 are provided as the inter-waveguide light shielding wall 6.

As illustrated in FIG. 19A, at the image height center 101, the first inter-waveguide light shielding wall 61 is provided between the first color filter 51 provided at each light receiving pixel 3 denoted by “R1” and “R2” and the second color filter 52 adjacent to this first color filter 51 in the second direction. In addition, at the image height center 101, the first inter-waveguide light shielding wall 61 is provided between the first color filter 51 provided at each light receiving pixel 3 denoted by “R7” and “R8” and the second color filter 52 adjacent to this first color filter 51 in the second direction.

In addition, at the image height center 101, the first inter-waveguide light shielding wall 61 is provided between each of the first color filter 51, the second color filter 52, and the third color filter 53 in the first direction and the second direction.

Furthermore, at the image height periphery 104 as illustrated in FIGS. 19B and 19D, the first inter-waveguide light shielding wall 61 is also provided between the first color filter 51 provided at each light receiving pixel 3 denoted by “R1” and “R2” and the second color filter 52 adjacent to this first color filter 51 in the second direction. Similarly, at the image height periphery 105 as illustrated in FIG. 19C, the first inter-waveguide light shielding wall 61 is also provided between the first color filter 51 provided at each light receiving pixel 3 denoted by “R7” and “R8” and the second color filter 52 adjacent to this first color filter 51 in the second direction. The width Wy1 in the second direction of the inter-waveguide light shielding wall 61 is the same as the width Wx1 in the first direction described above.

As illustrated in FIGS. 19B and 19D, at the image height periphery 104, the second inter-waveguide light shielding wall 62 is provided between the first color filter 51 provided at each light receiving pixel 3 denoted by “R1” and “R2” and the second color filter 52 adjacent to this first color filter 51 in the second direction. In other words, at the image height periphery 104 on the positive image height side, the second inter-waveguide light shielding wall 62 is provided between the first color filter 51 provided at the light receiving pixel 3 in an upper row of the pixel block and the second color filter 52.

In addition, at the image height periphery 105 as illustrated in FIG. 19C, the second inter-waveguide light shielding wall 62 is provided between the first color filter 51 provided at each light receiving pixel 3 denoted by “R7” and “R8” and the second color filter 52 adjacent to this first color filter 51 in the second direction. In other words, at the image height periphery 105 on the negative image height side, the second inter-waveguide light shielding wall 62 is provided between the first color filter 51 provided at the light receiving pixel 3 in a lower row of the pixel block and the second color filter 52.

At the image height periphery 104, the first inter-waveguide light shielding wall 61 is provided between each of the first color filter 51, the second color filter 52, and the third color filter 53 in the first direction and the second direction in a region other than where the second inter-waveguide light shielding wall 62 is provided. Similarly, at the image height periphery 105, the first inter-waveguide light shielding wall 61 is provided between each of the first color filter 51, the second color filter 52, and the third color filter 53 in the first direction and the second direction in a region other than where the second inter-waveguide light shielding wall 62 is provided.

A width Wy2 in the second direction of the second inter-waveguide light shielding wall 62 is the same as the width Wx2 in the first direction described above.

The width Wy2 of the second inter-waveguide light shielding wall 62 is a dimension at a predetermined position at each of the image height periphery 104 and the image height periphery 105. In other words, for example, the width Wy2 is a dimension at one of an entire region of the image height periphery 102, an intermediate region of the image height periphery 104 in the second direction, an upper region of the image height periphery 104 in the second direction, and a lower region of the image height periphery 104 in the second direction.

Basically, similar to the width Wx2, the width Wy2 extends from the image height center 101 to the image height periphery 104 as the offset distance from the image height center 101 increases. Similarly, the width Wy2 extends from the image height center 101 to the image height periphery 105 as the offset distance from the image height center 101 increases. An amount of increase in width Wy2 may be linear per pixel block or stepwise per each plurality of pixel blocks.

Alternatively expressed, the width Wy2 of the second inter-waveguide light shielding wall 62 is configured to vary accordingly within a dimensional range from the width Wy1 to the width Wy2.

Components other than those mentioned above are the same or substantially the same as those of the solid-state imaging device 1 according to the first embodiment described above.

### Workings and Effects

As illustrated in FIGS. 1 to 5, the solid-state imaging device 1 according to the thirteenth embodiment includes the pixel region 10, the first color filter 51, and the second color filter 52. The pixel region 10 includes light receiving pixels 3 arranged in a plurality of arrays in the first direction and the second direction that intersects with the first direction. The first color filter 51 is disposed over a plurality of light receiving pixels 3 arranged in the first direction and has a first color. The second color filter 52 is disposed over a plurality of light receiving pixels 3 arranged in the first direction and has a second color different from the first color.

Here, as illustrated in FIGS. 1 to 5 and FIGS. 19A to 19D, the solid-state imaging device 1 has the first inter-waveguide light shielding wall 61 and the second inter-waveguide light shielding wall 62.

The first inter-waveguide light shielding wall 61 is provided between the first color filter 51 and the second color filter 52 at the image height center 101 of the pixel region 10 and has a light-shielding property. The second inter-waveguide light shielding wall 62 is provided between the first color filter 51 and the second color filter 52 at each of the image height periphery 104 and the image height periphery 105 located away from the image height center 101 of the pixel region 10, and has a light-shielding property. Furthermore, the width Wy2 of the second inter-waveguide light shielding wall 62 is greater than the width Wy1 of the first inter-waveguide light shielding wall 61 in the same direction.

Thus, as a result of providing the second inter-waveguide light shielding wall 62 having a greater width at each of the image height periphery 104 and the image height periphery 105 where the amount of shift in photosensitivity is greater than at the image height center 101 (see FIG. 7), it is possible to effectively suppress or prevent color mixing. This makes it possible to improve autofocus performance of the solid-state imaging device 1.

In addition, in the solid-state imaging device 1, as illustrated in FIGS. 19A to 19D, the first inter-waveguide light shielding wall 61 is provided in a region other than where the second inter-waveguide light shielding wall 62 is provided at each of the image height periphery 104 and the image height periphery 105. The width Wy1 of the first inter-waveguide light shielding wall 61 is smaller than the width Wy2 of the second inter-waveguide light shielding wall 62.

Thus, it is possible to increase the light receiving area of the light receiving pixel 3 at each of the image height periphery 104 and the image height periphery 105, as compared with a case where all of the inter-waveguide light shielding walls 6 provided are the second inter-waveguide light shielding walls 62. This makes it possible to improve the quantum efficiency of the solid-state imaging device 1.

Workings and effects other than those described above are similar to those obtained by the solid-state imaging device 1 according to the first embodiment.

### 14. Fourteenth Embodiment

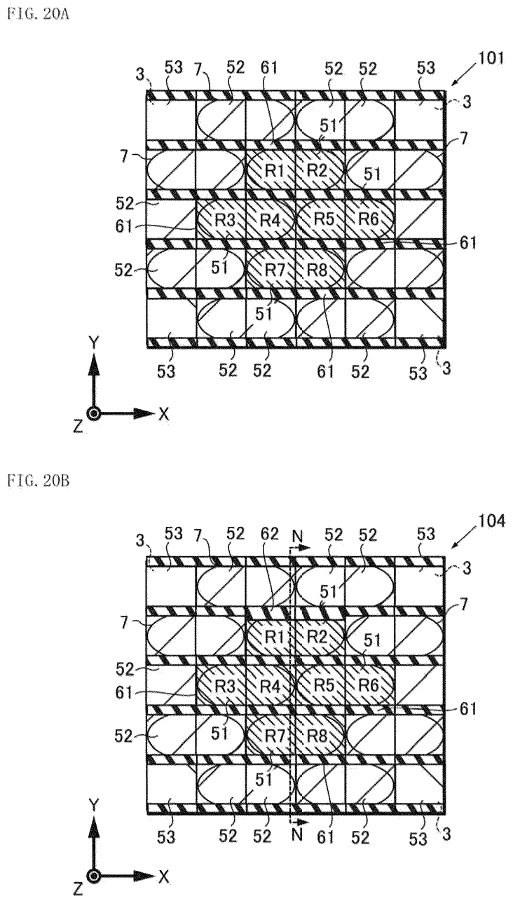

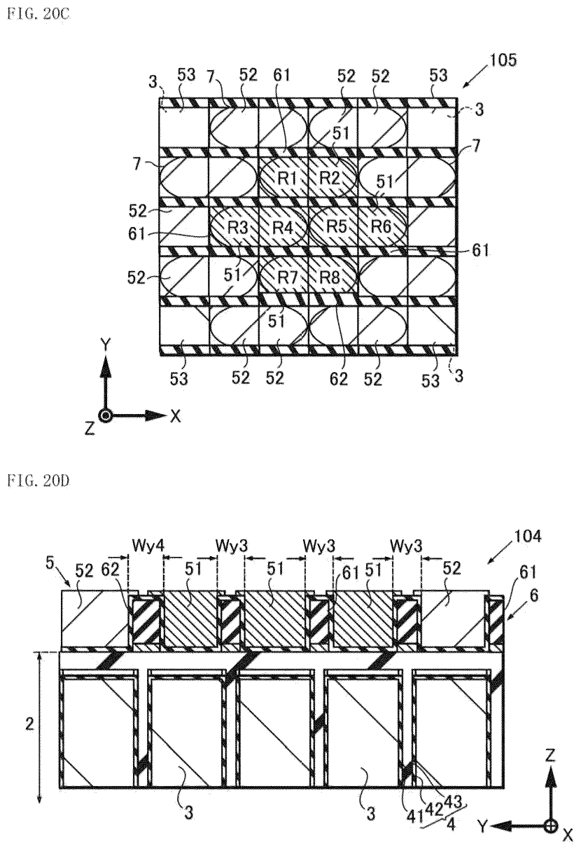

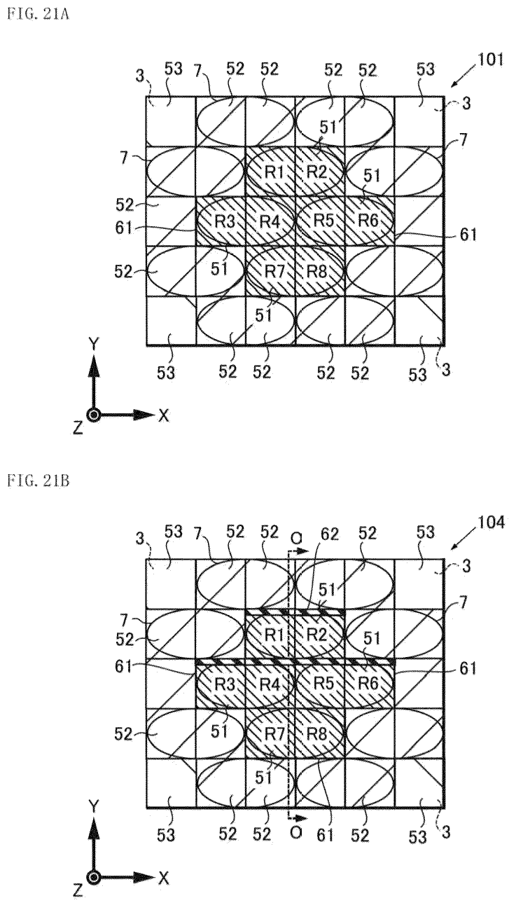

A solid-state imaging device 1 according to a fourteenth embodiment of the present disclosure is described with reference to FIGS. 20A to 20D. The solid-state imaging device 1 according to the fourteenth embodiment is an application example of the solid-state imaging device 1 according to the second embodiment.

### Configuration of the Solid-State Imaging Device 1

FIG. 20A illustrates an example of an enlarged planar configuration of the image height center 101 of the pixel region 10 (see FIG. 1). FIG. 20B illustrates an example of an enlarged planar configuration of the image height periphery 104 on the positive image height side of the pixel region 10. FIG. 20C illustrates an example of an enlarged planar configuration of the image height periphery 105 on the negative image height side of the pixel region 10. Then, FIG. 20D illustrates an example of an enlarged cross-sectional configuration of the image height periphery 104 of the pixel region 10 illustrated in FIG. 20B.

In the solid-state imaging device 1 according to the fourteenth embodiment, as illustrated in FIGS. 20A to 20D, the first inter-waveguide light shielding wall 61 and the second inter-waveguide light shielding wall 62 are provided as the inter-waveguide light shielding wall 6 in the pixel region 10 illustrated in FIG. 1.

Similar to the solid-state imaging device 1 according to the thirteenth embodiment, at the image height center 101 as illustrated in FIG. 20A, the first inter-waveguide light shielding wall 61 is provided between the first color filter 51 and the second color filter 52 arranged adjacent to each other in the second direction.

In addition, at the image height center 101, the first inter-waveguide light shielding wall 61 is also provided between each of the first color filter 51 and the second color filter 52 arranged adjacent to each other in the first direction.

The first inter-waveguide light shielding wall 61 provided in the second direction is set to a width Wy3 that is greater than the width Wy1 and the width Wy2 of the second inter-waveguide light shielding wall 62. The width Wy3 of the first inter-waveguide light shielding wall 61 is the same as the width Wx3. In addition, the first inter-waveguide light shielding wall 61 provided in the first direction is set to the width Wy1 that is the same as the width Wx1.

As illustrated in FIGS. 20B and 20D, at the image height periphery 104, the second inter-waveguide light shielding wall 62 is provided between the first color filter 51 provided at each light receiving pixel 3 denoted by “R1” and “R2” and the second color filter 52 adjacent to this first color filter 51 in the second direction.

In addition, at the image height periphery 105 as illustrated in FIG. 20C, the second inter-waveguide light shielding wall 62 is provided between the first color filter 51 provided at each light receiving pixel 3 denoted by “R7” and “R8” and the second color filter 52 adjacent to this first color filter 51 in the second direction.

At the image height periphery 104, the first inter-waveguide light shielding wall 61 is provided between each of the first color filter 51, the second color filter 52, and the third color filter 53 in the first direction and the second direction in a region other than where the second inter-waveguide light shielding wall 62 is provided. Similarly, at the image height periphery 105, the first inter-waveguide light shielding wall 61 is provided between each of the first color filter 51, the second color filter 52, and the third color filter 53 in the first direction and the second direction in a region other than where the second inter-waveguide light shielding wall 62 is provided.

The second inter-waveguide light shielding wall 62 is set to a width Wy4 that is greater than the width Wy3 of the first inter-waveguide light shielding wall 61. The width Wy4 of the second inter-waveguide light shielding wall 62 is the same as the width Wx4. In addition, at each of the image height periphery 104 and the image height periphery 105, the first inter-waveguide light shielding wall 61 is provided in a region other than where the second inter-waveguide light shielding wall 62 is provided. In the second direction, the first inter-waveguide light shielding wall 61 is set to the width Wy3. In addition, in the first direction, the first inter-waveguide light shielding wall 61 is set to the width Wy1.

Components other than those mentioned above are the same or substantially the same as those of the solid-state imaging device 1 according to the thirteenth embodiment described above.

### Workings and Effects

For the solid-state imaging device 1 according to the fourteenth embodiment, it is possible to obtain workings and effects similar to those obtained by the solid-state imaging device 1 according to the thirteenth embodiment.

In addition, in the solid-state imaging device 1, as illustrated in FIGS. 20A to 20D, the first inter-waveguide light shielding wall 61 is set to the width Wy3 that is greater than the width Wy1 and the width Wy2 in the second direction at each of the image height center 101, the image height periphery 104, and the image height periphery 105.

Thus, in a region other than where the second inter-waveguide light shielding wall 62 is provided, it is also possible to effectively suppress or prevent color mixing that occurs periodically or suddenly in the light receiving pixel 3 provided at each of the image height center 101, the image height periphery 104, and the image height periphery 105.

### 15. Fifteenth Embodiment

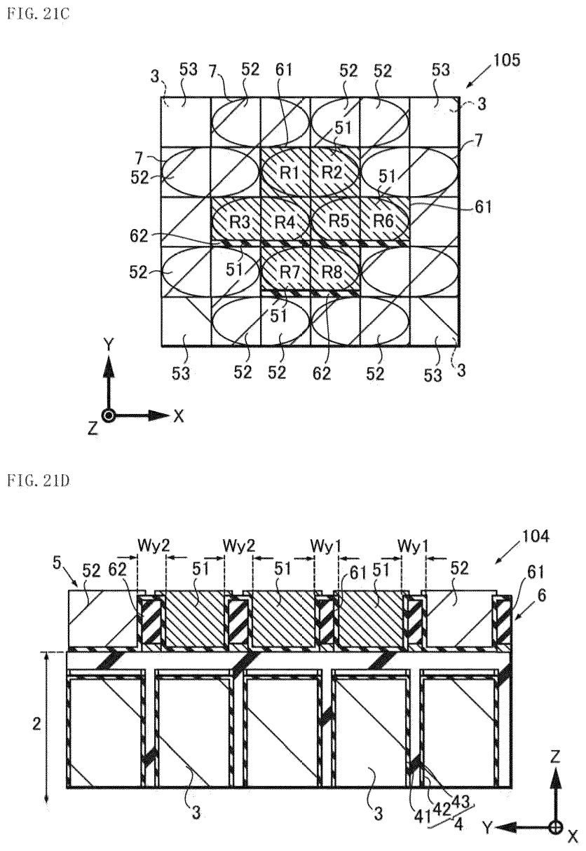

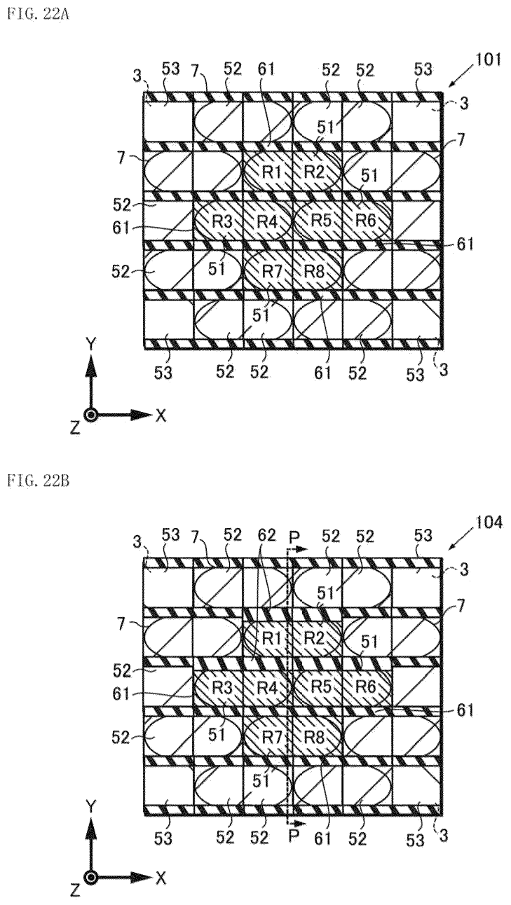

A solid-state imaging device 1 according to a fifteenth embodiment of the present disclosure is described with reference to FIGS. 21A to 21D. The solid-state imaging device 1 according to the fifteenth embodiment is an application example of the solid-state imaging device 1 according to the thirteenth embodiment.

### Configuration of the Solid-State Imaging Device 1

FIG. 21A illustrates an example of an enlarged planar configuration of the image height center 101 of the pixel region 10 (see FIG. 1). FIG. 21B illustrates an example of an enlarged planar configuration of the image height periphery 104 on the positive image height side of the pixel region 10. FIG. 21C illustrates an example of an enlarged planar configuration of the image height periphery 105 on the negative image height side of the pixel region 10. Then, FIG. 21D illustrates an example of an enlarged cross-sectional configuration of the image height periphery 105 of the pixel region 10 illustrated in FIG. 21B.

In the solid-state imaging device 1 according to the fifteenth embodiment, at the image height periphery 104 as illustrated in FIGS. 21B and 21D, the second inter-waveguide light shielding wall 62 is provided between the first color filter 51 provided at each light receiving pixel 3 denoted by “R1” to “R6” and the second color filter 52 adjacent in the second direction. In other words, at the image height periphery 104 on the positive image height side, the second inter-waveguide light shielding wall 62 is provided between the first color filter 51 provided at each light receiving pixel 3 in an upper row and a middle row of the pixel block and the second color filter 52.

In addition, at the image height periphery 105 as illustrated in FIG. 21C, the second inter-waveguide light shielding wall 62 is provided between the first color filter 51 provided at each light receiving pixel 3 denoted by “R3” to “R8” and the second color filter 52 adjacent in the second direction. In other words, at the image height periphery 105 on the negative image height side, the second inter-waveguide light shielding wall 62 is provided between the first color filter 51 provided at each light receiving pixel 3 in each of the middle row and the lower row of the pixel block and the second color filter 52.

The second inter-waveguide light shielding wall 62 is set to the width Wy2 in the second direction. The first inter-waveguide light shielding wall 61 is provided in a region other than where the second inter-waveguide light shielding wall 62 is provided. The first inter-waveguide light shielding wall 61 is set to the width Wy1 in the second direction.

Components other than those mentioned above are the same or substantially the same as those of the solid-state imaging device 1 according to the thirteenth embodiment described above.

### Workings and Effects

For the solid-state imaging device 1 according to the fifteenth embodiment, it is possible to obtain workings and effects similar to those obtained by the solid-state imaging device 1 according to the thirteenth embodiment.

In addition, in the solid-state imaging device 1, at each of the image height periphery 104 and the image height periphery 105 as illustrated in FIGS. 21A to 21D, the second inter-waveguide light shielding wall 62 is provided between many of the first color filters 51 and the second color filters 52 in the pixel block.

This makes it possible to effectively suppress or prevent color mixing in the pixel blocks at the image height periphery 104 and the image height periphery 105.

### 16. Sixteenth Embodiment

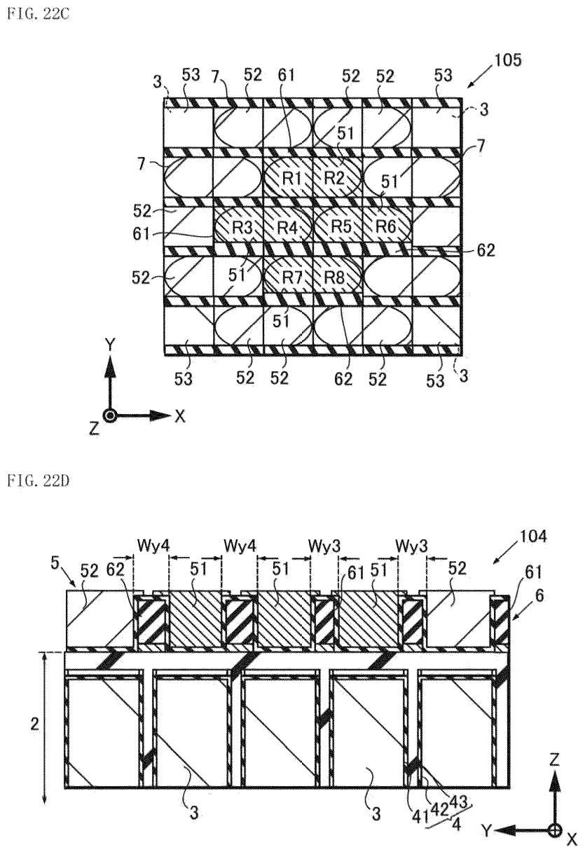

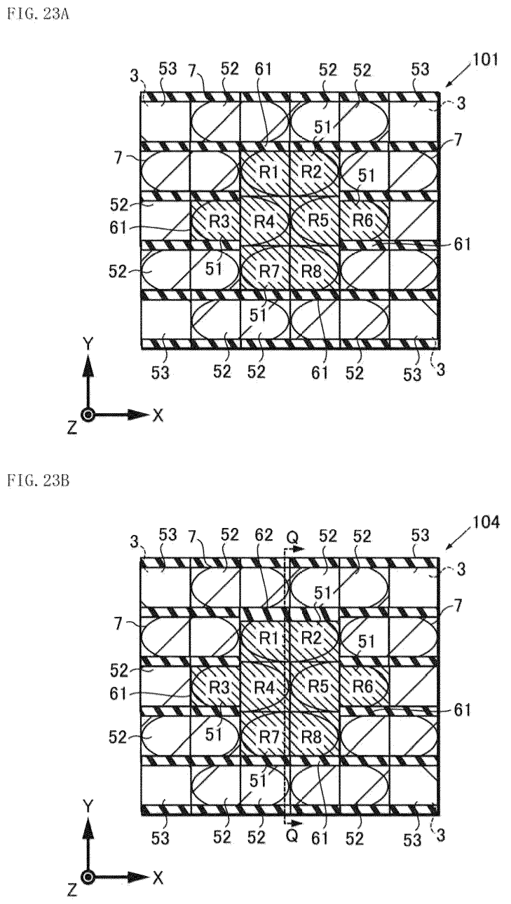

A solid-state imaging device 1 according to a sixteenth embodiment of the present disclosure is described with reference to FIGS. 22A to 22D. The solid-state imaging device 1 according to the sixteenth embodiment is an example of a combination of the solid-state imaging device 1 according to the fourteenth embodiment and the solid-state imaging device 1 according to the fifteenth embodiment.

### Configuration of the Solid-State Imaging Device 1

FIG. 22A illustrates an example of an enlarged planar configuration of the image height center 101 of the pixel region 10 (see FIG. 1). FIG. 22B illustrates an example of an enlarged planar configuration of the image height periphery 104 on the positive image height side of the pixel region 10. FIG. 22C illustrates an example of an enlarged planar configuration of the image height periphery 105 on the negative image height side of the pixel region 10. Then, FIG. 22D illustrates an example of an enlarged cross-sectional configuration of the image height periphery 104 of the pixel region 10 illustrated in FIG. 22B.

In the solid-state imaging device 1 according to the sixteenth embodiment, at the image height periphery 104 as illustrated in FIGS. 22B and 22D, the second inter-waveguide light shielding wall 62 is provided between the first color filter 51 provided at each light receiving pixel 3 denoted by “R1” to “R6” and the second color filter 52 adjacent in the second direction. In other words, at the image height periphery 104 on the positive image height side, the second inter-waveguide light shielding wall 62 is provided between the first color filter 51 provided at each light receiving pixel 3 in an upper row and a middle row of the pixel block and the second color filter 52.

In addition, at the image height periphery 105 as illustrated in FIG. 22C, the second inter-waveguide light shielding wall 62 is provided between the first color filter 51 provided at each light receiving pixel 3 denoted by “R3” to “R8” and the second color filter 52 adjacent in the second direction. In other words, at the image height periphery 105 on the negative image height side, the second inter-waveguide light shielding wall 62 is provided between the first color filter 51 provided at each light receiving pixel 3 in the middle row and a lower row of the pixel block and the second color filter 52.

The second inter-waveguide light shielding wall 62 is set to the width Wy4 in the second direction. The first inter-waveguide light shielding wall 61 is provided in a region other than where the second inter-waveguide light shielding wall 62 is provided. The first inter-waveguide light shielding wall 61 is set to the width Wy3 in the second direction.

Components other than those mentioned above are the same or substantially the same as those of each of the solid-state imaging device 1 according to the fourteenth embodiment and the solid-state imaging device 1 according to the fifteenth embodiment described above.

### Workings and Effects

In the solid-state imaging device 1 according to the sixteenth embodiment, it is possible to obtain workings and effects obtained by a combination of those obtained by the solid-state imaging device 1 according to the fourteenth embodiment and those obtained by the solid-state imaging device 1 according to the fifteenth embodiment.

### 17. Seventeenth Embodiment

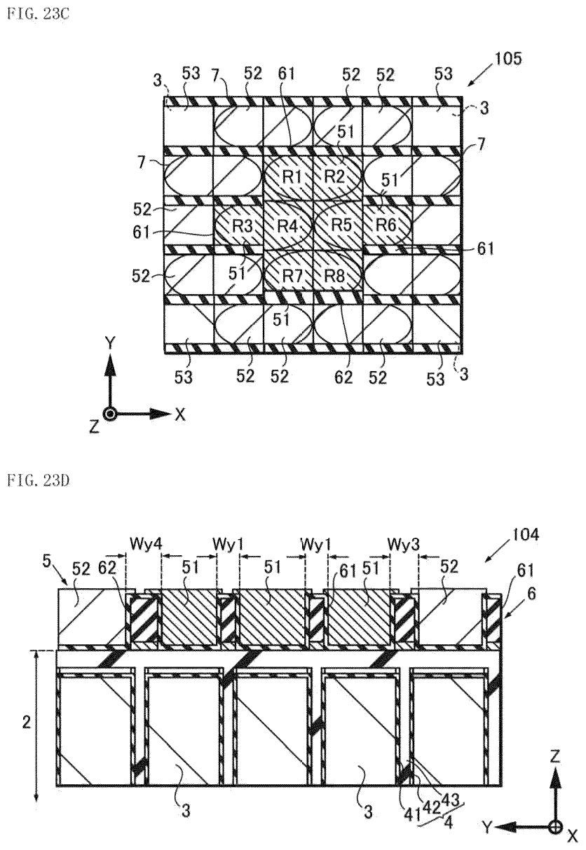

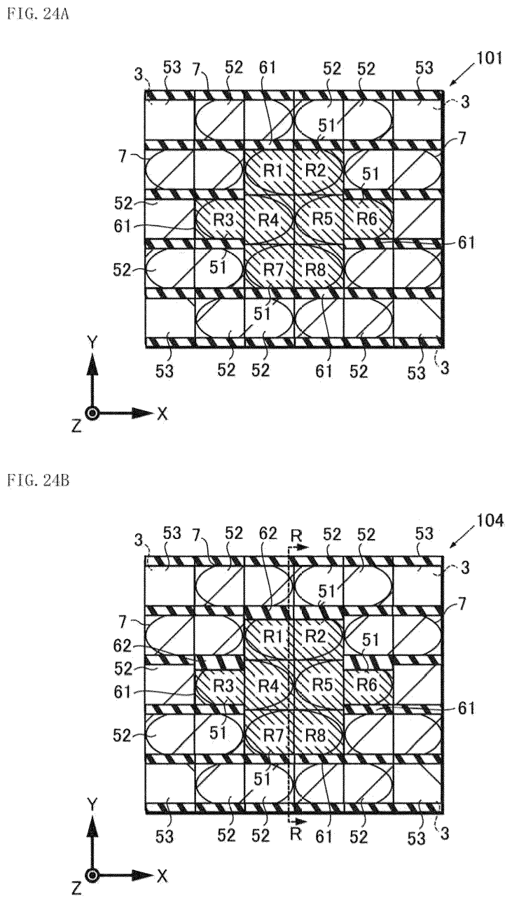

A solid-state imaging device 1 according to a seventeenth embodiment of the present disclosure is described with reference to FIGS. 23A to 23D. The solid-state imaging device 1 according to the seventeenth embodiment is an example of a combination of the solid-state imaging device 1 according to the thirteenth embodiment and the solid-state imaging device 1 according to the fourteenth embodiment.

### Configuration of the Solid-State Imaging Device 1

FIG. 23A illustrates an example of an enlarged planar configuration of the image height center 101 of the pixel region 10 (see FIG. 1). FIG. 23B illustrates an example of an enlarged planar configuration of the image height periphery 104 on the positive image height side of the pixel region 10. FIG. 23C illustrates an example of an enlarged planar configuration of the image height periphery 105 on the negative image height side of the pixel region 10. Then, FIG. 23D illustrates an example of an enlarged cross-sectional configuration of the image height periphery 105 of the pixel region 10 illustrated in FIG. 23B.

In the solid-state imaging device 1 according to the seventeenth embodiment, as illustrated in FIGS. 23A to 23D, the first inter-waveguide light shielding wall 61 and the second inter-waveguide light shielding wall 62 are provided as the inter-waveguide light shielding wall 6 in the pixel region 10 illustrated in FIG. 1.

Similar to the solid-state imaging device 1 according to the fourteenth embodiment, at the image height center 101 as illustrated in FIG. 23A, the first inter-waveguide light shielding wall 61 is provided between the first color filter 51 and the second color filter 52 arranged adjacent to each other in the second direction.

The first inter-waveguide light shielding wall 61 provided in the second direction is set to Wy3. In addition, the first inter-waveguide light shielding wall 61 provided in the first direction is set to the width Wx1.

At the image height periphery 104 as illustrated in FIGS. 23B and 23D, the second inter-waveguide light shielding wall 62 is provided between the first color filter 51 provided at each light receiving pixel 3 denoted by “R1” and “R2” and the second color filter 52 adjacent to this first color filter 51 in the second direction. The second inter-waveguide light shielding wall 62 is set to the width Wy4.

In addition, the first inter-waveguide light shielding wall 61 is provided between the first color filter 51 provided at each light receiving pixel 3 denoted by “R7” and “R8” and the second color filter 52 adjacent to this first color filter 51 in the second direction. The first inter-waveguide light shielding wall 61 is set to the width Wy3.

On the other hand, at the image height periphery 105 as illustrated in FIG. 23C, the second inter-waveguide light shielding wall 62 is provided between the first color filter 51 provided at each light receiving pixel 3 denoted by “R7” and “R8” and the second color filter 52 adjacent to this first color filter 51 in the second direction. The second inter-waveguide light shielding wall 62 is set to the width Wy4.

In addition, the first inter-waveguide light shielding wall 61 is provided between the first color filter 51 provided at each light receiving pixel 3 denoted by “R1” and “R2” and the second color filter 52 adjacent to this first color filter 51 in the second direction. The first inter-waveguide light shielding wall 61 is set to the width Wy3.

Then, in the pixel block at each of the image height periphery 104 and the image height periphery 105, the first inter-waveguide light shielding wall 61 is provided between the first color filters 51 having the same color and adjacent to each other in the first direction and between the first color filters 51 having the same color and adjacent to each other in the second direction. Each first inter-waveguide light shielding wall 61 is set to a corresponding one of the width Wx1 and the width Wy1.

Components other than those mentioned above are the same or substantially the same as those of the solid-state imaging device 1 according to the fourteenth embodiment and the solid-state imaging device 1 according to the fifteenth embodiment described above.

### Workings and Effects

For the solid-state imaging device 1 according to the seventeenth embodiment, it is possible to obtain workings and effects obtained by a combination of those obtained by the solid-state imaging device 1 according to the fourteenth embodiment and those obtained by the solid-state imaging device 1 according to the fifteenth embodiment.

In addition, in the solid-state imaging device 1, as illustrated in FIGS. 23A to 23D, the first inter-waveguide light shielding wall 61 is provided between the first color filters 51 having the same color in the pixel block at each of the image height center 101, the image height periphery 102, and the image height periphery 103. This first inter-waveguide light shielding wall 61 is set to the width Wx1 or width Wy1.

Thus, it is possible to increase the light receiving area (opening area) of the light receiving pixel 3 in the pixel block at each of the image height center 101, the image height periphery 102, and the image height periphery 103. This makes it possible to improve the quantum efficiency of the solid-state imaging device 1.

### 18. Eighteenth Embodiment

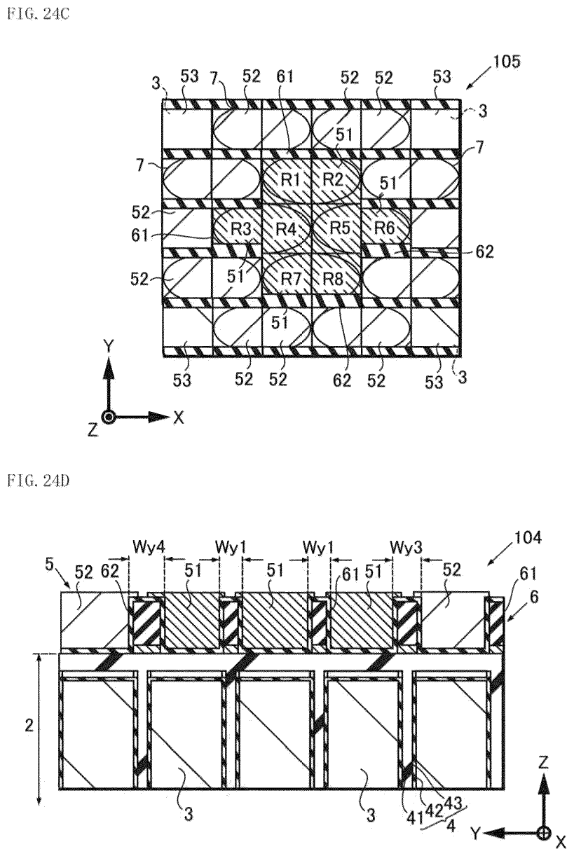

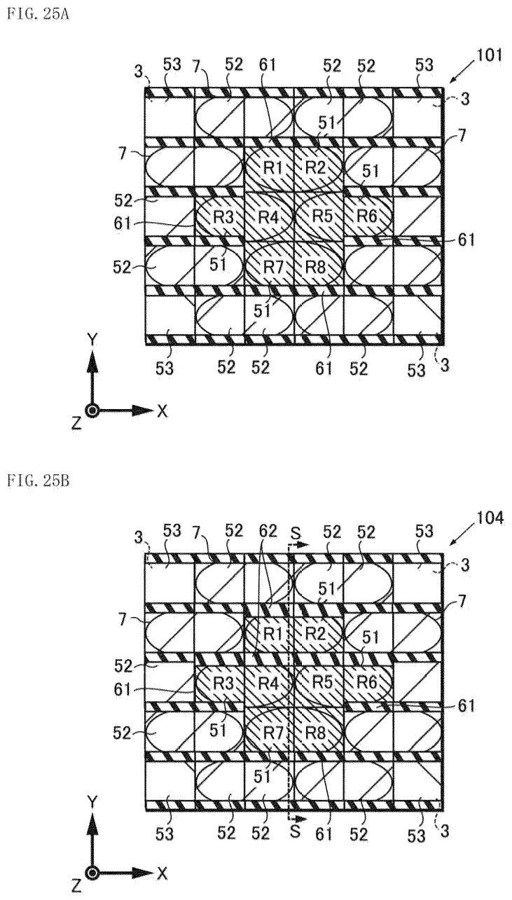

A solid-state imaging device 1 according to an eighteenth embodiment of the present disclosure is described with reference to FIGS. 24A to 24D. The solid-state imaging device 1 according to the eighteenth embodiment is an example of a combination of the solid-state imaging device 1 according to the fifteenth embodiment and the solid-state imaging device 1 according to the seventeenth embodiment.

### Configuration of the Solid-State Imaging Device 1

FIG. 24A illustrates an example of an enlarged planar configuration of the image height center 101 of the pixel region 10 (see FIG. 1). FIG. 24B illustrates an example of an enlarged planar configuration of the image height periphery 104 on the positive image height side of the pixel region 10. FIG. 24C illustrates an example of an enlarged planar configuration of the image height periphery 105 on the negative image height side of the pixel region 10. Then, FIG. 24D illustrates an example of an enlarged cross-sectional configuration of the image height periphery 104 of the pixel region 10 illustrated in FIG. 24B.

In the solid-state imaging device 1 according to the eighteenth embodiment, at the image height periphery 104 as illustrated in FIGS. 24B and 24D, the second inter-waveguide light shielding wall 62 is provided between the first color filter 51 provided at each light receiving pixel 3 denoted by “R1”, “R2”, “R3”, and “R6” and the second color filter 52 adjacent in the second direction. In other words, at the image height periphery 104 on the positive image height side, the second inter-waveguide light shielding wall 62 is provided between the first color filter 51 provided at each light receiving pixel 3 in an upper row and a middle row of the pixel block and the second color filter 52. The second inter-waveguide light shielding wall 62 is set to the width Wy4.

In addition, at the image height periphery 104, the first inter-waveguide light shielding wall 61 is provided between the first color filter 51 provided at each light receiving pixel 3 denoted by “R3”, “R6”, “R7” and “R8” and the second color filter 52 adjacent in the second direction. The first inter-waveguide light shielding wall 61 is set to the width Wy3.

On the other hand, at the image height periphery 105 as illustrated in FIG. 24C, the second inter-waveguide light shielding wall 62 is provided between the first color filter 51 provided at each light receiving pixel 3 denoted by “R3”, “R6”, “R7” and “R8” and the second color filter 52 adjacent in the second direction. In other words, at the image height periphery 105 on the negative image height side, the second inter-waveguide light shielding wall 62 is provided between the first color filter 51 provided at each light receiving pixel 3 in the middle row and the lower row of the pixel block and the second color filter 52. The second inter-waveguide light shielding wall 62 is set to the width Wy4.

In addition, at the image height periphery 105, the first inter-waveguide light shielding wall 61 is provided between the first color filter 51 provided at each light receiving pixel 3 denoted by “R1”, “R2”, “R3” and “R6” and the second color filter 52 adjacent in the second direction. The first inter-waveguide light shielding wall 61 is set to the width Wy3.

Then, at each of the image height center 101, the image height periphery 102, and the image height periphery 103, the first inter-waveguide light shielding wall 61 is provided between the first color filters 51 having the same color in the pixel block. This first inter-waveguide light shielding wall 61 is set to the width Wx1 or width Wy1.

Components other than those mentioned above are the same or substantially the same as those of each of the solid-state imaging device 1 according to the fifteenth embodiment and the solid-state imaging device 1 according to the seventeenth embodiment described above.

### Workings and Effects

For the solid-state imaging device 1 according to the eighteenth embodiment, it is possible to obtain workings and effects obtained by a combination of those obtained by the solid-state imaging device 1 according to the fifteenth embodiment and those obtained by the solid-state imaging device 1 according to the seventeenth embodiment.

### 19. Nineteenth Embodiment

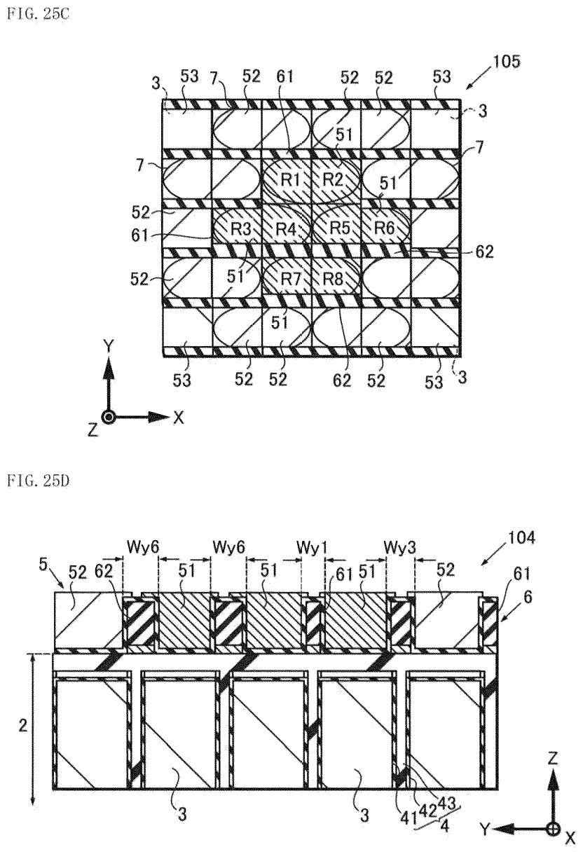

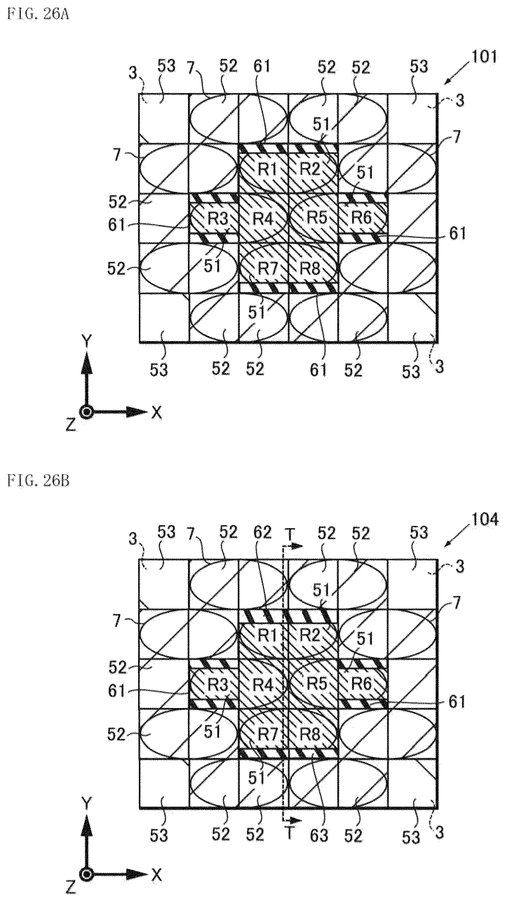

A solid-state imaging device 1 according to a nineteenth embodiment of the present disclosure is described with reference to FIGS. 25A to 25D. The solid-state imaging device 1 according to the nineteenth embodiment is an application example of the solid-state imaging device 1 according to the sixteenth embodiment.

### Configuration of the Solid-State Imaging Device 1

FIG. 25A illustrates an example of an enlarged planar configuration of the image height center 101 of the pixel region 10 (see FIG. 1). FIG. 25B illustrates an example of an enlarged planar configuration of the image height periphery 104 on the positive image height side of the pixel region 10. FIG. 25C illustrates an example of an enlarged planar configuration of the image height periphery 105 on the negative image height side of the pixel region 10. Then, FIG. 25D illustrates an example of an enlarged cross-sectional configuration of the image height periphery 104 of the pixel region 10 illustrated in FIG. 25B.

In the solid-state imaging device 1 according to the nineteenth embodiment, as illustrated in FIG. 25A to FIG. 25D, the first inter-waveguide light shielding wall 61 and the second inter-waveguide light shielding wall 62 are provided as the inter-waveguide light shielding wall 6 in the pixel region 10 illustrated in FIG. 1.

As illustrated in FIGS. 25B and 25D, at the image height periphery 104 of the pixel region 10, the first inter-waveguide light shielding wall 61 is provided between the first color filter 51 provided at each light receiving pixel 3 denoted by “R4” and “R5” in a middle row of the pixel block and the first color filter 51 provided at each light receiving pixel 3 denoted by “R7” and “R8” in a lower row and having the same color. The first inter-waveguide light shielding wall 61 is set to the width Wy1.

In addition, the second inter-waveguide light shielding wall 62 is set to a width Wy6. For example, the width Wy6 of the second inter-waveguide light shielding wall 62 is 180 nm or more and 230 nm or less.

As illustrated in FIG. 25C, at the image height periphery 105 of the pixel region 10, the first inter-waveguide light shielding wall 61 is provided between the first color filter 51 provided at each light receiving pixel 3 denoted by “R4” and “R5” in the middle row of the pixel block and the first color filter 51 provided at each light receiving pixel 3 denoted by “R1” and “R2” in an upper row and having the same color. The first inter-waveguide light shielding wall 61 is set to the width Wy1.

Components other than those mentioned above are the same or substantially the same as those of the solid-state imaging device 1 according to the sixteenth embodiment described above.

### Workings and Effects

For the solid-state imaging device 1 according to the nineteenth embodiment, it is possible to obtain workings and effects similar to those obtained by the solid-state imaging device 1 according to the sixteenth embodiment.

In addition, in the solid-state imaging device 1, as illustrated in FIGS. 25A to 25D, the first inter-waveguide light shielding wall 61 is provided between the first color filters 51 having the same color in the pixel block at each of the image height center 101, the image height periphery 102, and the image height periphery 103. The first inter-waveguide light shielding wall 61 is set to the width WY1.

Thus, it is possible to increase the light receiving area (opening area) of the light receiving pixel 3 at each of the image height center 101, the image height periphery 102, and the image height periphery 103, as compared with a case where all of the inter-waveguide light shielding walls 6 provided are the second inter-waveguide light shielding walls 62. This makes it possible to improve the quantum efficiency of the solid-state imaging device 1.

### 20. Twentieth Embodiment

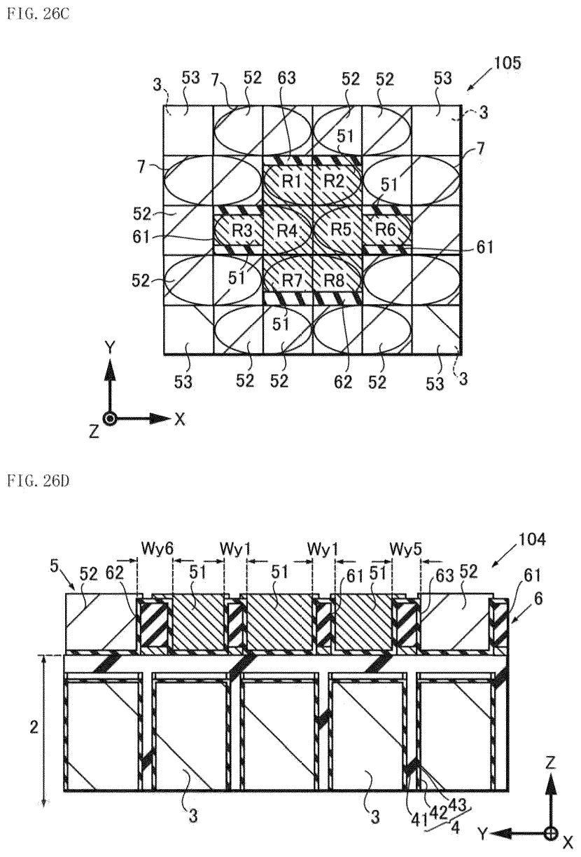

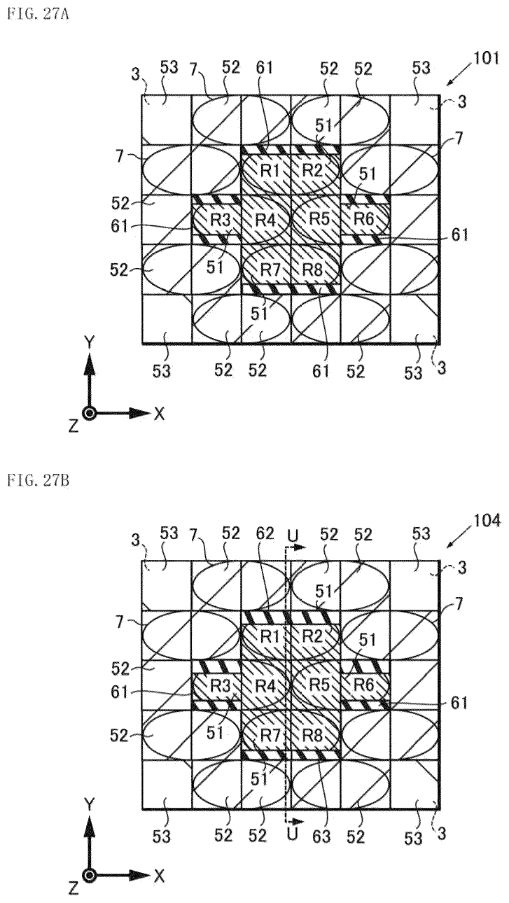

A solid-state imaging device 1 according to a twentieth embodiment of the present disclosure is described with reference to FIGS. 26A to 26D. The solid-state imaging device 1 according to the twentieth embodiment is an application example of the solid-state imaging device 1 according to the eighteenth embodiment.

### Configuration of the Solid-State Imaging Device 1

FIG. 26A illustrates an example of an enlarged planar configuration of the image height center 101 of the pixel region 10 (see FIG. 1). FIG. 26B illustrates an example of an enlarged planar configuration of the image height periphery 104 on the positive image height side of the pixel region 10. FIG. 26C illustrates an example of an enlarged planar configuration of the image height periphery 105 on the negative image height side of the pixel region 10. Then, FIG. 26D illustrates an example of an enlarged cross-sectional configuration of the image height periphery 104 of the pixel region 10 illustrated in FIG. 26B.

In the solid-state imaging device 1 according to the twentieth embodiment, as illustrated in FIGS. 26A to 26D, the first inter-waveguide light shielding wall 61 and the second inter-waveguide light shielding wall 62 are provided as the inter-waveguide light shielding wall 6 in the pixel region 10 illustrated in FIG. 1.

In the solid-state imaging device 1, as illustrated in FIGS. 26A to 26D, the first inter-waveguide light shielding wall 61 is provided between each second color filter 52, between each third color filter 53, and between the second color filter 52 and the third color filter 53 at each of the image height center 101, the image height periphery 104, and the image height periphery 105. Each first inter-waveguide light shielding wall 61 is set to a corresponding one of the width Wx1 and the width Wy1.

In addition, the second inter-waveguide light shielding wall 62, and a third inter-waveguide light shielding wall 63, which is newly provided, are provided at each of the image height periphery 104 and the image height periphery 105. The third inter-waveguide light shielding wall 63 is set to the width Wy6. For example, the width Wy6 of the third inter-waveguide light shielding wall 63 is 180 nm or more and 250 nm or less.

Components other than those mentioned above are the same or substantially the same as those of the solid-state imaging device 1 according to the eighteenth embodiment described above.

### Workings and Effects

For the solid-state imaging device 1 according to the twentieth embodiment, it is possible to obtain the same effects as those obtained by the solid-state imaging device 1 according to the eighteenth embodiment.

In addition, in the solid-state imaging device 1, as illustrated in FIGS. 26A to 26D, the first inter-waveguide light shielding wall 61 is provided at most of the image height center 101, the image height periphery 104, and the image height periphery 105, except for a portion in which the first color filter 51 is provided, in the pixel block. Each first inter-waveguide light shielding wall 61 is set to a corresponding one of the width Wx1 and the width Wy1.

Thus, it is possible to increase the light receiving area (opening area) of the light receiving pixel 3 at each of the image height center 101, the image height periphery 104, and the image height periphery 105 of the pixel region 10, as compared with the solid-state imaging device 1 according to the eighteenth embodiment. This makes it possible to improve the quantum efficiency of the solid-state imaging device 1.

### 21. Twenty-First Embodiment

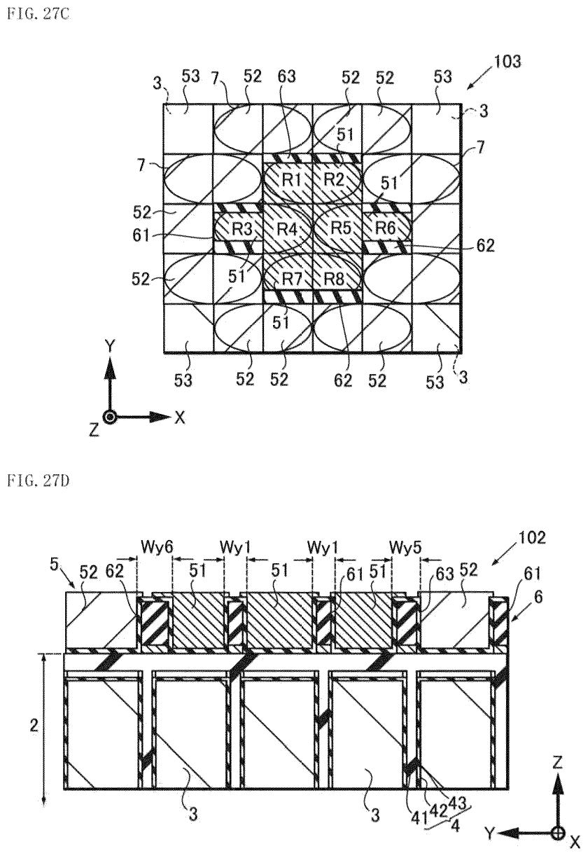

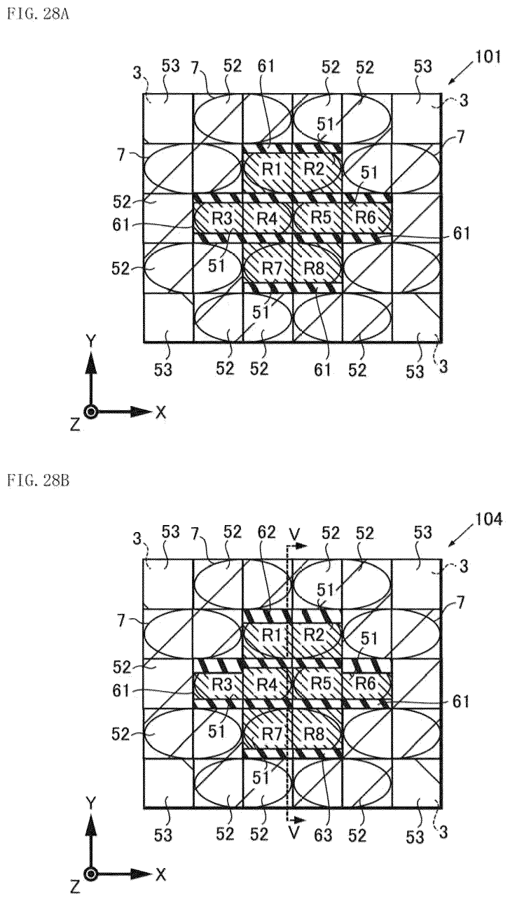

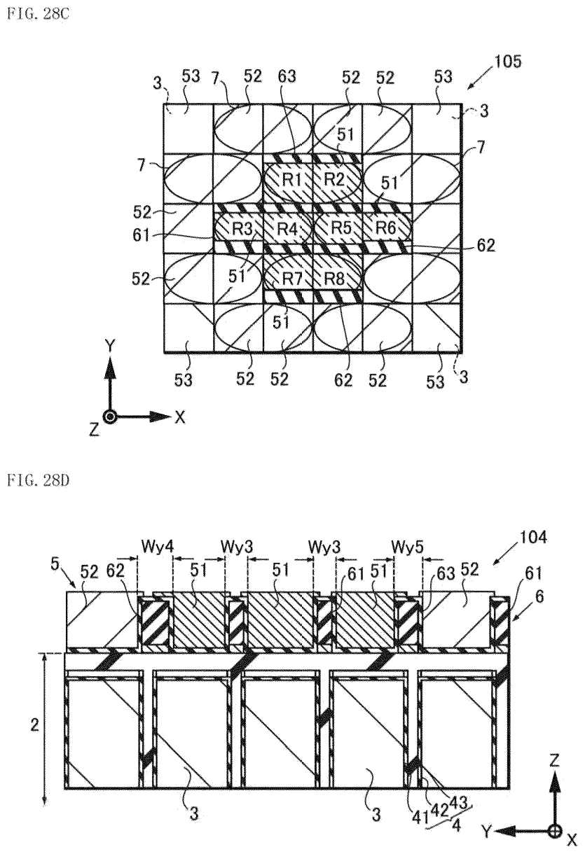

A solid-state imaging device 1 according to a twenty-first embodiment of the present disclosure is described with reference to FIGS. 27A to 27D. The solid-state imaging device 1 according to the twenty-first embodiment is an application example of the solid-state imaging device 1 according to the twentieth embodiment.

### Configuration of the Solid-State Imaging Device 1

FIG. 27A illustrates an example of an enlarged planar configuration of the image height center 101 of the pixel region 10 (see FIG. 1). FIG. 27B illustrates an example of an enlarged planar configuration of the image height periphery 104 on the positive image height side of the pixel region 10. FIG. 27C illustrates an example of an enlarged planar configuration of the image height periphery 105 on the negative image height side of the pixel region 10. Then, FIG. 27D illustrates an example of an enlarged cross-sectional configuration of the image height periphery 104 of the pixel region 10 illustrated in FIG. 27B.

In the solid-state imaging device 1 according to the twenty-first embodiment, as illustrated in FIGS. 27A to 27D, the first inter-waveguide light shielding wall 61 and the second inter-waveguide light shielding wall 62 are provided as the inter-waveguide light shielding wall 6 in the pixel region 10 illustrated in FIG. 1.

As illustrated in FIGS. 27B and 27D, at the image height periphery 104 of the pixel region 10, the second inter-waveguide light shielding wall 62 is provided between the first color filter 51 provided at each light receiving pixel 3 denoted by “R1”, “R2”, “R3”, and “R6” in an upper row of the pixel block and the second color filter 52 adjacent in the second direction. The second inter-waveguide light shielding wall 62 is set to the width Wy4.

In addition, each of the first inter-waveguide light shielding wall 61 and the third inter-waveguide light shielding wall 63 is provided between the first color filter 51 provided at each light receiving pixel 3 denoted by “R3” and “R6” in a middle row of the pixel block and denoted by “R7” and “R8” in a lower row, and the second color filter 52 adjacent in the second direction. The first inter-waveguide light shielding wall 61 is set to the width Wy3. The third inter-waveguide light shielding wall 63 is set to a width Wy5.

On the other hand, as illustrated in FIG. 27C, at the image height periphery 105 of the pixel region 10, the light shielding wall 62 is provided between the first color filter 51 provided at each light receiving pixel 3 denoted by “R7” and “R8” in the lower row of the pixel block and denoted by “R3” and “R6” in the middle row, and the second color filter 52 adjacent in the second direction. The second inter-waveguide light shielding wall 62 is set to a width Wy6.

In addition, the first inter-waveguide light shielding wall 61 is also provided between the first color filter 51 provided at each light receiving pixel 3 denoted by “R1” and “R2” in the upper row of the pixel block and denoted by “R3” and “R6” in the middle row, and the second color filter 52 adjacent in the second direction. The first inter-waveguide light shielding wall 61 is set to the width Wy3.

Components other than those mentioned above are the same or substantially the same as those of the solid-state imaging device 1 according to the twentieth embodiment described above.

### Workings and Effects

For the solid-state imaging device 1 according to the twenty-first embodiment, it is possible to obtain workings and effects similar to those obtained by the solid-state imaging device 1 according to the sixteenth embodiment.

In addition, for the solid-state imaging device 1, it is possible to increase the light receiving area (opening area) of the light receiving pixel 3, as compared with the solid-state imaging device 1 according to the seventeenth embodiment described above. This makes it possible to improve the quantum efficiency of the solid-state imaging device 1.

### 22. Twenty-second Embodiment

A solid-state imaging device 1 according to a twenty-second embodiment of the present disclosure is described with reference to FIGS. 28A to 28D. The solid-state imaging device 1 according to the twenty-second embodiment is an application example of the solid-state imaging device 1 according to the twenty-first embodiment.

### Configuration of the Solid-State Imaging Device 1

FIG. 28A illustrates an example of an enlarged planar configuration of the image height center 101 of the pixel region 10 (see FIG. 1). FIG. 28B illustrates an example of an enlarged planar configuration of the image height periphery 104 on the positive image height side of the pixel region 10. FIG. 28C illustrates an example of an enlarged planar configuration of the image height periphery 105 on the negative image height side of the pixel region 10. Then, FIG. 28D illustrates an example of an enlarged cross-sectional configuration of the image height periphery 104 of the pixel region 10 illustrated in FIG. 28B.

In the solid-state imaging device 1 according to the twenty-second embodiment, as illustrated in FIGS. 28A to 28D, the first inter-waveguide light shielding wall 61 and the second inter-waveguide light shielding wall 62 are provided as the inter-waveguide light shielding wall 6 in the pixel region 10 illustrated in FIG. 1.

As illustrated in FIGS. 28B and 28D, at the image height periphery 104 of the pixel region 10, the first inter-waveguide light shielding wall 61 is provided between the first color filters 51 provided at the light receiving pixels 3 denoted by “R1” and “R2” in an upper row of the pixel block, denoted by “R3” and “R6” in a middle row, and denoted by “R7” and “R8” in a lower row and adjacent to each other in the second direction. The first inter-waveguide light shielding wall 61 is set to the width Wy3.

On the other hand, as illustrated in FIG. 28C, at the image height periphery 105 of the pixel region 10, the first inter-waveguide light shielding walls 61 is provided between the first color filters 51 at the light receiving pixels 3 denoted by “R1” and “R2” in the upper row of the pixel block, denoted by “R3” and “R6” in the middle row, and denoted by “R7” and “R8” in the lower row and adjacent to each other in the second direction. The first inter-waveguide light shielding wall 61 is set to the width Wy3.

Components other than those mentioned above are the same or substantially the same as those of the solid-state imaging device 1 according to the twenty-first embodiment described above.

### Workings and Effects

For the solid-state imaging device 1 according to the twenty-second embodiment, it is possible to obtain workings and effects similar to those obtained by the solid-state imaging device 1 according to the twenty-first embodiment.

In addition, for the solid-state imaging device 1, as illustrated in FIGS. 28A to 28D, the first inter-waveguide light shielding wall 61 is provided between the first color filters 51 having the same color in each of the upper row, the middle row, and the lower row of the pixel block. This makes it possible to effectively suppress or prevent a difference in photosensitivity of the light receiving pixel 3 provided in the middle row of the pixel block, as compared with the solid-state imaging device 1 according to the twentieth embodiment.

### 23. Twenty-third Embodiment

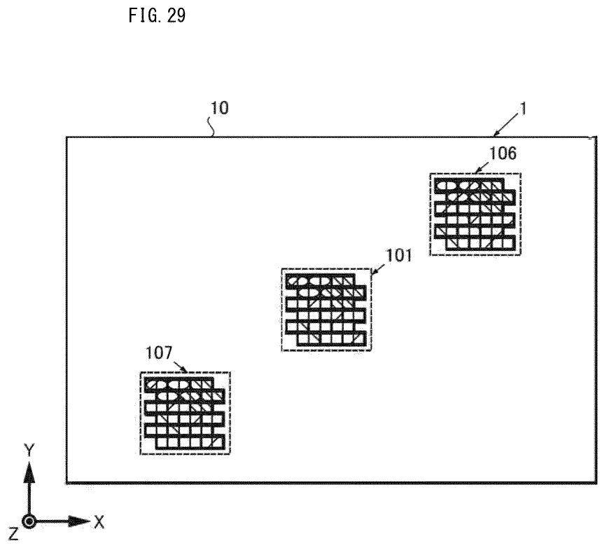

A solid-state imaging device 1 according to a twenty-third embodiment of the present disclosure is described with reference to FIG. 29. The solid-state imaging device 1 according to the twenty-third embodiment is an application example of the solid-state imaging device 1 according to the first to the twenty-second embodiments.

### Configuration of the Solid-State Imaging Device 1

FIG. 29 illustrates an example of a schematic planar configuration of the pixel region 10 of the solid-state imaging device 1.

In the solid-state imaging device 1 according to the first to the twelfth embodiments described above, the second inter-waveguide light shielding wall 62 is provided at each of the image height periphery 102 and the image height periphery 103 in the first direction centered on the image height center 101 (see FIG. 1). In addition, the solid-state imaging device 1 according to the thirteenth to the twenty-second embodiments described above, the second inter-waveguide light shielding wall 62 is provided at each of the image height periphery 104 and the image height periphery 105 in the second direction centered on the image height center 101 (see FIG. 1).

In the solid-state imaging device 1 according to the twenty-third embodiment, as illustrated in FIG. 29, the second inter-waveguide light shielding wall 62, which is not illustrated in the figure, is provided at each of an image height periphery 106 and an image height periphery 107 in a diagonal direction that intersects with the first direction and the second direction. The image height periphery 106 is on the positive image height side. The image height periphery 107 is on the negative image height side.

Components other than those mentioned above are the same or substantially the same as those of the solid-state imaging device 1 according to any of the first to the twenty-second embodiments described above.

### Workings and Effects

For the solid-state imaging device 1 according to the twenty-third embodiment, it is possible to obtain the same effects as those obtained by the solid-state imaging device 1 according to any of the first to the twenty-second embodiments.

### 24. Twenty-fourth Embodiment

A solid-state imaging device 1 according to a twenty-fourth embodiment of the present disclosure is described with reference to FIG. 30. The solid-state imaging device 1 according to the twenty-fourth embodiment and the twenty-fifth embodiment are each an example in which a structure of the inter-waveguide light shielding wall 6 is changed.

### Configuration of the Solid-State Imaging Device 1 and the Inter-Waveguide Light Shielding Wall 6

FIG. 30 illustrates an example of a cross-sectional configuration of the inter-waveguide light shielding wall 6.

As illustrated in FIG. 30, the solid-state imaging device 1 includes the inter-waveguide light shielding wall 6 between each color filter 5. The inter-waveguide light shielding wall 6 includes a barrier metal 601, a light-shielding wall body 602, and a protective film 603 in side view.

The barrier metal 601 is formed using the same material as the barrier metal 601 of the inter-waveguide light shielding wall 6 according to the first embodiment. The protective film 603 is formed using the same material as the protective film 603 of the inter-waveguide light shielding wall 6 according to the first embodiment.

The light-shielding wall body 602 is formed using a high-melting-point metal having a high light-shielding property such as tungsten (W), for example. For example, the light-shielding wall body 602 has a thickness of 85 nm or more and 285 nm or less.

Here, the inter-waveguide light shielding wall 6 has a height of, for example, 100 nm or more and 600 nm or less.

Components other than those mentioned above are the same or substantially the same as those of the solid-state imaging device 1 according to the first embodiment described above.

### Workings and Effects

For the solid-state imaging device 1 according to the twenty-fourth embodiment, it is possible to obtain workings and effects similar to those obtained by the solid-state imaging device 1 according to the first embodiment.

In addition, in the solid-state imaging device 1, as illustrated in FIG. 30, the light-shielding wall body 602 of the inter-waveguide light shielding wall 6 is formed using a high-melting-point metal, thereby making it possible to effectively limit the amount of entering light by the inter-waveguide light shielding wall 6.

### 25. Twenty-Fifth Embodiment

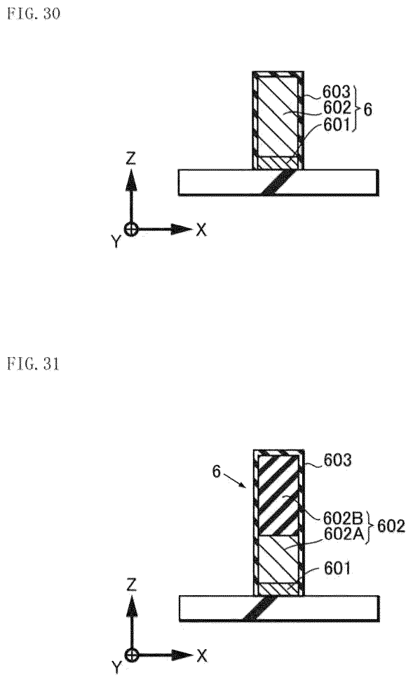

A solid-state imaging device 1 according to a twenty-fifth embodiment of the present disclosure is described with reference to FIG. 31. The solid-state imaging device 1 according to the twenty-fifth embodiment is a modification example of the inter-waveguide light shielding wall 6 in the solid-state imaging device 1 according to the first embodiment.

### Configuration of the Solid-State Imaging Device 1 and the Inter-Waveguide Light Shielding Wall 6

FIG. 31 illustrates an example of a cross-sectional configuration of the inter-waveguide light shielding wall 6.

As illustrated in FIG. 31, similar to the solid-state imaging device 1 according to the first embodiment, the solid-state imaging device 1 includes the inter-waveguide light shielding wall 6 between the color filters 5. The inter-waveguide light shielding wall 6 includes the barrier metal 601, the light-shielding wall body 602, and the protective film 603 in side view.

The barrier metal 601 is formed using the same material as the barrier metal 601 of the inter-waveguide light shielding wall 6 according to the first embodiment. The protective film 603 is formed using the same material as the protective film 603 of the inter-waveguide light shielding wall 6 according to the first embodiment.

The light-shielding wall body 602 includes a first light-shielding wall body 602A formed on the barrier metal 601 and a second light-shielding wall body 602B formed on the first light-shielding wall body 602A. The first light-shielding wall body 602A is formed using, for example, a high-melting-point metal such as W. The second light-shielding wall body 602B is formed using the same material as the light-shielding wall body 602 of the solid-state imaging device 1 according to the first embodiment, for example, SiO2.

Components other than those mentioned above are the same or substantially the same as those of the solid-state imaging device 1 according to the first embodiment described above.

### Workings and Effects

For the solid-state imaging device 1 according to the twenty-fifth embodiment, it is possible to obtain workings and effects similar to those obtained by the solid-state imaging device 1 according to the first embodiment.

### 26. Application Example for Mobile Object

The technique of the present disclosure (the present technology) is applicable to various products. For example, the technique of the present disclosure may be realized as a device to be mounted on any type of mobile object, such as an automobile, electric vehicle, hybrid electric vehicle, motorcycle, bicycle, personal mobility vehicle, airplane, drone, ship, robot, or the like.

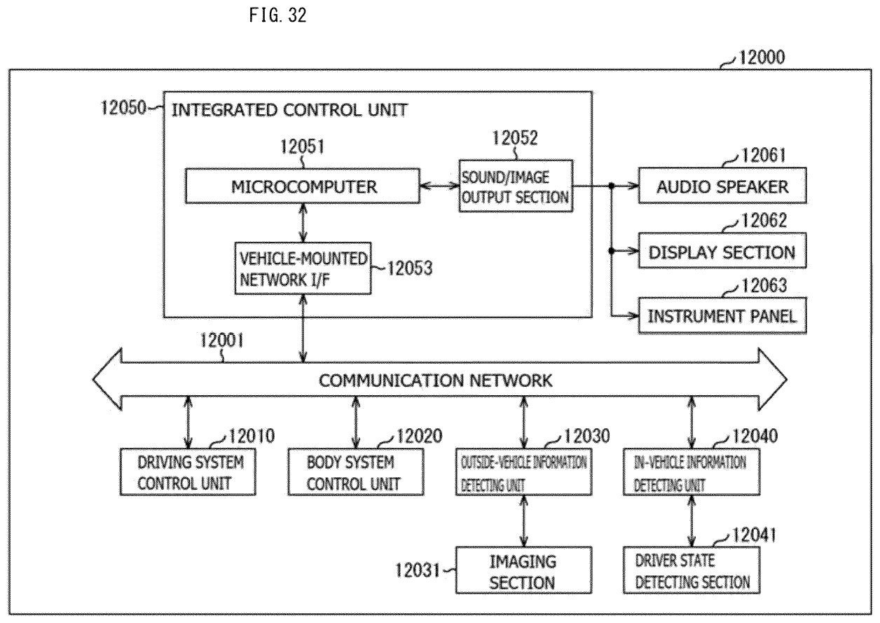

FIG. 32 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 32, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 32, an audio speaker 12061, a display section 12062, and an instrument panel 12063 are illustrated as the output device. The display section 12062 may, for example, include at least one of an on-board display and a head-up display.

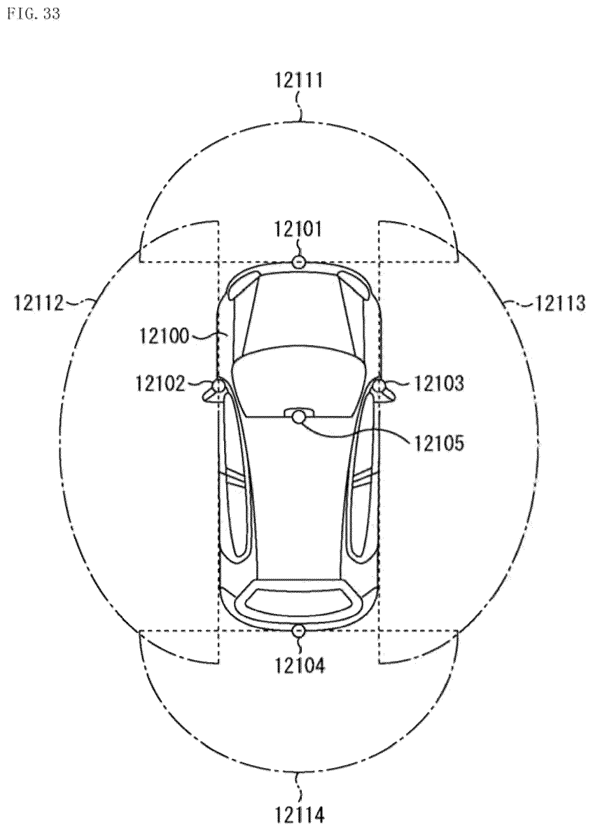

FIG. 33 is a diagram depicting an example of the installation position of the imaging section 12031.

In FIG. 33, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 33 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technique of the present disclosure is appliable has been described above. The technique of the present disclosure is applicable to the imaging section 12031 in the configuration described above. Applying the technique of the present disclosure to the imaging section 12031 makes it possible to realize a simpler configuration of the imaging section 12031.

### 27. Other Embodiment

The present technology is not limited to the above embodiments, but various modifications are possible within the scope that does not depart from the gist thereof.

For example, of the solid-state imaging devices according to the first to the twenty-third embodiments described above, the solid-state imaging devices according to two or more embodiments may be combined.

Furthermore, the present technology is applicable to an imaging device including the solid-state imaging device described above.

In the present disclosure, a solid-state imaging device includes a pixel region, a first color filter, and a second color filter.

The pixel region includes light receiving pixels arranged in a plurality of arrays in a first direction and in a second direction that intersects with the first direction. The first color filter is disposed over a plurality of light receiving pixels arranged in the first direction and has a first color. The second color filter is disposed over a plurality of light receiving pixels arranged in the first direction and has a second color different from the first color.

Here, the solid-state imaging device 1 includes a first inter-waveguide light shielding wall and a second inter-waveguide light shielding wall.

The first inter-waveguide light shielding wall is provided between the first color filter and the second color filter at the image height center of the pixel region and has a light-shielding property. The second inter-waveguide light shielding wall is provided between the first color filter and the second color filter at an image height periphery of the pixel region, which is located away from the image height center of the pixel region, and has a light-shielding property. Furthermore, the second inter-waveguide light shielding wall has a width greater than that of the first inter-waveguide light shielding wall in the same direction.

Thus, as a result of providing the second inter-waveguide light shielding wall having a greater width at the image height periphery where an amount of shift in photosensitivity is greater than at the image height center, it is possible to effectively suppress or prevent color mixing.

### Configuration of the Present Technology

The present technology has the following configuration. It is possible to effectively suppress or prevent color mixing by including the following configuration.

(1)

A solid-state imaging device including:
a pixel region including light receiving pixels arranged in a plurality of arrays, the light receiving pixels being arranged in a first direction and a second direction that intersects with the first direction;
a first color filter disposed over a plurality of the light receiving pixels arranged in the first direction, the first color filter having a first color;
a second color filter disposed over the plurality of the light receiving pixels arranged in the first direction, the second color filter having a second color different from the first color;
a first inter-waveguide light shielding wall provided between the first color filter and the second color filter at an image height center of the pixel region, the first inter-waveguide light shielding wall having a light-shielding property; and
a second inter-waveguide light shielding wall provided between the first color filter and the second color filter at an image periphery located away from the image height center of the pixel region, the second inter-waveguide light shielding wall having a light-shielding property and having a width greater than a width of the first inter-waveguide light shielding wall in the same direction.
   (2)

The solid-state imaging device according (1), in which
another first color filter or another second color filter is disposed with a shift in the first direction by an interval of an array of the light receiving pixels, the other first color filter being adjacent to the first color filter in the second direction, and the other second color filter being adjacent to the second color filter in the second direction.
   (3)

The solid-state imaging device according to (1) or (2), in which
the second inter-waveguide light shielding wall is provided between the first color filter and the second color filter, the second color filter being disposed closer to a side of the image height center than the first color filter.
   (4)

The solid-state imaging device according to any one of (1) to (3), in which the second inter-waveguide light shielding wall is provided between the first color filter and the second color filter, the first color filter and the second color filter being disposed in the first direction.

(5)

The solid-state imaging device according to any one of (1) to (3), in which
the second inter-waveguide light shielding wall is provided between the first color filter and the second color filter, the first color filter and the second color filter being disposed in the second direction.
   (6)

The solid-state imaging device according to any one of (1) to (3), in which
the second inter-waveguide light shielding wall is provided between the first color filter and the second color filter, the first color filter and the second color filter being disposed in a direction that intersects with the first direction and the second direction.
   (7)

The solid-state imaging device according to any one of (1) to (6), in which
the second inter-waveguide light shielding wall has a width that increases as an offset distance from the image height center increases.
   (8)

The solid-state imaging device according to any one of (1) to (7), in which
the image height periphery includes:
a first image height periphery located away from the image height center of the pixel region, and
a second image height periphery located away from the image height center toward an opposite side of the first image height periphery, and
the second inter-waveguide light shielding wall is provided at the first image height periphery and the second image height periphery.
   (9)

The solid-state imaging device according to (8), in which
the width of the second inter-waveguide light shielding wall provided at the first image height periphery has the same dimension as the width of the second inter-waveguide light shielding wall provided at the second image height periphery.
   (10)

The solid-state imaging device according to (8), in which
the width of the second inter-waveguide light shielding wall provided at the first image height periphery has a dimension different from the width of the second inter-waveguide light shielding wall provided at the second image height periphery.
   (11)

The solid-state imaging device according to any one of (1) to (11), in which
at the image height periphery, the first inter-waveguide light shielding wall is provided between each first color filter having the same color or between each second color filter having the same color.
   (12)

The solid-state imaging device according to any one of (1) to (11), further including a third color filter disposed over the plurality of the light receiving pixels arranged in the first direction, the third color filter having a third color different from the first color and the second color, in which
at the image height periphery, the second inter-waveguide light shielding wall is provided one each between the first color filter and the second color filter, between the second color filter and the third color filter, and between the third color filter and the first color filter.
   (13)

The solid-state imaging device according to any one of (1) to (12), in which
the light receiving pixels each include a photodiode that converts light into an electrical charge.
   (14)

The solid-state imaging device according to (12), further including a lens disposed on each of the first color filter, the second color filter, and the third color filter, the lens having a small aspect ratio in the second direction with respect to the first direction and protruding and curving to an opposite side of the light receiving pixels.

The present application claims the benefit of Japanese Priority Patent Application JP2022-096657 filed with the Japan Patent Office on Jun. 15, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device, comprising:
a pixel region including light receiving pixels arranged in a plurality of arrays, the light receiving pixels being arranged in a first direction and a second direction that intersects with the first direction;
a first color filter disposed over a plurality of the light receiving pixels arranged in the first direction, the first color filter having a first color;
a second color filter disposed over the plurality of the light receiving pixels arranged in the first direction, the second color filter having a second color different from the first color;
a first inter-waveguide light shielding wall provided between the first color filter and the second color filter at an image height center of the pixel region, the first inter-waveguide light shielding wall having a light-shielding property; and
a second inter-waveguide light shielding wall provided between the first color filter and the second color filter at an image periphery located away from the image height center of the pixel region, the second inter-waveguide light shielding wall having a light-shielding property and having a width greater than a width of the first inter-waveguide light shielding wall in a same direction.

2. The solid-state imaging device according to claim 1, wherein
another first color filter or another second color filter is disposed with a shift in the first direction by an interval of an array of the light receiving pixels, the other first color filter being adjacent to the first color filter in the second direction, and the other second color filter being adjacent to the second color filter in the second direction.

3. The solid-state imaging device according to claim 1, wherein
the second inter-waveguide light shielding wall is provided between the first color filter and the second color filter, the second color filter being disposed closer to a side of the image height center than the first color filter.

4. The solid-state imaging device according to claim 1, wherein
the second inter-waveguide light shielding wall is provided between the first color filter and the second color filter, the first color filter and the second color filter being disposed in the first direction.

5. The solid-state imaging device according to claim 1, wherein
the second inter-waveguide light shielding wall is provided between the first color filter and the second color filter, the first color filter and the second color filter being disposed in the second direction.

6. The solid-state imaging device according to claim 1, wherein
the second inter-waveguide light shielding wall is provided between the first color filter and the second color filter, the first color filter and the second color filter being disposed in a direction that intersects with the first direction and the second direction.

7. The solid-state imaging device according to claim 1, wherein
the second inter-waveguide light shielding wall has a width that increases as an offset distance from the image height center increases.

8. The solid-state imaging device according to claim 1, wherein
the image height periphery includes:
a first image height periphery located away from the image height center of the pixel region, and
a second image height periphery located away from the image height center toward an opposite side of the first image height periphery, and
the second inter-waveguide light shielding wall is provided at the first image height periphery and the second image height periphery.

9. The solid-state imaging device according to claim 8, wherein
the width of the second inter-waveguide light shielding wall provided at the first image height periphery has a same dimension as the width of the second inter-waveguide light shielding wall provided at the second image height periphery.

10. The solid-state imaging device according to claim 8, wherein
the width of the second inter-waveguide light shielding wall provided at the first image height periphery has a dimension different from the width of the second inter-waveguide light shielding wall provided at the second image height periphery.

11. The solid-state imaging device according to claim 1, wherein
at the image height periphery, the first inter-waveguide light shielding wall is provided between each first color filter having a same color or between each second color filter having a same color.

12. The solid-state imaging device according to claim 1, further comprising a third color filter disposed over the plurality of the light receiving pixels arranged in the first direction, the third color filter having a third color different from the first color and the second color, wherein
at the image height periphery, the second inter-waveguide light shielding wall is provided one each between the first color filter and the second color filter, between the second color filter and the third color filter, and between the third color filter and the first color filter.

13. The solid-state imaging device according to claim 1, wherein
the light receiving pixels each include a photodiode that converts light into an electrical charge.

14. The solid-state imaging device according to claim 12, further comprising a lens disposed on each of the first color filter, the second color filter, and the third color filter, the lens having a small aspect ratio in the second direction with respect to the first direction and protruding and curving to an opposite side of the light receiving pixels.
